(19) United States
(12) Patent Application Publication
(10) Pub. No.: US 2024/0113093 A1
(43) Pub. Date: Apr. 4, 2024

(54) INSULATION MODULE

(71) Applicant: ROHM CO., LTD., Kyoto-shi (JP)

(72) Inventors: Masahiko ARIMURA, Kyoto-shi (JP); Tomoichiro TOYAMA, Kyoto-shi (JP)

(21) Appl. No.: 18/537,324

(22) Filed: Dec. 12, 2023

Related U.S. Application Data
(63) Continuation of application No. PCT/JP2022/023701, filed on Jun. 14, 2022.

(30) Foreign Application Priority Data
Jun. 14, 2021 (JP) 2021-098853

(51) Int. Cl. H01L 25/16; H01L 23/00; H01L 23/495

(52) U.S. Cl. CPC H01L 25/167; H01L 23/49513; H01L 23/49541; H01L 23/49575; H01L 24/32; H01L 24/48; H01L 24/73; H01L 25/165; H01L 2224/32245; H01L 2224/48245; H01L 2224/73265

(57) ABSTRACT

This insulation module comprises: a light-emitting element that has a light-emitting surface and a pad formed on the light-emitting surface; a light-receiving element that has a light-receiving surface facing the light-emitting surface with a space therebetween, and that constitutes a photocoupler together with the light-emitting element; a plate-shaped member that is provided between the light-emitting surface and the light-receiving surface, has light-transmitting and insulating properties, and is inclined with respect to both the light-emitting surface and the light-receiving surface; and a wire that is connected to the pad. The pad is disposed offset from the center toward a section among the light-emitting surface where the distance to the plate-shaped member increases.

### BACKGROUND

### 1. Field

The present disclosure relates to an insulation module.

### 2. Description of Related Art

A photocoupler is a known insulation module of an optical type. U.S. Pat. No. 9,000,675 discloses an example of a structure in which the light emitting surface of a light emitting element is opposed to the light receiving surface of a light receiving element.

### BRIEF DESCRIPTION OF DRAWINGS

FIG. 1 is a perspective view showing a first embodiment of an insulation module.

FIG. 2 is a schematic plan view showing the internal structure of the insulation module shown in FIG. 1.

FIG. 3 is an enlarged view of the insulation module of FIG. 2 showing light emitting elements and their surroundings.

FIG. 4 is an enlarged view of the insulation module of FIG. 2 showing light receiving elements and their surroundings.

FIG. 5 is a cross-sectional view of the insulation module taken along line 5-5 in FIG. 2.

FIG. 6 is an enlarged view of the light emitting element and the light receiving element of the insulation module shown in FIG. 5 and their surroundings.

FIG. 7 is an enlarged view of the light emitting element of the insulation module shown in FIG. 6 and its surroundings.

FIG. 8 is an enlarged view of the light receiving element of the insulation module shown in FIG. 6 and its surroundings.

FIG. 9 is a cross-sectional view of the insulation module taken along line 9-9 in FIG. 2.

FIG. 10 is an enlarged view of a light emitting surface of the light emitting element and a light receiving surface of the light receiving element of the insulation module shown in FIG. 6 and their surroundings.

FIG. 11 is an enlarged view of the light emitting elements and the light receiving elements of the insulation module shown in FIG. 2 and their surroundings.

FIG. 12 is a cross-sectional view showing a portion of the light receiving element.

FIG. 13 is an enlarged plan view showing a portion of an encapsulation resin of the insulation module shown in FIG. 1.

FIG. 14 is an enlarged plan view showing another portion of the encapsulation resin of the insulation module shown in FIG. 1 differing from the portion shown in FIG. 13.

FIG. 15 is a schematic circuit diagram showing the electrical configuration of the insulation module shown in FIG. 1.

FIG. 16 is a cross-sectional view showing a cross-sectional structure of a portion of a second embodiment of an insulation module.

FIG. 17 is a cross-sectional view showing a portion of a light receiving element in a third embodiment of an insulation module.

FIG. 18 is a cross-sectional view showing a portion of a light receiving element in a fourth embodiment of an insulation module.

FIG. 19 is a cross-sectional view showing a cross-sectional structure of a portion of a fifth embodiment of an insulation module.

FIG. 20 is a schematic circuit diagram showing the electrical configuration of a sixth embodiment of an insulation module.

FIG. 21 is a cross-sectional view showing a cross-sectional structure of a portion of a modified example of an insulation module.

FIG. 22 is a cross-sectional view of a modified example of an insulation module showing a portion of a light receiving element and its surroundings.

FIG. 23 is a schematic plan view showing the internal structure of a modified example of an insulation module.

FIG. 24 is a cross-sectional view of a modified example of an insulation module showing a cross-sectional structure of a portion of the insulation module.

FIG. 25 is a schematic circuit diagram showing the electrical configuration of a modified example of an insulation module.

### DETAILED DESCRIPTION

Embodiments of an insulation module will be described below with reference to the drawings. The embodiments described below exemplify configurations and methods for embodying a technical concept and are not intended to limit the material, shape, structure, layout, dimensions, and the like of each component to those described below. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

### First Embodiment

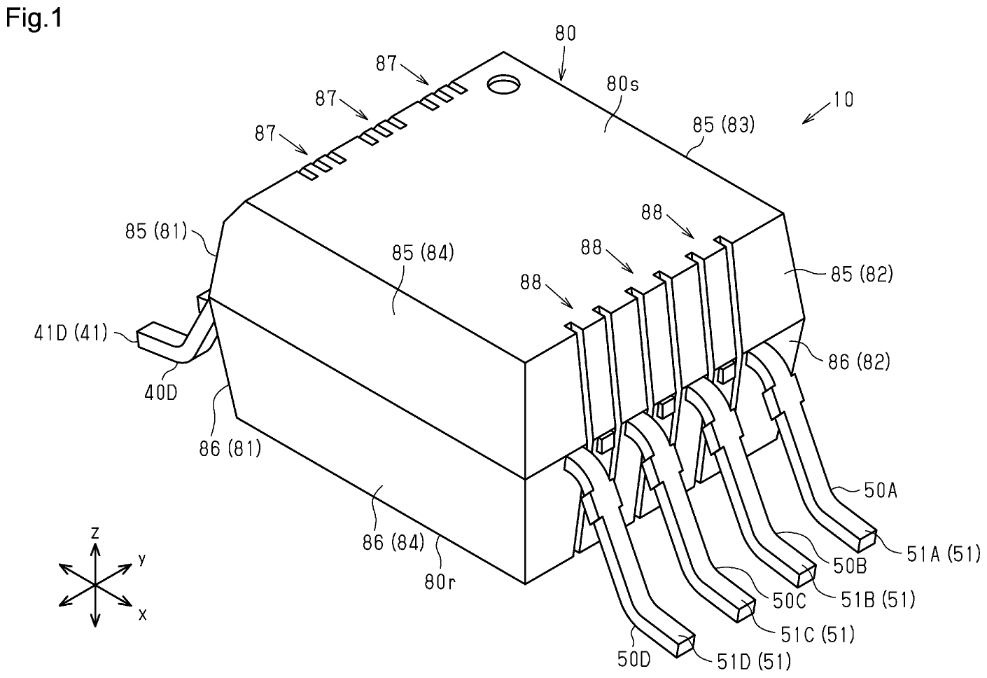

A first embodiment of an insulation module 10 will now be described with reference to FIGS. 1 to 15.

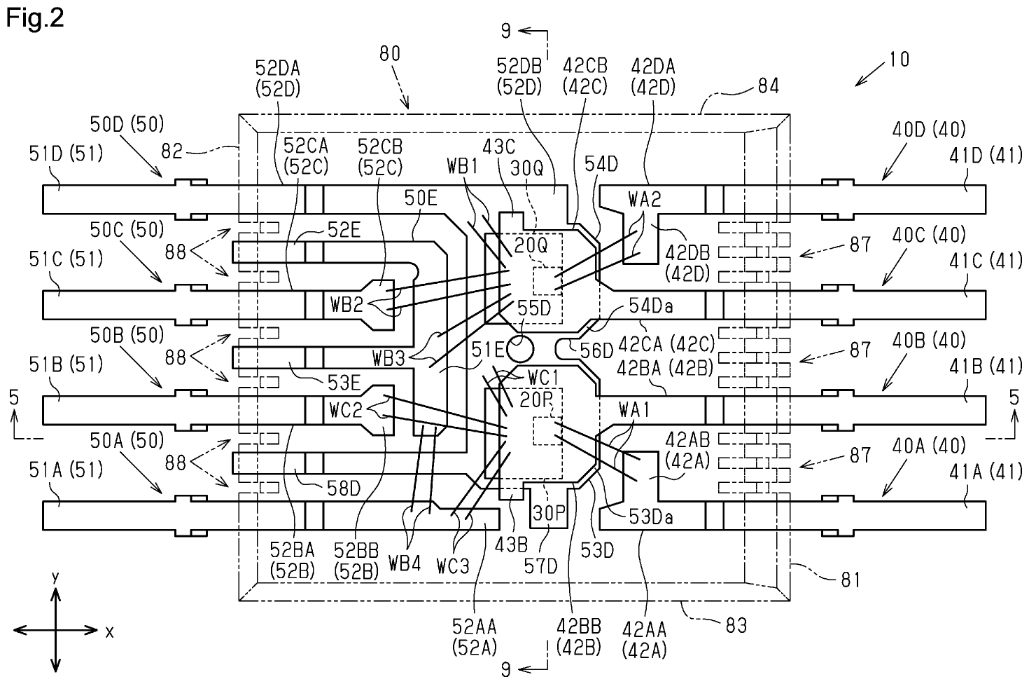

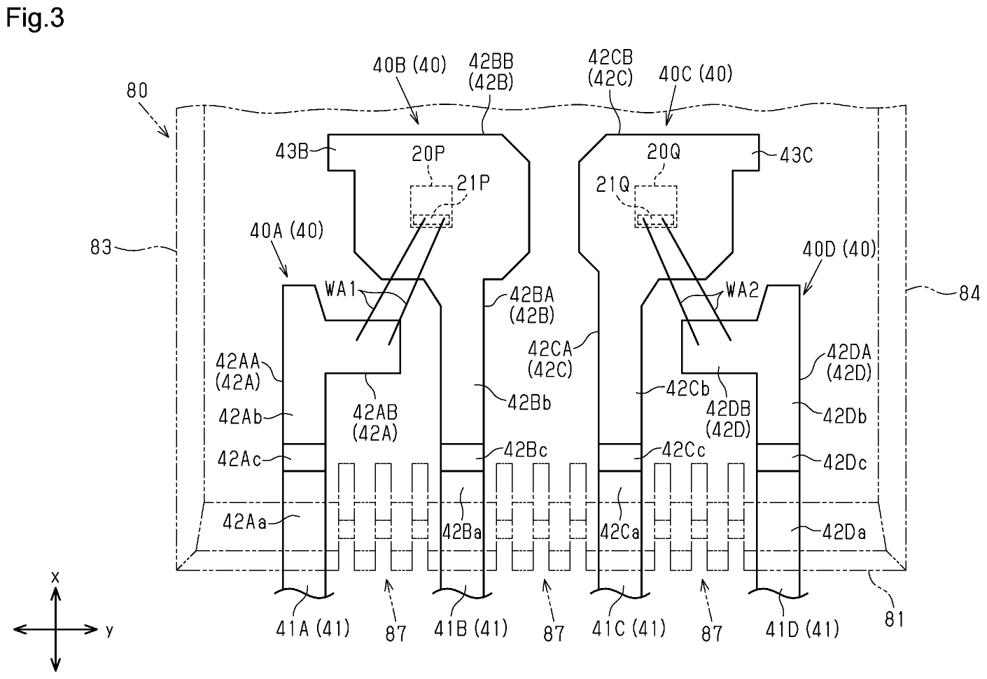

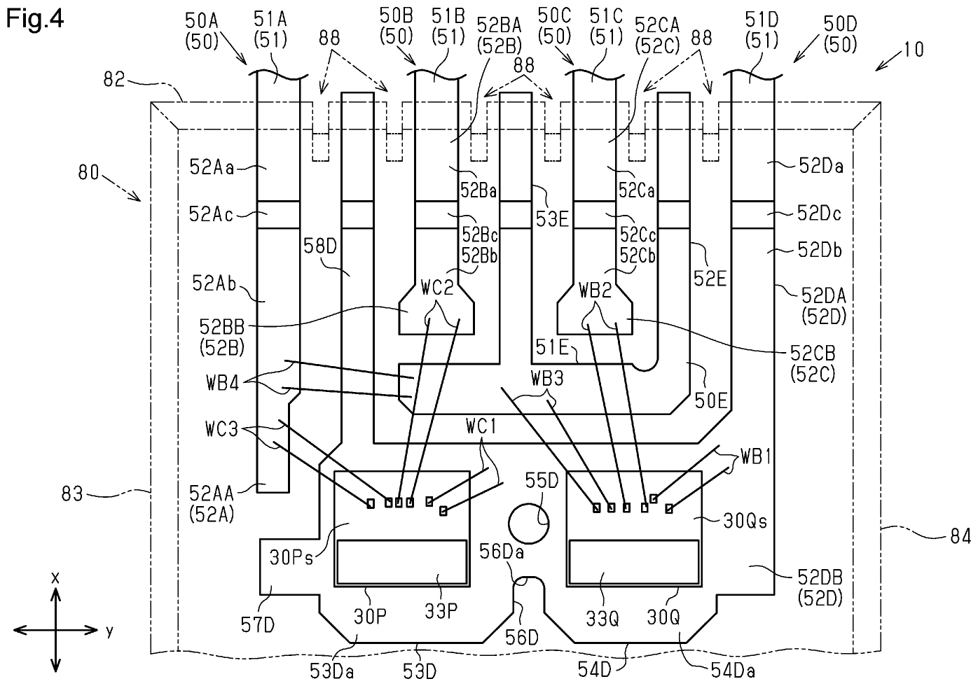

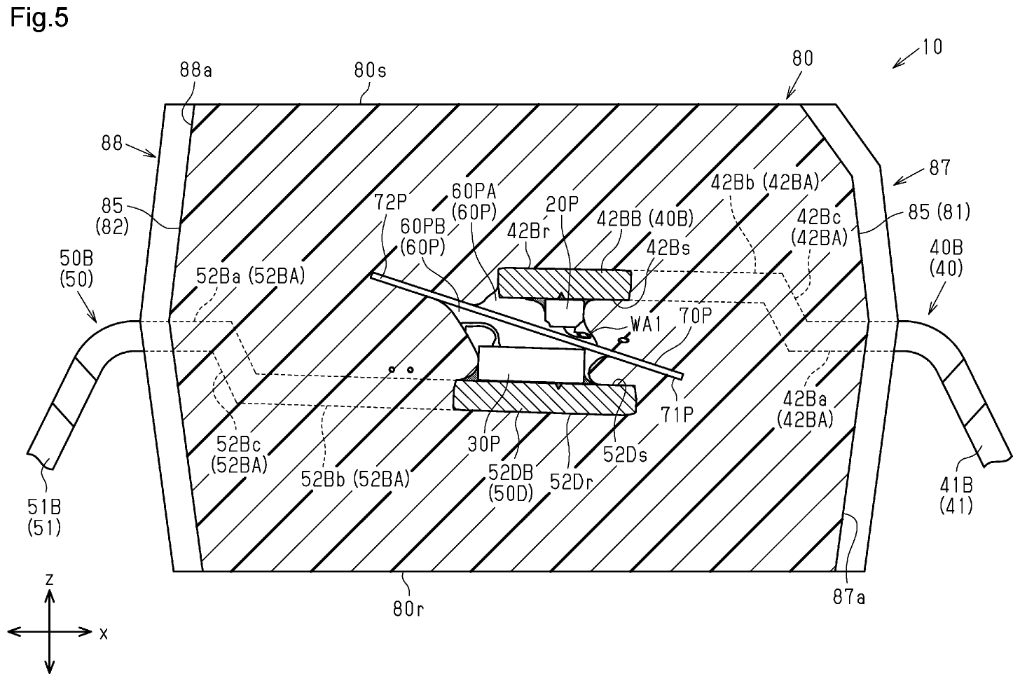

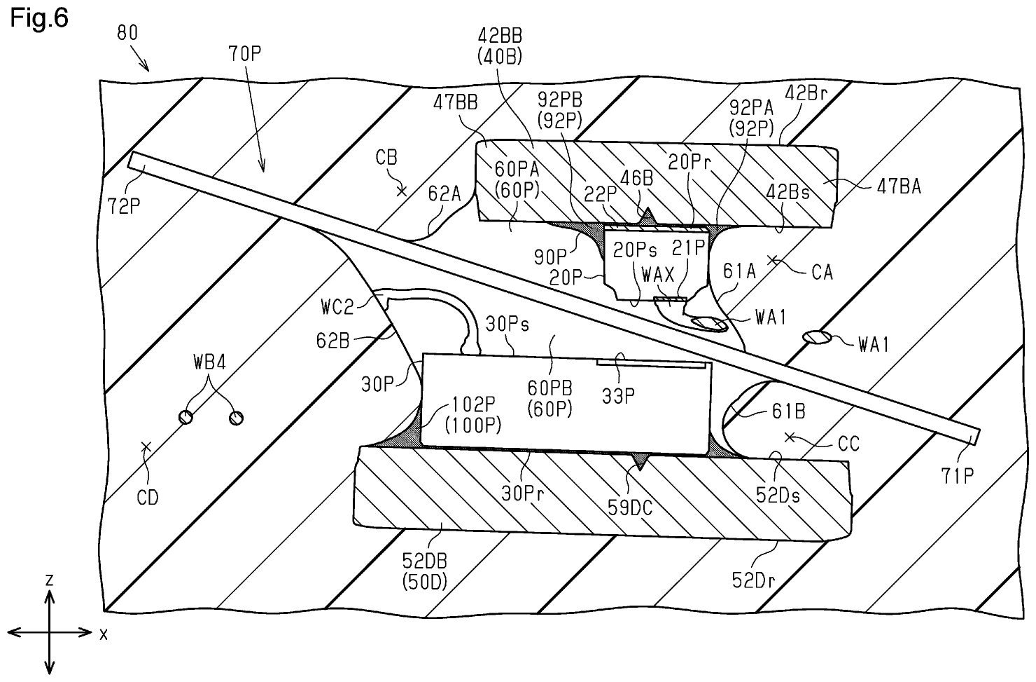

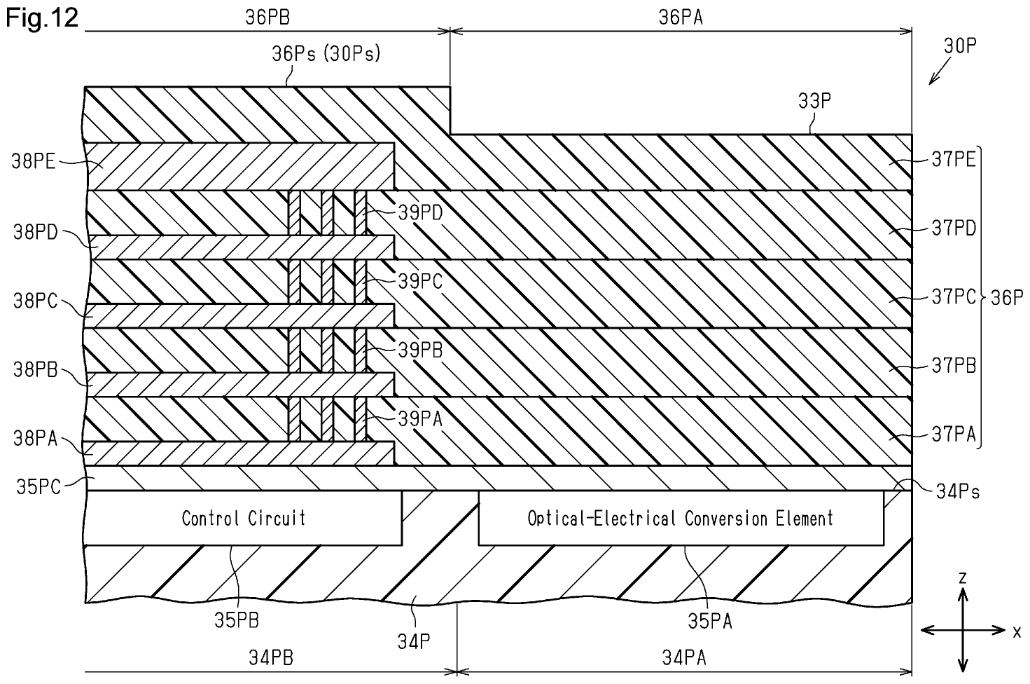

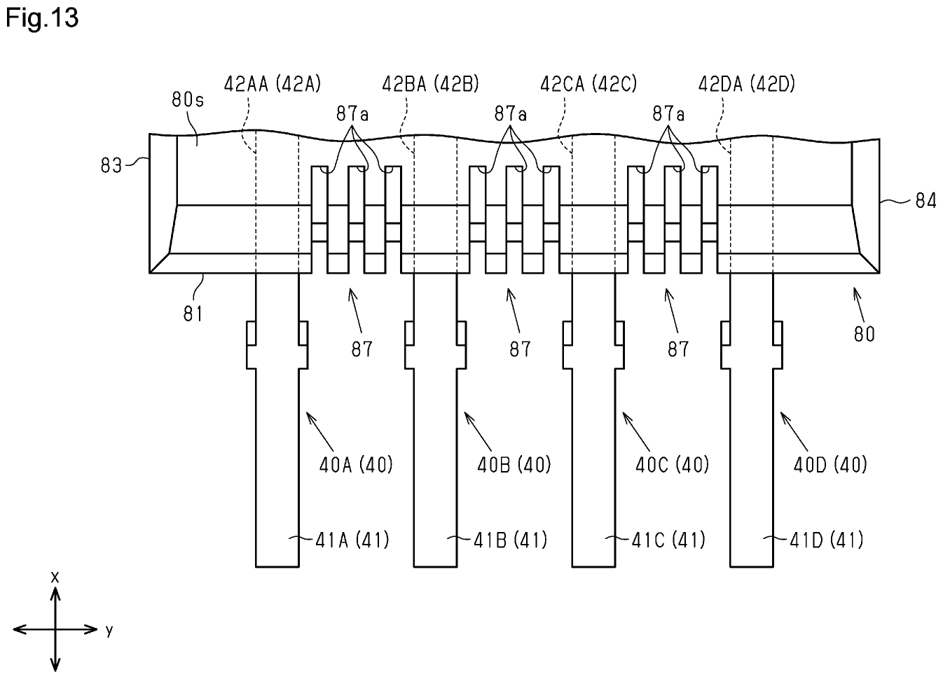

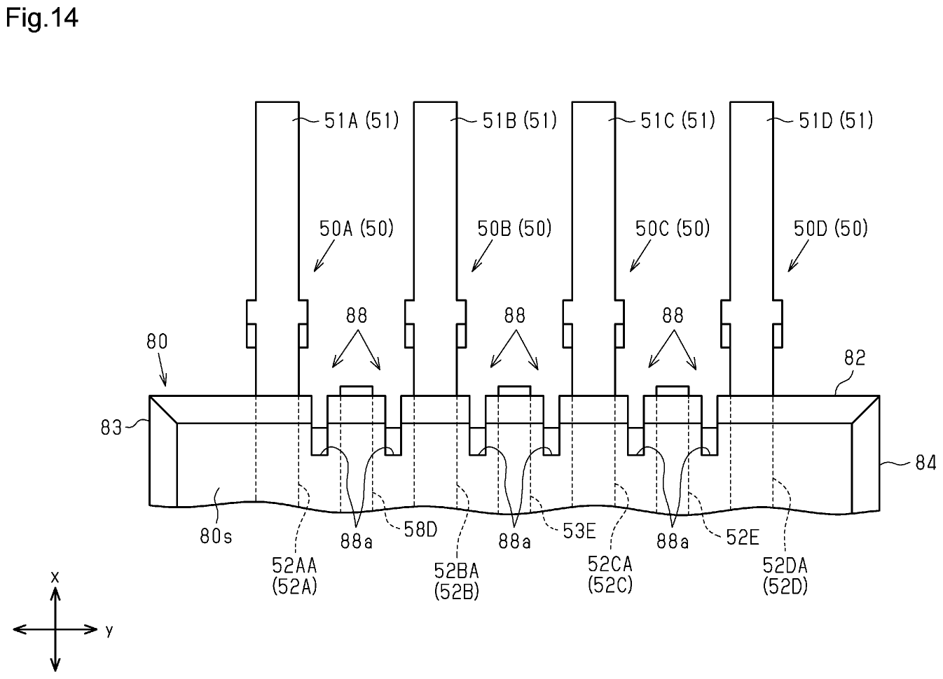

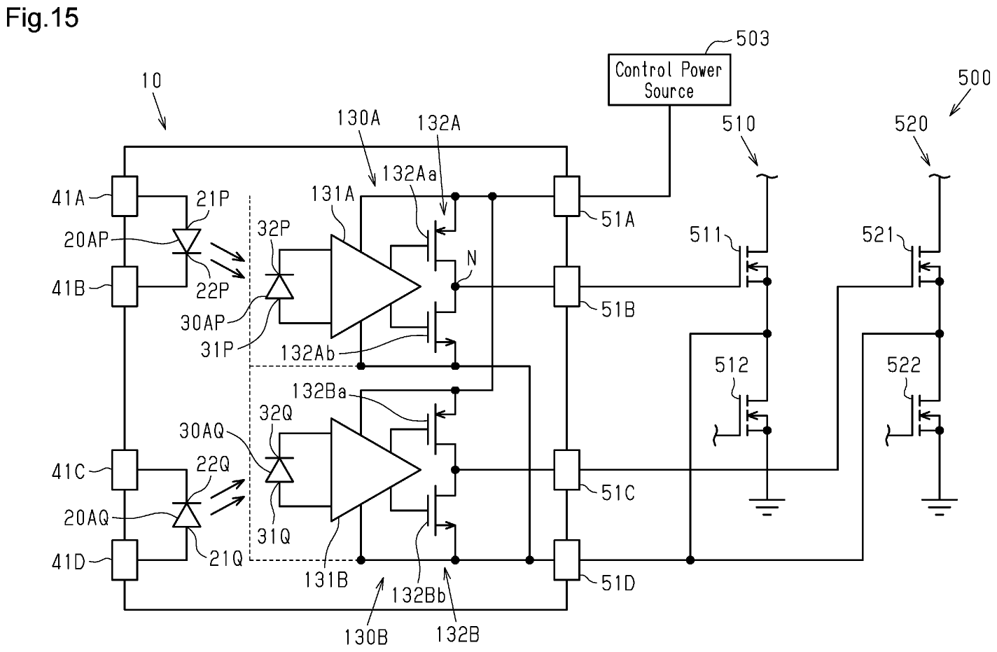

FIGS. 1 and 2 each show an overall structure of the insulation module 10. FIGS. 3 and 4 each show a partial internal structure of the insulation module 10. FIG. 5 shows an overall internal structure of the insulation module 10. FIGS. 6 to 11 each show an enlarged partial internal structure of the insulation module 10. FIG. 12 shows a partial cross-sectional structure of a light receiving element including a substrate and an insulation layer, which will be described later. FIG. 13 shows an outer appearance of a portion of the perimeter of the insulation module 10. FIG. 14 shows an outer appearance of a portion of the perimeter of the insulation module 10 differing from the portion shown in FIG. 13. FIG. 15 shows an example of the electrical configuration of the insulation module 10.

The insulation module 10 is used for a gate driver that applies a drive voltage signal to the gate of a switching element. As shown in FIGS. 1 and 2, the insulation module 10 has a dual in-line package (DIP) structure. The insulation module 10 includes a rectangular encapsulation resin 80 and terminals 41 and 51 projecting from the encapsulation resin 80. The insulation voltage of the insulation module 10 is, for example, in a range of 3500 Vrms to 7500 Vrms. However, the insulation voltage of the insulation module 10 is not limited to these values and may be any specific numerical value.

The encapsulation resin 80 is formed from a light-blocking, insulative material. An example of the insulative material is epoxy resin. In the present embodiment, the encapsulation resin 80 is formed from a black epoxy resin. As shown in FIGS. 1 and 2, the encapsulation resin 80 includes a resin main surface 80s, a resin back surface 80r, and first to fourth resin side surfaces 81 to 84. In the description hereafter, the thickness-wise direction of the encapsulation resin 80 is referred to as the z-direction. Two directions that are orthogonal to each other and to the z-direction are referred to as an x-direction and a y-direction.

The resin main surface 80s and the resin back surface 80r define two end surfaces of the encapsulation resin 80 in the thickness-wise direction (z-direction). As viewed in the z-direction, each of the resin main surface 80s and the resin back surface 80r is rectangular. In the present embodiment, as viewed in the z-direction, each of the resin main surface 80s and the resin back surface 80r is rectangular so that the long sides extend in the x-direction and the short sides extend in the y-direction.

The first resin side surface 81 and the second resin side surface 82 define two end surfaces in the x-direction. As viewed in the z-direction, each of the first resin side surface 81 and the second resin side surface 82 extends in the y-direction. Multiple (in the present embodiment, four) terminals 41A to 41D are arranged on the first resin side surface 81. Multiple (in the present embodiment, four) terminals 51A to 51D are arranged on the second resin side surface 82. In the present embodiment, the first resin side surface 81, including the terminals 41A to 41D, and the second resin side surface 82, including the terminals 51A to 51D, each correspond to “terminal surface.”

The terminals 41A to 41D project from the first resin side surface 81. The terminals 51A to 51D project from the second resin side surface 82. Thus, as viewed in the z-direction, the terminals 41A to 41D and the terminals 51A to 51D, which are arranged next one another, are spaced apart from each other in the x-direction. The x-direction may be referred to as an arrangement direction of the terminals 41A to 41D and the terminals 51A to 51D. As shown in FIGS. 1 and 2, the terminals 51A to 51D are identical in shape to the terminals 41A to 41D.

The third resin side surface 83 and the fourth resin side surface 84 define two end surfaces in the y-direction. The terminals 41A to 41D and 51A to 51D are not arranged on the third resin side surface 83 and the fourth resin side surface 84. As viewed in the z-direction, the third resin side surface 83 and the fourth resin side surface 84 extend in the x-direction.

In the present embodiment, the terminals 41A to 41D and 51A to 51D are identical to each other in shape. More specifically, as shown in FIG. 1, each of the terminals 41A to 41D includes a first part extending from the first resin side surface 81 in the x-direction, a first bent part bent downward from the first part, a second part inclining downward as the second part extends away from the encapsulation resin 80 in the x-direction, a second bent part bent outward from the second part, a third part inclining downward as the third part extends away from the encapsulation resin 80 in the x-direction. The inclination angle of the third part with respect to the z-direction is less than the inclination angle of the second part with respect to the z-direction. In the present embodiment, each of the terminals 41A to 41D and 51A to 51D is a gull-wing terminal.

For example, when the insulation module 10 is mounted on a wiring substrate (not shown), the terminals 41A to 41D and 51A to 51D are each configured as an external terminal mounted on a land arranged on the wiring substrate. The terminals 41A to 41D and 51A to 51D are bonded to the lands of the wiring substrate by, for example, a conductive bonding material such as solder or silver (Ag) paste. This electrically connects the insulation module 10 to the wiring substrate.

Each of the resin side surfaces 81 to 84 includes a first side surface 85 and a second side surface 86. The first side surface 85 is continuous with the second side surface 86. The first side surface 85 is located closer to the resin main surface 80s than to the resin back surface 80r in the z-direction. The second side surface 86 is located closer to the resin back surface 80r than to the resin main surface 80s in the z-direction. The first side surface 85 of the first resin side surface 81 and the first side surface 85 of the second resin side surface 82 are inclined toward each other in the x-direction as the resin main surface 80s becomes closer. The second side surface 86 of the first resin side surface 81 and the second side surface 86 of the second resin side surface 82 are inclined toward each other in the x-direction as the resin back surface 80r becomes closer. The first side surface 85 (not shown) of the third resin side surface 83 and the first side surface 85 of the fourth resin side surface 84 are inclined toward each other in the y-direction as the resin main surface 80s becomes closer. The second side surface 86 (not shown) of the third resin side surface 83 and the second side surface 86 of the fourth resin side surface 84 are inclined toward each other in the y-direction as the resin back surface 80r becomes closer.

Each of the four terminals 41A to 41D projects from the first resin side surface 81 between the first side surface 85 and the second side surface 86. The four terminals 41A to 41D are spaced apart from each other and arranged next one another in the y-direction.

Each of the four terminals 51A to 51D projects from the second resin side surface 82 between the first side surface 85 and the second side surface 86. The four terminals 51A to 51D are spaced apart from each other and arranged next one another in the y-direction.

The internal structure of the encapsulation resin 80 will now be described.

FIG. 2 is a plan view of the insulation module 10 showing the internal structure of the insulation module 10. In FIG. 2, for the sake of convenience, the encapsulation resin 80 is indicated by double-dashed lines. In addition, for the sake of convenience, FIG. 2 does not show a first transparent resin 60P, a second transparent resin 60Q, a first plate-shaped member 70P, a second plate-shaped member 70Q, and conductive bonding materials 90P, 90Q, 100P, and 100Q, which will be described later.

As shown in FIG. 2, the insulation module 10 includes a first light emitting element 20P, a second light emitting element 20Q, a first light receiving element 30P, a second light receiving element 30Q, a first lead frame 40, and a second lead frame 50. The first light emitting element 20P and the first light receiving element 30P form a first photocoupler. The second light emitting element 20Q and the second light receiving element 30Q form a second photocoupler.

In the present embodiment, the first lead frame 40 is configured to be electrically connected to the light emitting elements 20P and 20Q. The second lead frame 50 is configured to be electrically connected to the light receiving elements 30P and 30Q.

The first lead frame 40 includes four first lead frames, namely, the first lead frames 40A to 40D. As viewed in the z-direction, the first lead frames 40A to 40D are spaced apart from each other and arranged next one another in the y-direction.

The first lead frame 40A is located closer to the third resin side surface 83 with respect to the first lead frames 40B to 40D. The first lead frame 40A includes the terminal 41A. More specifically, the terminal 41A is a portion of the first lead frame 40A projecting from the first resin side surface 81 to the outside of the encapsulation resin 80.

The first lead frame 40A includes a portion arranged in the encapsulation resin 80, defining an inner lead 42A. The inner lead 42A includes a lead portion 42AA and a wire connector 42AB. The lead portion 42AA is continuous with the terminal 41A and, as viewed in the z-direction, extends from the first resin side surface 81 in the x-direction.

As shown in FIG. 3, the lead portion 42AA includes a first part 42Aa, a second part 42Ab, and a bent part 42Ac. The first part 42Aa is continuous with the terminal 41A. The first part 42Aa and the second part 42Ab are connected by the bent part 42Ac. The bent part 42Ac is arranged between the first part 42Aa and the second part 42Ab and is bent toward the resin main surface 80s (refer to FIG. 1) as the lead portion 42AA extends from the first part 42Aa toward the second part 42Ab. Thus, the second part 42Ab is located closer to the resin main surface 80s of the encapsulation resin 80 than the first part 42Aa is in the z-direction.

The wire connector 42AB extends from the second part 42Ab of the lead portion 42AA toward the fourth resin side surface 84 in the y-direction. The wire connector 42AB is aligned with the second part 42Ab in the z-direction. Therefore, the wire connector 42AB is located closer to the resin main surface 80s than the first part 42Aa is. In the x-direction, the wire connector 42AB is located closer to a distal end of the second part 42Ab with respect to the center of the second part 42Ab in the x-direction. Hence, the second part 42Ab includes a portion projecting from the wire connector 42AB in the x-direction. The encapsulation resin 80 is present at opposite sides of the wire connector 42AB in the x-direction. Thus, the wire connector 42AB restricts movement of the first lead frame 40A relative to the encapsulation resin 80 in the x-direction.

As shown in FIG. 2, the first lead frame 40B is located closer to the fourth resin side surface 84 than the first lead frame 40A is. The first lead frame 40B includes the terminal 41B. More specifically, the terminal 41B is a portion of the first lead frame 40B projecting from the first resin side surface 81 to the outside of the encapsulation resin 80.

The first lead frame 40B includes a portion arranged in the encapsulation resin 80, defining an inner lead 42B. The inner lead 42B includes a lead portion 42BA and a die pad 42BB. In the present embodiment, the die pad 42BB corresponds to a “first die pad.”

The lead portion 42BA is continuous with the terminal 41B and, as viewed in the z-direction, extends from the first resin side surface 81 in the x-direction. As viewed in the z-direction, the lead portion 42BA in the x-direction is equal to the lead portion 42AA of the first lead frame 40A in the dimension in the x-direction. As viewed in the z-direction, the wire connector 42AB is opposed to the lead portion 42BA in the y-direction.

In the present embodiment, the width of the lead portion 42BA (the dimension of the lead portion 42BA in the y-direction) is equal to the width of the lead portion 42AA (the dimension of the lead portion 42AA in the y-direction). When the difference between the width of the lead portion 42BA and the width of the lead portion 42AA is, for example, within 10% of the width of the lead portion 42BA, it is considered that the width of the lead portion 42BA is equal to the width of the lead portion 42AA.

As shown in FIG. 3, the lead portion 42BA includes a first part 42Ba, a second part 42Bb, and a bent part 42Bc. The first part 42Ba is continuous with the terminal 41B. The first part 42Ba and the second part 42Bb are connected by the bent part 42Bc. The bent part 42Bc is arranged between the first part 42Ba and the second part 42Bb and is bent toward the resin main surface 80s as the lead portion 42BA extends from the first part 42Ba toward the second part 42Bb. Thus, the second part 42Bb is located closer to the resin main surface 80s of the encapsulation resin 80 (refer to FIG. 1) than the first part 42Ba is in the z-direction. The second part 42Bb is continuous with the die pad 42BB. One of the two ends of the second part 42Bb in the y-direction that is located closer to the lead portion 42AA includes a slope that increases the width of the second part 42Bb (the dimension of the second part 42Bb in the y-direction) as the die pad 42BB becomes closer.

As shown in FIG. 2, the die pad 42BB is located closer to the second resin side surface 82 than the lead portion 42BA is in the x-direction. As viewed in the x-direction, the die pad 42BB partially overlaps the wire connector 42AB. In the present embodiment, as viewed in the y-direction, the die pad 42BB does not overlap the lead portion 42AA of the first lead frame 40A. The die pad 42BB is located closer to the fourth resin side surface 84 than the lead portion 42AA is in the y-direction. As viewed in the z-direction, the die pad 42BB is rectangular so that the short sides extend in the x-direction and the long sides extend in the y-direction.

As viewed in the x-direction, the die pad 42BB extends from opposite sides of the lead portion 42BA in the y-direction. The amount of the die pad 42BB extending from the lead portion 42BA toward the third resin side surface 83 is greater than the amount of the die pad 42BB extending from the lead portion 42BA toward the fourth resin side surface 84. In other words, the lead portion 42BA is located closer to the fourth resin side surface 84 with respect to the center of the die pad 42BB in the y-direction.

The die pad 42BB includes a protrusion 43B. The protrusion 43B extends toward the third resin side surface 83 in the y-direction from one of the four corners of the die pad 42BB that is located close to the second resin side surface 82 and the third resin side surface 83. As viewed in the x-direction, the protrusion 43B overlaps the wire connector 42AB. As viewed in the x-direction, the protrusion 43B does not overlap the lead portion 42AA. Therefore, the distal end of the protrusion 43B is separated apart from the third resin side surface 83 in the y-direction. That is, the protrusion 43B is not exposed from the third resin side surface 83. The encapsulation resin 80 is present at opposite sides of the protrusion 43B in the x-direction. Thus, the protrusion 43B restricts movement of the first lead frame 40B relative to the encapsulation resin 80 in the x-direction.

As shown in FIGS. 2 and 3, the first lead frame 40C is located closer to the fourth resin side surface 84 than the first lead frame 40B is. The first lead frame 40C includes the terminal 41C. More specifically, the terminal 41C is a portion of the first lead frame 40C projecting from the first resin side surface 81 to the outside of the encapsulation resin 80.

The first lead frame 40C includes a portion arranged in the encapsulation resin 80, defining an inner lead 42C. The inner lead 42C includes a lead portion 42CA and a die pad 42CB. In the present embodiment, the die pad 42CB corresponds to a “first die pad.”

The shapes of the lead portion 42CA and the die pad 42CB as viewed in the z-direction are symmetrical to the shapes of the lead portion 42BA and the die pad 42BB as viewed in the z-direction with respect to the centerline extending in the x-direction through the center of the encapsulation resin 80 in the y-direction. The bent shape of lead portion 42CA is the same as that of the lead portion 42BA. Hence, the lead portion 42CA and the die pad 42CB will not described in detail.

In the same manner as the lead portion 42BA, the lead portion 42CA includes a first part 42Ca, a second part 42Cb, and a bent part 42Cc. In the same manner as the die pad 42BB, the die pad 42CB includes a protrusion 43C. As viewed in the z-direction, the die pad 42CB and the die pad 42BB of the first lead frame 40B are aligned with each other in the x-direction and separated from each other in the y-direction.

The first lead frame 40D is located closer to the fourth resin side surface 84 than the first lead frame 40C is. The first lead frame 40D includes the terminal 41D. More specifically, the terminal 41D is a portion of the first lead frame 40D projecting from the first resin side surface 81 to the outside of the encapsulation resin 80.

The first lead frame 40D includes a portion arranged in the encapsulation resin 80, defining an inner lead 42D. The inner lead 42D includes a lead portion 42DA and a wire connector 42DB.

The shapes of the lead portion 42DA and the wire connector 42DB as viewed in the z-direction are symmetrical to the shapes of the lead portion 42AA and the wire connector 42AB as viewed in the z-direction with respect to the centerline extending in the x-direction through the center of the encapsulation resin 80 in the y-direction. The bent shape of the lead portion 42DA is the same as that of the lead portion 42AA. More specifically, the lead portion 42DA is continuous with the terminal 41D. In the same manner as the lead portion 42AA, the lead portion 42DA includes a first part 42Da, a second part 42Db, and a bent part 42Dc. Hence, the lead portion 42DA and the wire connector 42DB will not be described in detail.

As shown in FIG. 2, the second lead frame 50 includes four second lead frames, namely, second lead frames 50A to 50D. As viewed in the z-direction, the second lead frames 50A to 50D are spaced apart from each other and arranged next one another in the y-direction. The insulation module 10 includes an intermediate frame 50E.

The second lead frame 50A is located closer to the third resin side surface 83 with respect to the second lead frames 50B to 50D. The second lead frame 50A includes the terminal 51A. More specifically, the terminal 51A is a portion of the second lead frame 50A projecting from the second resin side surface 82 to the outside of the encapsulation resin 80. In the present embodiment, the terminal 51A overlaps the terminal 41A as viewed in the x-direction.

The second lead frame 50A includes a portion arranged in the encapsulation resin 80, defining an inner lead 52A. The inner lead 52A extends in the x-direction. As viewed in the z-direction, the distal end of the inner lead 52A is located closer to the second resin side surface 82 than the center of the encapsulation resin 80 is in the x-direction. More specifically, the distal end of the inner lead 52A is located closer to the second resin side surface 82 than the die pad 42BB of the first lead frame 40B is.

As viewed in the x-direction, the inner lead 52A overlaps the lead portion 42AA of the first lead frame 40A. The distal end of the inner lead 52A includes a narrow portion 52AA that decreases the width of the inner lead 52A (the dimension of the inner lead 52A in the y-direction). The narrow portion 52AA is recessed toward the third resin side surface 83 from one of the two ends of the inner lead 52A in the y-direction that is located closer to the fourth resin side surface 84.

As shown in FIG. 4, the inner lead 52A includes a first part 52Aa, a second part 52Ab, and a bent part 52Ac. The first part 52Aa is continuous with the terminal 51A. The first part 52Aa and the second part 52Ab are connected by the bent part 52Ac. The bent part 52Ac is a portion of the inner lead 52A arranged between the first part 52Aa and the second part 52Ab and bent toward the resin back surface 80r (refer to FIG. 1) as the inner lead 52A extends from the first part 52Aa toward the second part 52Ab. Thus, the second part 52Ab is located closer to the resin back surface 80r of the encapsulation resin 80 than the first part 52Aa is in the z-direction. The narrow portion 52AA is continuous with the second part 52Ab. Thus, the narrow portion 52AA is located closer to the resin back surface 80r than the first part 52Aa is in the z-direction.

As shown in FIG. 2, the second lead frame 50B is located closer to the fourth resin side surface 84 than the second lead frame 50A is. The second lead frame 50B includes the terminal 51B. More specifically, the terminal 51B is a portion of the second lead frame 50B projecting from the second resin side surface 82 to the outside of the encapsulation resin 80. In the present embodiment, the terminal 51B overlaps the terminal 41B as viewed in the x-direction.

The second lead frame 50B includes a portion arranged in the encapsulation resin 80, defining an inner lead 52B. The inner lead 52B includes a lead portion 52BA and a wire connector 52BB. The lead portion 52BA is continuous with the terminal 51B and, as viewed in the z-direction, extends from the second resin side surface 82 in the x-direction. The dimension of the lead portion 52BA in the x-direction is smaller than the dimension of the inner lead 52A of the second lead frame 50A in the x-direction. In the present embodiment, the width of the lead portion 52BA (the dimension of the lead portion 52BA in the y-direction) is equal to the width of the inner lead 52A excluding the narrow portion 52AA (the dimension of the inner lead 52A excluding the narrow portion 52AA in the y-direction). When the difference between the width of the lead portion 52BA and the width of the inner lead 52A excluding the narrow portion 52AA is, for example, less than or equal to 10% of the width of the lead portion 52BA, it is considered that the width of the lead portion 52BA is equal to the width of the inner lead 52A excluding the narrow portion 52AA.

As shown in FIG. 4, the lead portion 52BA includes a first part 52Ba, a second part 52Bb, and a bent part 52Bc. The first part 52Ba is continuous with the terminal 51B. The first part 52Ba and the second part 52Bb are connected by the bent part 52Bc. The bent part 52Bc is a portion arranged between the first part 52Ba and the second part 52Bb and bent toward the resin back surface 80r (refer to FIG. 1) as the inner lead 52A extends from the first part 52Ba toward the second part 52Bb. Thus, the second part 52Bb is located closer to the resin back surface 80r of the encapsulation resin 80 than the first part 52Ba is in the z-direction.

The wire connector 52BB is located closer to the first resin side surface 81 than the second part 52Bb of the lead portion 52BA. As viewed in the z-direction, the wire connector 52BB is trapezoidal. The width of the wire connector 52BB (the dimension of the wire connector 52BB in the y-direction) is greater than the width of the lead portion 52BA (the dimension of the lead portion 52BA in the y-direction). The wire connector 52BB extends from opposite sides of the lead portion 52BA in the y-direction. One of the two ends of the wire connector 52BB in the x-direction that is located closer to the lead portion 52BA is tapered so that the width of the wire connector 52BB increases as the lead portion 52BA becomes farther away. The encapsulation resin 80 is present at opposite sides of a portion of the wire connector 52BB extending from the lead portion 52BA in the x-direction. Thus, the wire connector 52BB restricts movement of the second lead frame 50B relative to the encapsulation resin 80 in the x-direction.

As shown in FIG. 2, the second lead frame 50C is located closer to the fourth resin side surface 84 than the second lead frame 50B is. The second lead frame 50C includes the terminal 51C. More specifically, the terminal 51C is a portion of the second lead frame 50C projecting from the second resin side surface 82 to the outside of the encapsulation resin 80. In the present embodiment, the terminal 51C overlaps the terminal 41C as viewed in the x-direction.

The second lead frame 50C includes a portion arranged in the encapsulation resin 80, defining an inner lead 52C. The inner lead 52C includes a lead portion 52CA and a wire connector 52CB.

As shown in FIG. 4, the shapes of the lead portion 52CA and the wire connector 52CB as viewed in the z-direction are symmetrical to the shapes of the lead portion 52BA and the wire connector 52BB as viewed in the z-direction with respect to the centerline extending in the x-direction through the center of the encapsulation resin 80 in the y-direction. The bent shape of lead portion 52CA is the same as that of the lead portion 52BA. In the same manner as the lead portion 52BA, the lead portion 52CA includes a first part 52Ca, a second part 52Cb, and a bent part 52Cc. Hence, the lead portion 42CA and the die pad 42CB will not described in detail.

As shown in FIG. 2, the second lead frame 50D is located closer to the fourth resin side surface 84 than the second lead frame 50C is. The second lead frame 50D includes the terminal 51D. More specifically, the terminal 51D is a portion of the second lead frame 50D projecting from the second resin side surface 82 to the outside of the encapsulation resin 80. In the present embodiment, the terminal 51D overlaps the terminal 41D as viewed in the x-direction.

The second lead frame 50D includes a portion arranged in the encapsulation resin 80, defining an inner lead 52D. The inner lead 52D includes a lead portion 52DA and a die pad 52DB. In the present embodiment, the die pad 52DB corresponds to a “second die pad.”

The lead portion 52DA is continuous with the terminal 51D and, as viewed in the z-direction, extends from the second resin side surface 82 in the x-direction. The dimension of the lead portion 52DA in the x-direction is greater than the dimension of the inner lead 52C of the second lead frame 50C in the x-direction and less than the dimension of the inner lead 52A of the second lead frame 50A in the x-direction. The width of the lead portion 52DA (the dimension of the lead portion 52DA in the y-direction) is equal to the width of the lead portion 52CA of the second lead frame 50C (the dimension of the lead portion 52CA in the y-direction). When the difference between the width of the lead portion 52DA and the width of the lead portion 52CA is, for example, less than or equal to 10% of the width of the lead portion 52DA, it is considered that the width of the lead portion 52DA is equal to the width of the lead portion 52CA.

As shown in FIG. 4, the lead portion 52DA includes a first part 52Da, a second part 52Db, and a bent part 52Dc. The first part 52Da is continuous with the terminal 51D. The first part 52Da and the second part 52Db are connected by the bent part 52Dc. The bent part 52Dc is a portion arranged between the first part 52Da and the second part 52Db and bent toward the resin back surface 80r (refer to FIG. 1) as the lead portion 52DA extends from the first part 52Da toward the second part 52Db. Thus, the second part 52Db is located closer to the resin back surface 80r of the encapsulation resin 80 than the first part 52Da is in the z-direction.

The die pad 52DB is located closer to the first resin side surface 81 than the lead portion 52DA is. One of the two ends of the die pad 52DB in the y-direction that is located closer to the lead portion 52DA is aligned with the lead portion 52DA in the y-direction. One of the two ends of the die pad 52DB in the y-direction that is located farther away from the lead portion 52DA is arranged adjacent to the narrow portion 52AA of the second lead frame 50A in the y-direction. Thus, the die pad 52DB extends toward the third resin side surface 83 beyond the second lead frame 50B. In other words, the die pad 52DB is opposed to the second lead frames 50B and 50C in the x-direction. As shown in FIG. 4, the die pad 52DB is shaped so that a long side extends in the y-direction and a short side extends in the x-direction. The width of the die pad 52DB (the dimension of the die pad 52DB in the x-direction) is greater than the width of the lead portion 52DA.

The die pad 52DB includes a first element mount 53D and a second element mount 54D. The first element mount 53D and the second element mount 54D are spaced apart from each other in the y-direction. The first element mount 53D is a region of the die pad 52DB opposite the lead portion 52DA. The second element mount 54D is a region of the die pad 52DB located closer to the lead portion 52DA with respect to the first element mount 53D in the y-direction.

A through hole 55D extends through between the first element mount 53D and the second element mount 54D in the y-direction. In the present embodiment, as viewed in the z-direction, the through hole 55D is circular. The through hole 55D is filled with the encapsulation resin 80. The encapsulation resin 80 in the through hole 55D restricts movement of the second lead frame 50D relative to the encapsulation resin 80 in a direction orthogonal to the z-direction.

The first element mount 53D and the second element mount 54D respectively include protrusions 53Da and 54Da extending toward the second resin side surface 82 in the x-direction with respect to one of the two ends of the die pad 52DB in the y-direction located closer to the lead portion 52DA. As viewed in the z-direction, a recess 56D is arranged between the protrusions 53Da and 54Da in the y-direction. As viewed in the z-direction, the recess 56D is open toward the first resin side surface 81 in the x-direction. As viewed in the z-direction, the recess 56D includes a bottom surface 56Da located closer to the second resin side surface 82 than an end surface, located close to the first resin side surface 81, of one of the two ends of the die pad 52DB in the y-direction located closer to the lead portion 52DA. The recess 56D and the through hole 55D are aligned with each other in the y-direction and separated from each other in the x-direction.

The perimeter of the die pad 52DB includes a protrusion 57D and a suspension lead 58D.

The protrusion 57D extends toward the third resin side surface 83 in the y-direction from one of the two ends of the die pad 52DB in the y-direction that is located farther away from the lead portion 52DA, that is, the distal end of the die pad 52DB. The protrusion 57D is located closer to the first resin side surface 81 than the center of the die pad 52DB is in the x-direction. As viewed in the x-direction, the protrusion 57D overlaps with the first lead frame 40A and the second lead frame 50A. The protrusion 57D is arranged between the first lead frame 40A and the second lead frame 50A in the x-direction. In the present embodiment, the width of the protrusion 57D (the dimension of the protrusion 57D in the x-direction) is greater than the width of the lead portion 52DA. However, the protrusion 57D may have any width. The encapsulation resin 80 is present at opposite sides of the protrusion 57D in the x-direction. This restricts movement of the die pad 52DB relative to the encapsulation resin 80 in the x-direction.

The suspension lead 58D extends toward the second resin side surface 82 in the x-direction from one of the two ends of the die pad 52DB in the y-direction that is located farther away from the lead portion 52DA (i.e., the distal end of the die pad 52DB). The suspension lead 58D is exposed from the second resin side surface 82. The suspension lead 58D overlaps the first element mount 53D as viewed in the x-direction. The suspension lead 58D is arranged between the second lead frame 50A and the second lead frame 50B in the y-direction. The width of the suspension lead 58D (the dimension of the suspension lead 58D in the y-direction) is less than the width of the lead portion 52DA.

As shown in FIG. 2, as viewed in the z-direction, the die pads 42BB and 42CB of the first lead frames 40B and 40C overlap the die pad 52DB. The die pads 42BB and 42CB are located closer to the resin main surface 80s (refer to FIG. 5) than the die pad 52DB. In other words, as viewed in the z-direction, the die pad 52DB overlaps the die pads 42BB and 42CB. The die pad 52DB is located closer to the resin back surface 80r (refer to FIG. 5) than the die pads 42BB and 42CB.

As viewed in the z-direction, the die pad 42BB overlaps the first element mount 53D of the die pad 52DB. As viewed in the z-direction, the die pad 42CB overlaps the second element mount 54D of the die pad 52DB. As shown in FIG. 2, as viewed in the z-direction, the die pads 42BB and 42CB are located at a position differing from the positions of the through hole 55D and the recess 56D.

The die pad 52DB is greater than the die pads 42BB and 42CB in the dimension in the x-direction. Thus, as viewed in the z-direction, the die pad 52DB includes an extension extending beyond the die pads 42BB and 42CB in the x-direction. In the present embodiment, the entire surface of the die pad 42BB overlaps the first element mount 53D of the die pad 52DB. The entire surface of the die pad 42CB overlaps the second element mount 54D of the die pad 52DB. As shown in FIG. 2, as viewed in the z-direction, the protrusion 43B of the die pad 42BB is located closer to the second resin side surface 82 than the protrusion 57D.

As shown in FIGS. 2 and 4, the intermediate frame 50E is opposed to the die pad 52DB in the x-direction. The intermediate frame 50E is located closer to the second resin side surface 82 than the die pad 52DB is. The intermediate frame 50E does not include an external terminal.

The intermediate frame 50E includes a wire connector 51E, a first suspension lead 52E, and a second suspension lead 53E.

The wire connector 51E extends in the y-direction. As viewed in the z-direction, the wire connector 51E is shaped so that a long side extends in the y-direction and a short side extends in the x-direction. The width of the wire connector 51E (the dimension of the wire connector 51E in the x-direction) is equal to the width of the lead portion 52CA (the dimension of the lead portion 52CA in the y-direction). Also, the width of the wire connector 51E is equal to the width of the lead portion 52BA (the dimension of the lead portion 52BA in the y-direction). When the difference between the width of the wire connector 51E and the width of the lead portion 52CA (the width of the lead portion 52BA) is, for example, less than or equal to 10% of the width of the wire connector 51E, it is considered that the width of the wire connector 51E is equal to the width of the lead portion 52CA (the width of the lead portion 52BA).

The wire connector 51E is opposed to the second lead frames 50B and 50C in the x-direction. In other words, as viewed in the x-direction, the wire connector 51E overlaps the second lead frames 50B and 50C. The wire connector 51E is arranged between the die pad 52DB and the second lead frames 50B and 50C in the x-direction. In other words, the wire connector 51E is opposed to the die pad 52DB in the x-direction.

The first suspension lead 52E extends toward the second resin side surface 82 in the x-direction from one of the two ends of the wire connector 51E in the y-direction that is located closer to the lead portion 52DA of the second lead frame 50D. The first suspension lead 52E is arranged between the lead portion 52DA and the second lead frame 50C in the y-direction. The first suspension lead 52E is exposed from the second resin side surface 82.

The second suspension lead 53E extends toward the second resin side surface 82 in the x-direction from substantially the center of the wire connector 51E in the y-direction. The second suspension lead 53E is arranged between the second lead frame 50C and the second lead frame 50B in the y-direction. The second suspension lead 53E is exposed from the second resin side surface 82.

As shown in FIG. 3, the first light emitting element 20P is mounted on the die pad 42BB of the first lead frame 40B. The second light emitting element 20Q is mounted on the die pad 42CB of the first lead frame 40C.

The first light emitting element 20P is arranged on the center of the die pad 42BB in the y-direction. The first light emitting element 20P is arranged closer to the second resin side surface 82 (refer to FIG. 2) with respect to the center of the die pad 42BB in the x-direction. More specifically, as viewed in the z-direction, the first light emitting element 20P overlaps the center of the die pad 42BB in the x-direction. The center of the first light emitting element 20P in the x-direction is located closer to the second resin side surface 82 than the center of the die pad 42BB in the x-direction.

The second light emitting element 20Q is arranged on the die pad 42CB in the same manner as the first light emitting element 20P is arranged on the die pad 42BB. The first light emitting element 20P and the second light emitting element 20Q are aligned with each other in the x-direction and spaced apart from each other in the y-direction. In the present embodiment, the distance between the first light emitting element 20P and the second light emitting element 20Q is greater than the dimension of the first light emitting element 20P in the y-direction.

With reference to FIGS. 5 to 7, the cross-sectional structure of the die pad 42BB, the structure of the first light emitting element 20P, and the arrangement of the first light emitting element 20P on the die pad 42BB will be described. The cross-sectional structure of the die pad 42CB, the structure of the second light emitting element 20Q, and the arrangement of the second light emitting element 20Q on the die pad 42CB are the same as those of the first light emitting element 20P and the die pad 42BB and thus will not be described in detail.

As shown in FIGS. 5 and 6, the die pad 42BB includes a first surface 42Bs and a second surface 42Br facing in opposite directions in the thickness-wise direction of the die pad 42CB.

The first surface 42Bs includes a mount surface on which the first light emitting element 20P is mounted. In the present embodiment, the first surface 42Bs corresponds to a “mount surface of first die pad.” The first surface 42Bs and the resin back surface 80r (refer to FIG. 5) of the encapsulation resin 80 face in the same direction.

The second surface 42Br and the resin main surface 80s of the encapsulation resin 80 (refer to FIG. 5) face in the same direction. The second surface 42Br is separated from the resin main surface 80s in the z-direction. That is, the second surface 42Br is not exposed from the resin main surface 80s.

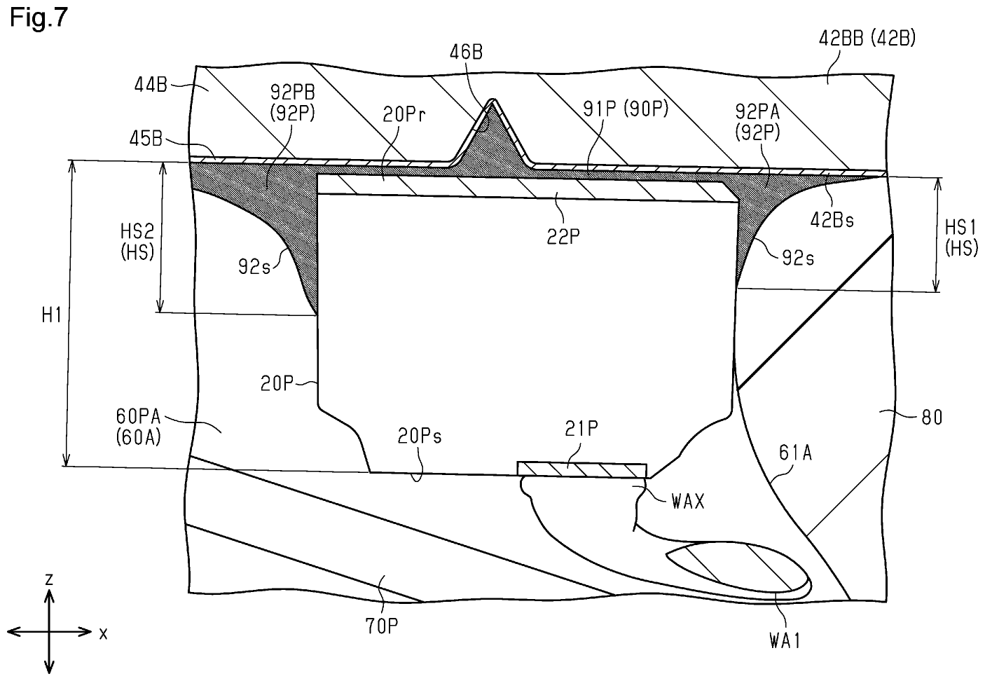

As shown in FIG. 7, the die pad 42BB includes a main metal layer 44B and a plated layer 45B formed on an outer surface of the main metal layer 44B. The main metal layer 44B is formed from, for example, a metal material including Cu. The plated layer 45B is formed from a material including nickel (Ni), chromium (Cr), or the like. As shown in FIG. 7, the thickness of the plated layer 45B is much smaller than that of the main metal layer 44B.

A portion of the first surface 42Bs of the die pad 42BB is recessed from the first surface 42Bs toward the second surface 42Br, defining a recess 46B. The recess 46B is arranged in the center of the die pad 42BB in the x-direction. As viewed in the z-direction, the recess 46B extends in the y-direction. In the present embodiment, as shown in FIG. 7, the recess 46B is a V-shaped groove. The depth of the recess 46B is greater than the thickness of the plated layer 45B. The plated layer 45B is also formed in the recess 46B. In the present embodiment, the recess 46B corresponds to a “first recess.”

As viewed in the z-direction, the first light emitting element 20P is arranged on the die pad 42BB to overlap the recess 46B. The first light emitting element 20P includes an element main surface 20Ps and an element back surface 20Pr that face in opposite directions in the thickness-wise direction of the first light emitting element 20P. The element main surface 20Ps and the first surface 42Bs of the die pad 42BB face in the same direction. The element back surface 20Pr and the second surface 42Br (refer to FIG. 6) face in the same direction.

A first electrode 21P is arranged on the element main surface 20Ps. A second electrode 22P is arranged on the element back surface 20Pr. The second electrode 22P is arranged on, for example, the entirety of the element back surface 20Pr. In the present embodiment, the element main surface 20Ps includes a light emitting surface. The first light emitting element 20P emits light downward from the element main surface 20Ps. The first light emitting element 20P emits light having a first wavelength. An example of the first wavelength light is light having a wavelength including infrared. In the present embodiment, the element main surface 20Ps corresponds to a “light emitting surface” and “first light emitting surface.”

In a cross-sectional structure of the first light emitting element 20P cut along the xz-plane, one of the two ends of the first light emitting element 20P in the z-direction located closer to the element main surface 20Ps is tapered toward the element main surface 20Ps. Thus, in the first light emitting element 20P, the element main surface 20Ps has a smaller area than the element back surface 20Pr.

As shown in FIG. 7, the first light emitting element 20P is bonded to the first surface 42Bs of the die pad 42BB by the conductive bonding material 90P such as solder or silver (Ag) paste. In an example, the conductive bonding material 90P is used to die-bond the first light emitting element 20P to the die pad 42BB so that the first light emitting element 20P is bonded to the die pad 42BB. The conductive bonding material 90P is applied between the first surface 42Bs of the die pad 42BB and the element back surface 20Pr of the first light emitting element 20P. In the present embodiment, the conductive bonding material 90P corresponds to a “first bonding material.”

The conductive bonding material 90P includes a first bonding region 91P located between the element back surface 20Pr of the first light emitting element 20P and the first surface 42Bs of the die pad 42BB and a second bonding region 92P bonded to outer side surfaces of the first light emitting element 20P in a region extending out from the first light emitting element 20P as viewed in the z-direction.

The first bonding region 91P extends into the recess 46B of the die pad 42BB. More specifically, the first bonding region 91P is located between the element back surface 20Pr of the first light emitting element 20P and the first surface 42Bs of the die pad 42BB and in the recess 46B.

The thickness of the second bonding region 92P is decreased as the outer side surface of the first light emitting element 20P becomes farther away. As viewed in the z-direction, the second bonding region 92P is formed around the perimeter of the first light emitting element 20P.

The second bonding region 92P includes a surface 92s that is curved to have a center of curvature located downward with respect to the surface 92s, that is, located on a side of the surface 92s opposite the die pad 42BB in the z-direction. The surface 92s of the second bonding region 92P is formed of a combination of curved surfaces. Each of the curved surfaces has a center of curvature located on a side of the surface 92s opposite the die pad 42BB. In the surface 92s of the second bonding region 92P, the curvature of a curved surface in a region adjacent to the first light emitting element 20P is greater than the curvature of a curved surface in a region farther away from the first light emitting element 20P.

Height HS of a portion of the second bonding region 92P that is in contact with the outer side surface of the first light emitting element 20P is less than or equal to ½ of height H1 of the first light emitting element 20P. In a cross-sectional structure of the first light emitting element 20P and the conductive bonding material 90P cut along xz-plane, the height HS1 of the second bonding region 92P in contact with one of the side surfaces of the first light emitting element 20P in the x-direction and located closer to the first resin side surface 81 (refer to FIG. 5) is less than or equal to ½ of the height H1. The height HS2 of the second bonding region 92P in contact with one of the side surfaces of the first light emitting element 20P in the x-direction located closer to the second resin side surface 82 (refer to FIG. 5) is approximately ½ of the height H1. The heights HS1, HS2 (HS) are determined by height of a portion of the second bonding region 92P that is in contact with the outer side surface of the first light emitting element 20P from the first surface 42Bs of the die pad 42BB. That is, the height HS is the thickness of the portion of the second bonding region 92P in contact with the outer surface of the first light emitting element 20P. The height H1 is determined by the distance between the first surface 42Bs of the die pad 42BB and the element main surface 20Ps of the first light emitting element 20P in the z-direction.

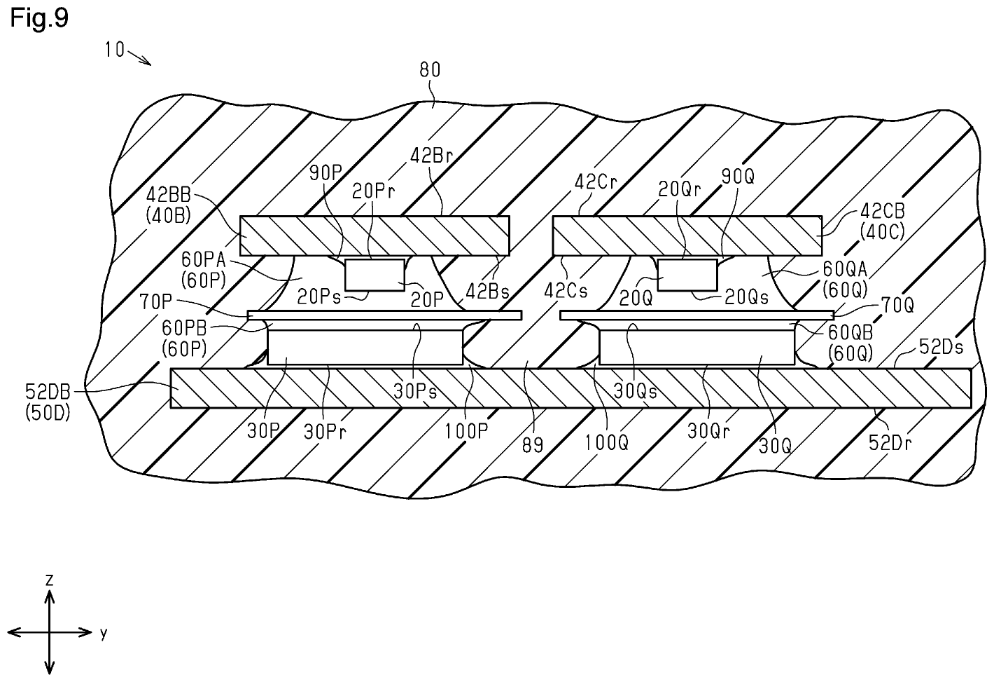

The die pad 42CB of the first lead frame 40C includes a first surface 42Cs and a second surface 42Cr (refer to FIG. 9) in the same manner as the die pad 42BB. The first surface 42Cs and the first surface 42Bs of the die pad 42BB face in the same direction. The second surface 42Cr and the second surface 42Br of the die pad 42BB face in the same direction. The die pad 42CB and the die pad 42BB are aligned with each other in the z-direction.

The second light emitting element 20Q emits light having a second wavelength that differs from the first wavelength of the first light emitting element 20P. An example of the second wavelength light is light having a wavelength including red.

The first wavelength light of the first light emitting element 20P and the second wavelength light of the second light emitting element 20Q may be changed in any manner. In an example, each of the first light emitting element 20P and the second light emitting element 20Q is configured to emit visible light. In an example, the first light emitting element 20P may be configured to emit light having a wavelength including blue. The second light emitting element 20Q may be configured to emit light having a wavelength including red. In the present embodiment, the first wavelength light of the first light emitting element 20P differs from the second wavelength light of the second light emitting element 20Q. However, there is no limit to such a configuration. The first light emitting element 20P and the second light emitting element 20Q may be configured to emit light having the same wavelength. In an example, the first light emitting element 20P and the second light emitting element 20Q are configured to emit light including a red wavelength. In another example, the first light emitting element 20P and the second light emitting element 20Q are configured to emit light including an infrared wavelength.

In the same manner as the first light emitting element 20P, the second light emitting element 20Q includes an element main surface 20Qs and an element back surface 20Qr. The element main surface 20Qs includes a light emitting surface. The element main surface 20Qs and the element main surface 20Ps of the first light emitting element 20P face in the same direction. The element back surface 20Qr and the element back surface 20Pr of the first light emitting element 20P face in the same direction. In the present embodiment, the element main surface 20Qs corresponds to a “light emitting surface” and a “second light emitting surface.”

The second light emitting element 20Q is bonded to the first surface 42Cs (refer to FIG. 9) of the die pad 42CB by the conductive bonding material 90Q such as solder or Ag paste. In an example, the conductive bonding material 90Q is used to die-bond the second light emitting element 20Q to the die pad 42CB so that the second light emitting element 20Q is bonded to the die pad 42CB. The second light emitting element 20Q and the die pad 42CB are bonded by the conductive bonding material 90Q in the same manner as the conductive bonding material 90P.

As shown in FIG. 4, the first light receiving element 30P and the second light receiving element 30Q are mounted on the die pad 52DB of the second lead frame 50D. The first light receiving element 30P is mounted on the first element mount 53D of the die pad 52DB. The second light receiving element 30Q is mounted on the second element mount 54D. The first light receiving element 30P and the second light receiving element 30Q are aligned with each other in the x-direction and spaced apart from each other in the y-direction. As shown in FIG. 4, the through hole 55D and the recess 56D are located in the die pad 52DB between the first light receiving element 30P and the second light receiving element 30Q in the y-direction.

As viewed in the z-direction, the first light receiving element 30P is rectangular. In the present embodiment, as viewed in the z-direction, the first light receiving element 30P is rectangular so that the short sides extend in the x-direction and the long sides extend in the y-direction. The first light receiving element 30P is configured to receive light (first wavelength light) from the first light emitting element 20P. The first light receiving element 30P includes a first semiconductor region that receives light from the first light emitting element 20P and a second semiconductor region that generates a signal based on the received light. The first semiconductor region includes an optical-electrical conversion element. The optical-electrical conversion element includes, for example, a photodiode. The second semiconductor region is formed of, for example, large scale integration (LSI). Thus, the first light receiving element 30P of the present embodiment integrates the function of receiving light from the first light emitting element 20P and the function of generating a signal from the received light. As viewed in the z-direction, the first semiconductor region and the second semiconductor region are formed next each other in the x-direction. As viewed in the z-direction, the first semiconductor region is formed in a portion of the first light receiving element 30P located toward the first resin side surface 81 (refer to FIG. 2). The second semiconductor region is formed in a portion of the first light receiving element 30P located toward the second resin side surface 82. The area of the first semiconductor region as viewed in the z-direction is smaller than the area of the second semiconductor region as viewed in the z-direction. As viewed in the z-direction, the dimension of the first semiconductor region in the x-direction is smaller than the dimension of the second semiconductor region in the x-direction. As viewed in the z-direction, the first semiconductor region of the first light receiving element 30P forms a light receiving surface 33P.

As shown in FIG. 2, the area of the first light receiving element 30P as viewed in the z-direction is larger than the area of the first light emitting element 20P as viewed in the z-direction. In an example, the area of the first light receiving element 30P as viewed in the z-direction is larger than or equal to two times, and preferably larger than or equal to five times, the area of the first light emitting element 20P as viewed in the z-direction. In the present embodiment, the area of the first light receiving element 30P as viewed in the z-direction is approximately six times the area of the first light emitting element 20P as viewed in the z-direction.

The first light receiving element 30P includes an element main surface 30Ps and an element back surface 30Pr. The element main surface 30Ps and a first surface 52Ds of the die pad 52DB face in the same direction. The element back surface 30Pr and a second surface 52Dr of the die pad 52DB face in the same direction. The element main surface 30Ps includes a light receiving surface 33P.

The structure of the second light receiving element 30Q is the same as that of the first light receiving element 30P and integrates the optical-electrical conversion element and LSI. However, the second light receiving element 30Q is configured to receive light (second wavelength light) from the second light emitting element 20Q. In the same manner as the first light receiving element 30P, a light receiving surface 33Q is formed on the second light receiving element 30Q. The light receiving surface 33Q of the second light receiving element 30Q and the light receiving surface 33P of the first light receiving element 30P are aligned with each other in the x-direction and spaced apart from each other in the y-direction. In the same manner as the first light receiving element 30P, the second light receiving element 30Q includes an element main surface 30Qs and an element back surface 30Qr. The element main surface 30Qs and the element main surface 30Ps of the first light receiving element 30P face in the same direction. The element back surface 30Qr and the element back surface 30Pr of the first light receiving element 30P face in the same direction.

As shown in FIGS. 2 and 3, the first light emitting element 20P is electrically connected to the first lead frames 40A and 40B. The second light emitting element 20Q is electrically connected to the first lead frames 40C and 40D.

The first electrode 21P of the first light emitting element 20P is connected to the first lead frame 40A by two wires WA1. Thus, the first electrode 21P is electrically connected to the first lead frame 40A. The two wires WA1 connect the first electrode 21P to the wire connector 42AB of the first lead frame 40A. The two wires WA1 are separated farther from each other from the first electrode 21P toward the wire connector 42AB. The wire connector 42AB is located closer to the first resin side surface 81 and the third resin side surface 83 than the first electrode 21P is. Therefore, as viewed in the z-direction, the two wires WA1 are inclined toward the third resin side surface 83 as the two wires WA1 extend from the first electrode 21P toward the wire connector 42AB.

The second electrode 22P of the first light emitting element 20P is bonded to the first lead frame 40B by the conductive bonding material 90P and is thereby electrically connected to the first lead frame 40B. The first electrode 21P is an anode electrode. The second electrode 22P is a cathode electrode. Accordingly, the terminal 41A of the first lead frame 40A is configured as an anode terminal of the first light emitting element 20P. The terminal 41B of the first lead frame 40B is configured as a cathode terminal of the first light emitting element 20P.

The second light emitting element 20Q includes a first electrode 21Q connected to the first lead frame 40D by two wires WA2. Thus, the first electrode 21Q is electrically connected to the first lead frame 40D. The two wires WA2 connect the first electrode 21Q to the wire connector 42DB of the first lead frame 40D. The two wires WA2 are separated farther from each other from the first electrode 21Q toward the wire connector 42DB. The wire connector 42DB is located closer to the first resin side surface 81 and the fourth resin side surface 84 than the first electrode 21Q is. Therefore, as viewed in the z-direction, the two wires WA2 are inclined toward the fourth resin side surface 84 as the two wires WA2 extend from the first electrode 21Q toward the wire connector 42DB.

The second light emitting element 20Q includes a second electrode 22Q bonded to the first lead frame 40C by the conductive bonding material 90Q and is thereby electrically connected to the first lead frame 40C. The first electrode 21Q is an anode electrode. The second electrode 22Q is a cathode electrode. Accordingly, the terminal 41D of the first lead frame 40D is configured as an anode terminal of the second light emitting element 20Q. The terminal 41C of the first lead frame 40C is configured as a cathode terminal of the second light emitting element 20Q.

The wires WA1 and WA2 are, for example, bonding wires formed by a wire bonder (not shown). The wires WA1 and WA2 are formed from a conductive material including, for example, Cu, aluminum (Al), gold (Au), or Ag. In the present embodiment, the wires WA1 and WA2 are formed from a material including Au.

As shown in FIGS. 2 and 4, the first light receiving element 30P is electrically connected to the second lead frames 50A, 50C, and 50D by wires WC1 to WC4. The second light receiving element 30Q is electrically connected to the second lead frames 50A, 50B, and 50D by wires WB1 to WB3. The wires WB1 to WB4 and WC1 to WC3 are, for example, bonding wires formed by a wire bonder (not shown) in the same manner as the wires WA1 and WA2. The wires WB1 to WB4 and WC1 to WC3 are formed from a conductive material (in the present embodiment, Au) in the same manner as the wires WA1 and WA2.

The two wires WB1 connect the second semiconductor region of the second light receiving element 30Q to the die pad 52DB of the second lead frame 50D. The two wires WB2 connect the second semiconductor region of the second light receiving element 30Q to the wire connector 52CB of the second lead frame 50C. The two wires WB3 connect the second semiconductor region of the second light receiving element 30Q to the wire connector 51E of the intermediate frame 50E. The two wires WB3 are connected to a portion of the wire connector 51E located between the second lead frame 50B and the second lead frame 50C in the y-direction. As viewed in the z-direction, the wires WB1 to WB3 are connected to a peripheral portion of the second semiconductor region of the second light receiving element 30Q. The two wires WB4 connect one of the two ends of the wire connector 51E in the y-direction that is located closer to the second lead frame 50A to a portion of the second lead frame 50A located toward the second resin side surface 82 from the narrow portion 52AA. Thus, the second light receiving element 30Q is electrically connected to the second lead frame 50A by the wires WB3 and WB4 and the intermediate frame 50E.

The two wires WC1 connect the second semiconductor region of the first light receiving element 30P to the die pad 52DB. The two wires WC2 connect the second semiconductor region of the first light receiving element 30P to the wire connector 52BB of the second lead frame 50B. The two wires WC3 connect the second semiconductor region of the first light receiving element 30P to the narrow portion 52AA of the second lead frame 50A.

With reference to FIGS. 5, 6, and 8, the cross-sectional structure of the die pad 52DB, the structure of the first light receiving element 30P, and the arrangement of the first light receiving element 30P on the die pad 52DB will be described. The structure of the second light receiving element 30Q and the arrangement of the second light receiving element 30Q on the die pad 52DB are the same as those of the first light receiving element 30P and the die pad 52DB and thus will not be described in detail.

As shown in FIGS. 5 and 6, the die pad 52DB includes the first surface 52Ds and the second surface 52Dr facing in opposite directions in the thickness-wise direction of the die pad 52DB (z-direction).

The first surface 52Ds includes a mount surface on which the first light receiving element 30P and the second light receiving element 30Q are mounted. In the present embodiment, the first surface 52Ds corresponds to a “mount surface of second die pad.” The first surface 52Ds is faced to the first surface 42Bs of the die pad 42BB in the z-direction. The first surface 52Ds is faced to the second surface 42Br of the die pad 42BB.

The second surface 52Dr and the first surface 42Bs of the die pad 42BB face in the same direction. The second surface 52Dr is separated from the resin back surface 80r (refer to FIG. 5) in the z-direction. That is, the second surface 52Dr is not exposed from the resin back surface 80r.

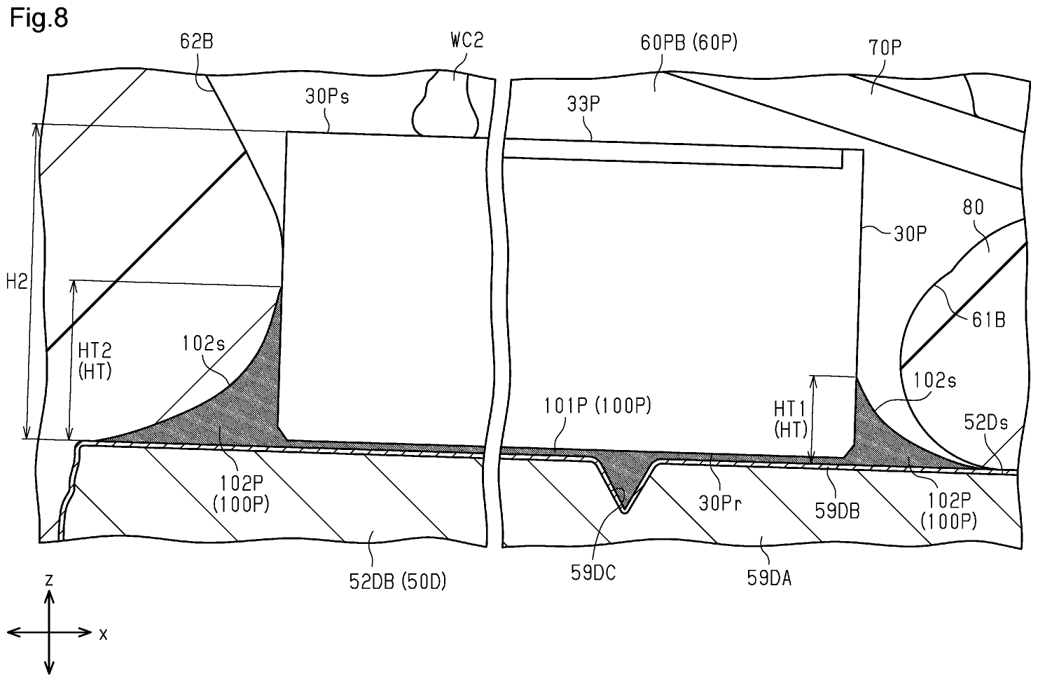

As shown in FIG. 8, the die pad 52DB includes a main metal layer 59DA and a plated layer 59DB formed on an outer surface of the main metal layer 59DA. The main metal layer 59DA is formed from, for example, a metal material including Cu. The plated layer 59DB is formed from a material including Ni, Cr, or the like. As shown in FIG. 6, the thickness of the plated layer 59DB is much smaller than that of the main metal layer 59DA.

A portion of the first surface 52Ds of the die pad 52DB is recessed from the first surface 52Ds toward the second surface 52Dr, defining a recess 59DC. As shown in FIG. 6, the recess 59DC is arranged closer to the first resin side surface 81 (refer to FIG. 2) than the center of the die pad 52DB in the x-direction. As viewed in the z-direction, the recess 59DC extends in the y-direction. In the present embodiment, as shown in FIG. 8, the recess 59DC is a V-shaped groove. The depth of the recess 59DC is greater than the thickness of the plated layer 59DB. The plated layer 59DB is formed in the recess 59DC. In the present embodiment, the recess 59DC corresponds to a “second recess.”

The shape of the recess 59DC may be changed in any manner. In an example, the recess 59DC may be, for example, quadrilateral, semi-circular, or arcuate as viewed in the y-direction. The recess 59DC may have any shape that is recessed from the first surface 52Ds toward the second surface 52Dr.

As shown in FIG. 6, the first light receiving element 30P is bonded to the first surface 52Ds of the die pad 52DB by the conductive bonding material 100P (refer to FIG. 6) such as solder or Ag paste.

As shown in FIG. 8, the conductive bonding material 100P is applied between the first surface 52Ds of the die pad 52DB and the element back surface 30Pr of the first light receiving element 30P. In the present embodiment, the conductive bonding material 100P corresponds to a “second bonding material.”

The conductive bonding material 100P includes a first bonding region 101P located between the element back surface 30Pr of the first light receiving element 30P and the first surface 52Ds of the die pad 52DB and a second bonding region 102P bonded to outer side surfaces of the first light receiving element 30P in a region extending out from the first light receiving element 30P as viewed in the z-direction.

The first bonding region 101P extends into the recess 59DC of the die pad 52DB. More specifically, the first bonding region 101P is located between the element back surface 30Pr of the first light receiving element 30P and the first surface 52Ds of the die pad 52DB and in the recess 59DC.

The thickness of the second bonding region 102P is decreased from the portion bonded to the outer side surfaces of the first light receiving element 30P as the first light receiving element 30P becomes farther away. As viewed in the z-direction, the second bonding region 102P is formed around the perimeter of the first light receiving element 30P.

The second bonding region 102P includes a surface 102s that is curved to have a center of curvature located upward from the surface 102s, that is, located on a side of the surface 102s opposite the die pad 52DB in the z-direction. The surface 102s of the second bonding region 102P is formed of a combination of curved surfaces. Each curved surface has a center of curvature located on a side of the curved surface opposite the die pad 52DB. The curvature of the surface 102s of the second bonding region 102P in a region adjacent to the first light receiving element 30P is greater than the curvature of the surface 102s of the second bonding region 102P in a region farther away from the first light receiving element 30P.

Height HT of a portion of the second bonding region 102P that is in contact with the outer side surface of the first light receiving element 30P is less than or equal to ½ of height H2 of the first light receiving element 30P. In the present embodiment, the height HT is less than ½ of the height H2. The height HT is determined by height of a portion of the second bonding region 102P that is in contact with the outer side surface of the first light receiving element 30P from the first surface 52Ds of the die pad 52DB. That is, the height HT is the thickness of the portion of the second bonding region 102P in contact with the outer side surface of the first light receiving element 30P. The height H2 is determined by the distance between the first surface 52Ds of the die pad 52DB and the element main surface 30Ps of the first light receiving element 30P in the z-direction.

The height HT includes height HT1 of a portion of the second bonding region 102P in contact with the outer side surface of the first light receiving element 30P located toward the first resin side surface 81 (refer to FIG. 5) and height HT2 of a portion of the second bonding region 102P in contact with the outer side surface of the first light receiving element 30P toward the second resin side surface 82 (refer to FIG. 5). As shown in FIG. 8, the height HT1 differs from the height HT2. In the present embodiment, the height HT2 is greater than the height HT1. More specifically, as viewed in the z-direction, the height HT2 of the second bonding region 102P located toward the second resin side surface 82, at which the die pad 52DB extends out from the first light receiving element 30P in the x-direction by a small amount, is greater than the height HT1 of the second bonding region 102P located toward the first resin side surface 81, at which the die pad 52DB extends out from the first light receiving element 30P in the x-direction by a large amount.

As shown in FIGS. 5 and 6, the first light receiving element 30P is arranged closer to one of the two ends of the die pad 52DB in the x-direction that is located closer to the second resin side surface 82 (refer to FIG. 5). Hence, the portion of the die pad 52DB extending out from the first light receiving element 30P toward the second resin side surface 82 is smaller in dimension in the x-direction than the portion of the die pad 52DB extending out from the first light receiving element 30P toward the first resin side surface 81. As viewed in the z-direction, the dimension, in the x-direction, of the portion of the die pad 52DB extending out from the first light receiving element 30P toward the second resin side surface 82 is determined by the distance in the x-direction between the first light receiving element 30P and one of the two side surfaces of the first element mount 53D of the die pad 52DB in the x-direction that is located closer to the second resin side surface 82. As viewed in the z-direction, the dimension, in the x-direction, of the portion of the die pad 52DB extending out from the first light receiving element 30P toward the first resin side surface 81 is determined by the distance in the x-direction between the first light receiving element 30P and one of the two side surfaces of the first element mount 53D of the die pad 52DB in the x-direction that is located closer to the first resin side surface 81.

As shown in FIG. 6, as viewed in the z-direction, the first light receiving element 30P overlaps the recess 59DC in the die pad 52DB. The recess 59DC is arranged closer to the first resin side surface 81 than the center of the first light receiving element 30P in the x-direction. In other words, the first light receiving element 30P is offset in the x-direction toward the second resin side surface 82 with respect to the recess 59DC.

As shown in FIG. 6, the thickness of the first light emitting element 20P (dimension of the first light emitting element 20P in the z-direction) is less than the thickness of the first light receiving element 30P (dimension of the first light receiving element 30P in the z-direction). In the present embodiment, the thickness of the first light emitting element 20P is in a range of 80% to 90% of the thickness of the first light receiving element 30P. The thickness of the first light emitting element 20P is determined by the distance between the element main surface 20Ps and the element back surface 20Pr of the first light emitting element 20P in the thickness-wise direction. The thickness of the first light receiving element 30P is determined by the distance between the element main surface 30Ps and the element back surface 30Pr in the thickness-wise direction of the first light receiving element 30P.

The relationship between the thickness of the first light emitting element 20P and the thickness of the first light receiving element 30P may be changed in any manner. In an example, the thickness of the first light emitting element 20P is greater than or equal to 90% and less than 100% of the thickness of the first light receiving element 30P. The thickness of the first light emitting element 20P may be greater than or equal to 70% and less than 80% of the thickness of the first light receiving element 30P. In another example, the thickness of the first light emitting element 20P may be greater than or equal to 60% and less than 70% of the thickness of the first light receiving element 30P. In another example, the thickness of the first light emitting element 20P may be greater than or equal to 50% and less than 60% of the thickness of the first light receiving element 30P.

As shown in FIGS. 2 and 6, the die pad 52DB and the die pad 42BB overlap each other as viewed in the z-direction. The die pad 42BB is separated from the die pad 52DB and arranged closer to the resin main surface 80s (refer to FIG. 5) in the z-direction. In other words, the die pad 52DB is separated from the die pad 42BB and arranged closer to the resin back surface 80r (refer to FIG. 5) in the z-direction.

The die pad 42BB and the die pad 52DB are arranged in the x-direction so that one of the two ends of the die pad 42BB in the x-direction that is located closer to the first resin side surface 81 overlaps one of the two ends of the die pad 52DB in the x-direction that is located closer to the first resin side surface 81 as viewed in the z-direction. Since the die pad 52DB is greater than the die pad 42BB in dimension in the x-direction, as viewed in the z-direction, the die pad 52DB has an extension extending from the die pad 42BB toward the second resin side surface 82. In addition, the die pads 42BB and 52DB are arranged so that as viewed in the z-direction, the recess 46B of the die pad 42BB overlaps the recess 59DC of the die pad 52DB. In other words, the die pad 42BB and the die pad 52DB are arranged so that the recess 46B and the recess 59DC are opposed to each other in the z-direction.

Therefore, as shown in FIG. 6, as viewed in the z-direction, the first light emitting element 20P overlaps the first light receiving element 30P. In the present embodiment, the first light emitting element 20P is offset toward the first resin side surface 81 with respect to the first light receiving element 30P in the x-direction. In the present embodiment, as viewed in the z-direction, the first light emitting element 20P is arranged to overlap one of the two ends of the first light receiving element 30P in the x-direction that is located closer to the first resin side surface 81. More specifically, as viewed in the z-direction, the first light emitting element 20P and the first light receiving element 30P are arranged so that one of the two side surfaces of the first light emitting element 20P in the x-direction that is located closer to the first resin side surface 81 is aligned with one of the two side surfaces of the first light receiving element 30P in the x-direction that is located closer to the first resin side surface 81. The light receiving surface 33P of the first light receiving element 30P is arranged on the element main surface 30Ps toward the first resin side surface 81. Thus, the first light emitting element 20P is offset toward the first semiconductor region with respect to the first light receiving element 30P in the x-direction. Accordingly, the element main surface 20Ps, which is the light emitting surface of the first light emitting element 20P, is opposed to the light receiving surface 33P of the first light receiving element 30P in the z-direction. In other words, the light receiving surface 33P is spaced apart and faced to the element main surface 20Ps (light emitting surface).

As shown in FIG. 9, the insulation module 10 includes the first transparent resin 60P, the second transparent resin 60Q, the first plate-shaped member 70P, and the second plate-shaped member 70Q.

The transparent resins 60P and 60Q are formed from, for example, a transparent epoxy resin, acrylic resin, or silicone resin. In the present embodiment, the first transparent resin 60P is formed from an insulative resin that allows passage of light (first wavelength light) from the first light emitting element 20P. Preferably, the resin material of the first transparent resin 60P is formed from an insulative resin that blocks light (that does not allow passage of light) from the second light emitting element 20Q. The second transparent resin 60Q is formed from an insulative resin that allows passage of light (second wavelength light) from the second light emitting element 20Q. Preferably, the resin material of the second transparent resin 60Q is formed from an insulative resin that blocks light (that does not allow passage of light) from the second light emitting element 20Q. The transparent resins 60P and 60Q are formed, for example, by a potting process.

The first transparent resin 60P is arranged at least between the element main surface 20Ps of the first light emitting element 20P and the light receiving surface 33P of the first light receiving element 30P. The first transparent resin 60P covers the first light emitting element 20P and the first light receiving element 30P. The first transparent resin 60P covers at least the element main surface 20Ps of the first light emitting element 20P and the light receiving surface 33P of the first light receiving element 30P. At least a portion of the second transparent resin 60Q is arranged between the element main surface 20Qs of the second light emitting element 20Q and the light receiving surface 33Q of the second light receiving element 30Q. The second transparent resin 60Q covers the second light emitting element 20Q and the second light receiving element 30Q. The second transparent resin 60Q covers at least the element main surface 20Qs of the second light emitting element 20Q and the light receiving surface 33Q of the second light receiving element 30Q. The first transparent resin 60P and the second transparent resin 60Q are aligned with each other in the x-direction and spaced apart from each other in the y-direction.

Each of the plate-shaped members 70P and 70Q is formed from a light-transmissive, electrically insulating material. The first plate-shaped member 70P insulates the first light emitting element 20P from the first light receiving element 30P while allowing optical communication between the first light emitting element 20P and the first light receiving element 30P. The second plate-shaped member 70Q insulates the second light emitting element 20Q from the second light receiving element 30Q while allowing optical communication between the second light emitting element 20Q and the second light receiving element 30Q.

The first plate-shaped member 70P is arranged on the first transparent resin 60P. The second plate-shaped member 70Q is arranged on the second transparent resin 60Q. As shown in FIG. 6, the first plate-shaped member 70P extends through the first transparent resin 60P. Also, although not shown, the second plate-shaped member 70Q extends through the second transparent resin 60Q. The first plate-shaped member 70P and the second plate-shaped member 70Q are aligned with each other in the x-direction and spaced apart from each other in the y-direction.

In the present embodiment, the transmittance of the first plate-shaped member 70P is lower than the transmittance of the first transparent resin 60P. In an example, the first plate-shaped member 70P is formed from a material, the transmittance of which is lower than the transmittance of the first transparent resin 60P.

The transmittance of the first plate-shaped member 70P may be changed in any manner. In an example, the transmittance of the first plate-shaped member 70P may be higher than or equal to the transmittance of the first transparent resin 60P. In other words, the transmittance of the first transparent resin 60P may be lower than the transmittance of the first plate-shaped member 70P.

The first plate-shaped member 70P is formed from an insulative resin that allows passage of light (first wavelength light) from the first light emitting element 20P. The first plate-shaped member 70P may be formed from an insulative resin that blocks light (that does not allow passage of light) from the second light emitting element 20Q. The second plate-shaped member 70Q is formed from an insulative resin that allows passage of light (second wavelength light) from the second light emitting element 20Q. The second plate-shaped member 70Q may be formed from an insulative resin that blocks light (that does not allow passage of light) from the first light emitting element 20P. In this case, each of the transparent resins 60P and 60Q may be formed from a resin material that allows passage of the first wavelength light and the second wavelength light.

As shown in FIG. 9, the encapsulation resin 80 covers the first transparent resin 60P, the second transparent resin 60Q, the first plate-shaped member 70P, and the second plate-shaped member 70Q. More specifically, the encapsulation resin 80 covers the first transparent resin 60P, the first light emitting element 20P, the first light receiving element 30P, and the first plate-shaped member 70P. The encapsulation resin 80 covers the second transparent resin 60Q, the second light emitting element 20Q, the second light receiving element 30Q, and the second plate-shaped member 70Q.

The encapsulation resin 80 includes a separation wall 89 arranged between the first transparent resin 60P and the second transparent resin 60Q in the y-direction and between the first plate-shaped member 70P and the second plate-shaped member 70Q in the y-direction. As viewed in the z-direction, the separation wall 89 overlaps the through hole 55D and the recess 56D (refer to FIG. 4) in the die pad 52DB of the second lead frame 50D.

The structure of the first plate-shaped member 70P and the second plate-shaped member 70Q will now be described in detail.

The first plate-shaped member 70P and the second plate-shaped member 70Q are identical to each other in shape. The arrangement of the first plate-shaped member 70P with the first light emitting element 20P and the first light receiving element 30P is the same as the arrangement of the second plate-shaped member 70Q with the second light emitting element 20Q and the second light receiving element 30Q. In the description hereafter, the first plate-shaped member 70P will be described in detail, and the second plate-shaped member 70Q will not be described in detail.

As shown in FIG. 6, the first plate-shaped member 70P is arranged between the first light emitting element 20P and the first light receiving element 30P. More specifically, the first plate-shaped member 70P is disposed between the element main surface 20Ps (light emitting element) of the first light emitting element 20P and the light receiving surface 33P of the first light receiving element 30P. The first plate-shaped member 70P includes two ends in the x-direction, namely, a first end 71P and a second end 72P. The first end 71P is one of the two ends of the first plate-shaped member 70P in the x-direction located closer to the first resin side surface 81. The second end 72P is one of the two ends of the first plate-shaped member 70P in the x-direction located closer to the second resin side surface 82.

As viewed in the z-direction, the first plate-shaped member 70P extends out from the die pads 42BB and 52DB in the x-direction. As viewed in the z-direction, the first end 71P of the first plate-shaped member 70P is arranged closer to the first resin side surface 81 than the die pads 42BB and 52DB are. The second end 72P is arranged closer to the second resin side surface 82 than the die pads 42BB and 52DB are.

The first end 71P is arranged between the die pad 42BB and the die pad 52DB in the z-direction. The first end 71P is arranged closer to the die pad 52DB than the center of the die pad 42BB and the die pad 52DB in the z-direction is. As viewed in the x-direction, the first end 71P overlaps the first light receiving element 30P.

The second end 72P is arranged closer to the resin main surface 80s than the first surface 42Bs of the die pad 42BB and closer to the resin back surface 80r than the second surface 42Br in the z-direction. Thus, as viewed in the x-direction, the second end 72P overlaps the die pad 42BB.

The first plate-shaped member 70P extends and is inclined from the element main surface 20Ps of the first light emitting element 20P and the light receiving surface 33P of the first light receiving element 30P. More specifically, the first end 71P of the first plate-shaped member 70P is located closest to the resin back surface 80r in the z-direction in the first plate-shaped member 70P. The second end 72P is located closest to the resin main surface 80s in the z-direction in the first plate-shaped member 70P. That is, the first plate-shaped member 70P is inclined from the resin back surface 80r toward the resin main surface 80s as the first plate-shaped member 70P extends from the first end 71P toward the second end 72P.

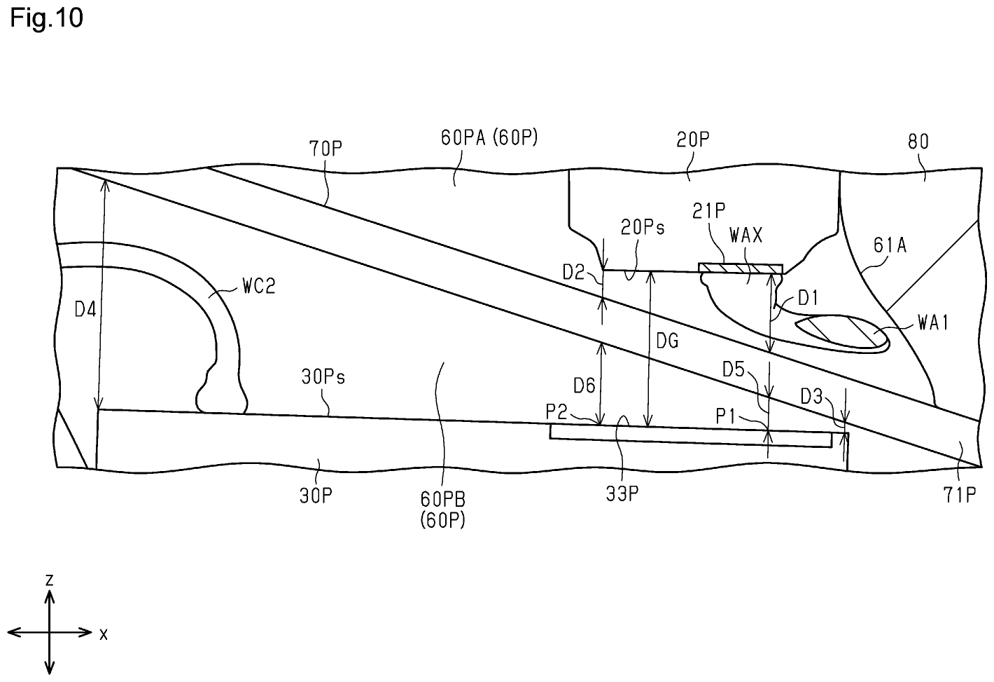

As shown in FIG. 10, the distance between the element main surface 20Ps of the first light emitting element 20P and the first plate-shaped member 70P in the z-direction is decreased from the first end 71P toward the second end 72P (refer to FIG. 6). In other words, the distance between the element main surface 20Ps of the first light emitting element 20P and the first plate-shaped member 70P in the z-direction is decreased from the first resin side surface 81 toward the second resin side surface 82. The element main surface 20Ps includes a first end that is one of the two ends in the x-direction located closer to the first resin side surface 81. A distance D1 in the z-direction between the first end and the first plate-shaped member 70P corresponding to the first end in the z-direction is the maximum distance between the element main surface 20Ps of the first light emitting element 20P and the first plate-shaped member 70P in the z-direction. The distance D1 also refers to the maximum distance between the first electrode 21P and the first plate-shaped member 70P opposed to the first electrode 21P. The element main surface 20Ps includes a second end that is one of the two ends in the x-direction located closer to the second resin side surface 82. A distance D2 in the z-direction between the second end and the first plate-shaped member 70P corresponding to the second end in the z-direction is the minimum distance between the element main surface 20Ps of the first light emitting element 20P and the first plate-shaped member 70P in the z-direction.

The distance between the element main surface 30Ps of the first light receiving element 30P and the first plate-shaped member 70P in the z-direction is increased from the first end 71P toward the second end 72P. In other words, the distance between the element main surface 30Ps of the first light receiving element 30P and the first plate-shaped member 70P in the z-direction is increased from the first resin side surface 81 toward the second resin side surface 82. A distance D3 in the z-direction between one of the two ends of the element main surface 30Ps in the x-direction that is located closer to the first resin side surface 81 and the first plate-shaped member 70P corresponding to the end of the element main surface 30Ps in the z-direction is the minimum distance between the element main surface 30Ps of the first light receiving element 30P and the first plate-shaped member 70P in the z-direction. A distance D4 in the z-direction between one of the two ends of the element main surface 30Ps in the x-direction that is located closer to the second resin side surface 82 and the first plate-shaped member 70P corresponding to the end of the element main surface 30Ps in the z-direction is the maximum distance between the element main surface 30Ps of the first light receiving element 30P and the first plate-shaped member 70P in the z-direction.

In the present embodiment, the distance D1 is greater than the distance D3. The distance D2 is greater than the distance D3. The distance D4 is greater than the distance D2. The distance D4 is greater than the distance D1. The distance D4 is greater than a distance DG between the first light emitting element 20P and the first light receiving element 30P in the z-direction. The distance D1 is less than the thickness of the first light emitting element 20P. The distance D1 is less than the thickness of the first light receiving element 30P. The distance D1 is greater than or equal to ½ of the distance DG.

The minimum distance between the first electrode 21P and the first plate-shaped member 70P opposed to the first electrode 21P is less than ½ of the distance DG. The minimum distance between the first electrode 21P and the first plate-shaped member 70P opposed to the first electrode 21P is determined by the distance in the z-direction between one of the two ends of the first electrode 21P in the x-direction that is located closer to the second resin side surface 82 and the first plate-shaped member 70P overlapping the end of the first electrode 21P in the z-direction.

A position P1 on the element main surface 30Ps of the first light receiving element 30P is opposed to the first end of the element main surface 20Ps of the first light emitting element 20P in the z-direction. A distance D5 between the position P1 of the element main surface 30Ps and the first plate-shaped member 70P in the z-direction is less than ½ of the distance DG. The distance D5 is less than ⅓ of the distance DG. In the example shown, the distance D5 is approximately ⅙ of the distance DG. The distance D2 is less than ½ of the distance DG. The distance D2 is less than ⅓ of the distance DG. In the example shown, the distance D2 is approximately ⅙ of the distance DG.

A position P2 on the element main surface 30Ps of the first light receiving element 30P is opposed to the second end of the element main surface 20Ps of the first light emitting element 20P in the z-direction. A distance D6 between the position P2 of the element main surface 30Ps and the first plate-shaped member 70P in the z-direction is approximately ½ of the distance DG. The distance D1 is approximately ½ of the distance DG.

The distance DG is less than the thickness of the first light receiving element 30P. The distance DG is less than or equal to 90% of the thickness of the first light receiving element 30P. The distance DG may be less than or equal to 80% of the thickness of the first light receiving element 30P. The distance DG may be less than or equal to 70% of the thickness of the first light receiving element 30P. In an example, the distance DG is approximately 65% of the thickness of the first light receiving element 30P.

The distance DG is less than the thickness of the first light emitting element 20P. The distance DG is less than or equal to 90% of the thickness of the first light emitting element 20P. In an example, the distance DG is approximately 80% of the thickness of the first light emitting element 20P.

As shown in FIG. 6, the first plate-shaped member 70P separates the first transparent resin 60P into a light-emitting-side transparent resin 60PA covering the first light emitting element 20P and a light-receiving-side transparent resin 60PB covering the first light receiving element 30P.

The light-emitting-side transparent resin 60PA is arranged between the first plate-shaped member 70P and the first light emitting element 20P. The light-emitting-side transparent resin 60PA covers at least the entirety of the element main surface 20Ps of the first light emitting element 20P. In the present embodiment, the light-emitting-side transparent resin 60PA covers a portion of the die pad 42BB that is located toward the second resin side surface 82 (refer to FIG. 5) from the first light emitting element 20P. More specifically, the die pad 42BB includes a first extension 47BA extending from the first light emitting element 20P toward the first resin side surface 81 (refer to FIG. 5) and a second extension 47BB extending from the first light emitting element 20P toward the second resin side surface 82. In a cross-sectional structure of the conductive bonding material 90P cut along the xz-plane, the second bonding region 92P of the conductive bonding material 90P includes a first part 92PA arranged on the first extension 47BA and a second part 92PB arranged on the second extension 47BB. The light-emitting-side transparent resin 60PA is in contact with the second extension 47BB and the second part 92PB. The light-emitting-side transparent resin 60PA fills between the first plate-shaped member 70P and each of the second extension 47BB and the second part 92PB in the z-direction. In the present embodiment, the light-emitting-side transparent resin 60PA is arranged beyond the second extension 47BB toward the second resin side surface 82.

In a cross-sectional structure of the light-emitting-side transparent resin 60PA cut along the xz-plane, the light-emitting-side transparent resin 60PA spreads from the die pad 42BB toward the first plate-shaped member 70P in the x-direction. More specifically, the light-emitting-side transparent resin 60PA is in contact with the tapered portion of the first light emitting element 20P located toward the element main surface 20Ps and is inclined toward the first resin side surface 81 from the tapered portion toward the first plate-shaped member 70P. The light-emitting-side transparent resin 60PA is in contact with a portion of the side surface of the second extension 47BB in the x-direction located near the first surface 42Bs and is inclined toward the second resin side surface 82 from the side surface of the second extension 47BB in the x-direction toward the first plate-shaped member 70P.

As shown in FIG. 6, in a cross-sectional structure of the light-emitting-side transparent resin 60PA cut along the xz-plane, curved surfaces 61A and 62A are formed on two ends of the light-emitting-side transparent resin 60PA in the x-direction. In the present embodiment, each of the curved surfaces 61A and 62A corresponds to a “side surface of light-emitting-side transparent resin.”

The curved surface 61A is curved to have a center of curvature CA located upward from the curved surface 61A. That is, the center of curvature CA is located toward the die pad 42BB with respect to the curved surface 61A in the z-direction. The curved surface 61A is curved so that the center of curvature CA is located on a side of the curved surface 61A opposite the first plate-shaped member 70P. One of the two ends of the curved surface 61A in the x-direction that is located closer to the first resin side surface 81 (refer to FIG. 5) is arranged closer to the first light emitting element 20P in the x-direction than one of the two ends of the die pad 42BB in the x-direction that is located closer to the first resin side surface 81. One of the two ends of the curved surface 61A in the x-direction that is located closer to the first resin side surface 81 is arranged closer to the first resin side surface 81 in the x-direction with respect to the second bonding region 92P of the conductive bonding material 90P. In the present embodiment, the one of the two ends of the curved surface 61A in the x-direction located closer to the first resin side surface 81 is arranged closer to the first light receiving element 30P than the wires WA1 in the z-direction.

The curved surface 62A is curved to have a center of curvature CB located upward from the curved surface 62A. That is, the center of curvature CB is located toward the resin main surface 80s (refer to FIG. 5) with respect to the curved surface 62A in the z-direction. The curved surface 62A is curved so that the center of curvature CB is located on a side of the curved surface 62A opposite the first plate-shaped member 70P.

The light-emitting-side transparent resin 60PA does not cover one of the two side surfaces of the first light emitting element 20P in the x-direction that is located closer to the first extension 47BA, the first part 92PA of the second bonding region 92P of the conductive bonding material 90P, and the first extension 47BA. Thus, the encapsulation resin 80 covers the one of the two side surfaces of the first light emitting element 20P in the x-direction that is located closer to the first extension 47BA, the first part 92PA of the second bonding region 92P of the conductive bonding material 90P, and the first extension 47BA.

The light-receiving-side transparent resin 60PB is arranged between the first plate-shaped member 70P and the first light receiving element 30P. The light-receiving-side transparent resin 60PB covers at least the entirety of the element main surface 30Ps of the first light receiving element 30P. In the present embodiment, the light-receiving-side transparent resin 60PB covers two side surfaces of the first light receiving element 30P in the x-direction and a portion of the conductive bonding material 100P. The portion of the conductive bonding material 100P is a region of the second bonding region 102P of the conductive bonding material 100P bonded to the side surface of the first light receiving element 30P located closer to the first resin side surface 81 in the x-direction. The light-receiving-side transparent resin 60PB is not in contact with the remaining conductive bonding material 100P and the die pad 52DB. Thus, the remaining conductive bonding material 100P and the die pad 52DB are covered by the encapsulation resin 80.

As viewed in the z-direction, the light-receiving-side transparent resin 60PB is arranged beyond the die pad 52DB toward the second resin side surface 82. In the present embodiment, as viewed in the z-direction, the light-receiving-side transparent resin 60PB extends beyond the light-emitting-side transparent resin 60PA toward the second resin side surface 82 in the x-direction.

In a cross-sectional structure of the light-receiving-side transparent resin 60PB cut along the xz-plane, the light-receiving-side transparent resin 60PB spreads in the x-direction from the die pad 52DB toward the first plate-shaped member 70P. More specifically, the light-receiving-side transparent resin 60PB is in contact with two side surfaces of the first light receiving element 30P in the x-direction and spreads in the x-direction from the side surfaces toward the first plate-shaped member 70P.

As shown in FIG. 6, in a cross-sectional structure of the light-receiving-side transparent resin 60PB cut along the xz-plane, curved surfaces 61B and 62B are formed on two ends of the light-receiving-side transparent resin 60PB in the x-direction. In the present embodiment, each of the curved surfaces 61B and 62B corresponds to a “side surface of light-receiving-side transparent resin.”

The curved surface 61B is curved to have a center of curvature CC located downward from the curved surface 61B. That is, the center of curvature CC is located toward the die pad 52DB with respect to the curved surface 61B in the z-direction. In other words, the curved surface 61B is curved so that the center of curvature CC is located on a side of the curved surface 61B opposite the first plate-shaped member 70P. One of the two ends of the curved surface 61B in the x-direction that is located closer to the first resin side surface 81 is arranged closer to the first resin side surface 81 in the x-direction with respect to the second bonding region 102P of the conductive bonding material 100P.

The curved surface 62B is curved to have a center of curvature CD located downward from the curved surface 62B. That is, the center of curvature CD is located toward the resin back surface 80r (refer to FIG. 5) with respect to the curved surface 62B in the z-direction. The curved surface 62B is curved so that the center of curvature CD is located on a side of the curved surface 62B opposite the first plate-shaped member 70P.

As shown in FIG. 9, the second transparent resin 60Q includes a light-emitting-side transparent resin 60QA and a light-receiving-side transparent resin 60QB separated from each other by the second plate-shaped member 70Q. The light-emitting-side transparent resin 60QA is identical in shape to the light-emitting-side transparent resin 60PA. The light-receiving-side transparent resin 60QB is identical in shape to the light-receiving-side transparent resin 60PB.

As shown in FIG. 7, the first electrode 21P, which is a portion of the element main surface 20Ps of the first light emitting element 20P connected to the wire WA1, is offset from the center of the element main surface 20Ps of the first light emitting element 20P in the x-direction. More specifically, the first electrode 21P is offset in the x-direction from the center of the element main surface 20Ps of the first light emitting element 20P toward a portion at which the distance to the first plate-shaped member 70P is greater than that at the center. In the present embodiment, the first electrode 21P is offset in the x-direction from the center of the element main surface 20Ps of the first light emitting element 20P toward the first resin side surface 81 (refer to FIG. 5). More specifically, the first electrode 21P is arranged on one of the two ends of the element main surface 20Ps in the x-direction that is located closer to the first resin side surface 81. In the present embodiment, the first electrode 21P corresponds to a “pad.”

As shown in FIG. 10, as viewed in the z-direction, the first electrode 21P overlaps a position that is offset from the center of the light receiving surface 33P of the first light receiving element 30P in the x-direction. More specifically, as viewed in the z-direction, the first electrode 21P is offset to overlap a portion of the light receiving surface 33P at which the distance between the element main surface 20Ps and the first plate-shaped member 70P is greater than the distance at the center of the light receiving surface 33P in the x-direction. More specifically, as viewed in the z-direction, the first electrode 21P overlaps one of the two ends of the light receiving surface 33P in the x-direction that is located closer to the first resin side surface 81.

The wire WA1 includes a connecting part WAX connected to the first electrode 21P of the first light emitting element 20P. The connecting part WAX is offset from the center of the element main surface 20Ps of the first light emitting element 20P in the x-direction. More specifically, the connecting part WAX is offset in the x-direction from the center of the element main surface 20Ps of the first light emitting element 20P toward a portion at which the distance to the first plate-shaped member 70P is greater than at the center. In the present embodiment, the connecting part WAX is offset in the x-direction from the center of the element main surface 20Ps of the first light emitting element 20P toward the first resin side surface 81. More specifically, the connecting part WAX is arranged on one of the two ends of the element main surface 20Ps in the x-direction that is located closer to the first resin side surface 81. The connecting part WAX is covered by the light-emitting-side transparent resin 60PA.

As viewed in the z-direction, the connecting part WAX overlaps a position that is offset from the center of the light receiving surface 33P of the first light receiving element 30P in the x-direction. More specifically, as viewed in the z-direction, the connecting part WAX is offset to overlap a portion of the light receiving surface 33P at which the distance between the element main surface 20Ps and the first plate-shaped member 70P is greater than that at the center of the light receiving surface 33P in the x-direction. More specifically, as viewed in the z-direction, the connecting part WAX overlaps one of the two ends of the light receiving surface 33P in the x-direction that is located closer to the first resin side surface 81. The wire WA1 extends from the connecting part WAX toward the first resin side surface 81. In other words, the wire WA1 extends from the connecting part WAX into the space in which the distance between the element main surface 20Ps and the first plate-shaped member 70P is increased. As viewed in the z-direction, the wire WA1 overlaps only one of the two ends of the light receiving surface 33P in the x-direction that is located closer to the first resin side surface 81.

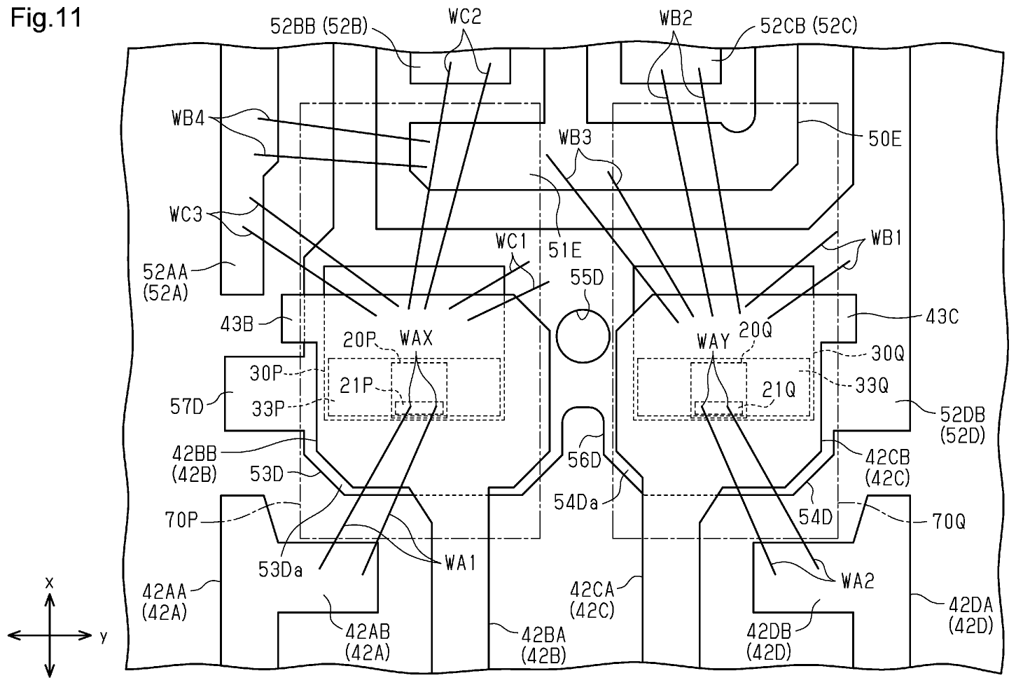

FIG. 11 is a plan view showing the first light emitting element 20P and the second light emitting element 20Q in the z-direction. In FIG. 11, the first transparent resin 60P and the second transparent resin 60Q are omitted for the sake of convenience.

As shown in FIG. 11, the two wires WA1 are connected to the first electrode 21P of the first light emitting element 20P. The connecting part WAX of each of the two wires WA1 is offset in the x-direction from the center of the element main surface 20Ps of the first light emitting element 20P (refer to FIG. 6) toward a portion at which the distance to the first plate-shaped member 70P is greater than that at the center. The connecting parts WAX of the two wires WA1 are aligned with each other in the x-direction and spaced apart from each other in the y-direction. The two wires WA1 extend away from each other from the connecting part WAX toward the wire connector 42AB.

The two wires WA2 are connected to the first electrode 21Q of the second light emitting element 20Q. The two wires WA2 include connecting parts WAY offset in the x-direction from the center of the element main surface 20Qs of the second light emitting element 20Q (refer to FIG. 9) toward a portion at which the distance to the first plate-shaped member 70P is greater than that at the center. The connecting parts WAY of the two wires WA2 are aligned with each other in the x-direction and spaced apart from each other in the y-direction. The two wires WA2 extend away from each other from the connecting part WAY toward the wire connector 42DB.

Internal Structure of Light Receiving Element

An example of the structure of the first light receiving element 30P will now be partially described with reference to FIG. 12. FIG. 12 is a schematic cross-sectional view of the element main surface 30Ps showing the cross-sectional structure of the first light receiving element 30P and its surroundings. The second light receiving element 30Q has the same structure as the first light receiving element 30P and thus will not be described in detail.

As shown in FIG. 12, the first light receiving element 30P includes a semiconductor substrate 34P, an insulation wiring layer 35PC formed on a surface 34Ps of the semiconductor substrate 34P, and an insulation layer 36P formed on the insulation wiring layer 35PC.

The semiconductor substrate 34P defines the element back surface 30Pr of the first light receiving element 30P (refer to FIG. 8). More specifically, the semiconductor substrate 34P includes a back surface (not shown) facing in a direction opposite from the surface 34Ps. The back surface includes the element back surface 30Pr. The semiconductor substrate 34P is formed of a substrate formed from a material including, for example, silicon (Si). The semiconductor substrate 34P includes a first semiconductor region 34PA in which an optical-electrical conversion element 35PA is arranged. The semiconductor substrate 34P includes a second semiconductor region 34PB in which a control circuit 35PB is arranged. The control circuit 35PB is, for example, configured to receive a signal from the optical-electrical conversion element 35PA.

The insulation wiring layer 35PC includes wiring that electrically connects the optical-electrical conversion element 35PA and the control circuit 35PB. As viewed in the z-direction, the insulation wiring layer 35PC overlaps both the optical-electrical conversion element 35PA and the control circuit 35PB.

The insulation layer 36P is formed on the optical-electrical conversion element 35PA and the control circuit 35PB. More specifically, the insulation layer 36P is arranged over the first semiconductor region 34PA and the second semiconductor region 34PB of the semiconductor substrate 34P. In the present embodiment, the insulation layer 36P is formed on the entirety of the insulation wiring layer 35PC.

The insulation layer 36P includes a first insulation portion 36PA formed on the optical-electrical conversion element 35PA and a second insulation portion 36PB formed on the control circuit 35PB. The first insulation portion 36PA corresponds to the first semiconductor region 34PA. The second insulation portion 36PB corresponds to the second semiconductor region 34PB. The insulation layer 36P includes a surface 36Ps including the element main surface 30Ps. A portion of the surface 36Ps of the insulation layer 36P corresponding to the first insulation portion 36PA includes the light receiving surface 33P.

The insulation layer 36P includes insulation films 37PA to 37PE stacked on one another in the z-direction, wiring layers 38PAto 38PE arranged in the insulation films 37PA to 37PE, and vias 39PA to 39PD connecting the wiring layers 38PAto 38PE. In the present embodiment, the wiring layers 38PAto 38PE and the vias 39PAto 39PD are arranged in the second insulation portion 36PB. In other words, in the present embodiment, the wiring layers 38PA to 38PE and the vias 39PA to 39PD are not arranged in the first insulation portion 36PA. In the present embodiment, each of the wiring layers 38PA to 38PE arranged in the second insulation portion 36PB corresponds to a “first wiring layer.”

As shown in FIG. 12, the insulation films 37PA to 37PE are stacked on the insulation wiring layer 35PC in this order. Each of the insulation films 37PA to 37PE is an interlayer insulation film formed from, for example, silicon oxide (SiO₂).

In the present embodiment, the wiring layers 38PAto 38PE mainly form wiring connected to the control circuit 35PB and are arranged in the second insulation portion 36PB of the insulation layer 36P. In other words, the wiring layers 38PAto 38PE are not arranged in the first insulation portion 36PA of the insulation layer 36P. In the example shown, the wiring layers 38PA to 38PE overlap each other as viewed in the z-direction. The wiring layers 38PA to 38PE are formed from a metal material such as Al or titanium (Ti).

The wiring layer 38PA is embedded in the insulation film 37PA. The wiring layer 38PA is, for example, electrically connected to the semiconductor substrate 34P.

The wiring layer 38PB is embedded in the insulation film 37PB. The wiring layer 38PA and the wiring layer 38PB are connected by the vias 39PA. Each via 39PA is embedded in the insulation film 37PA and extends in the z-direction.

The wiring layer 38PC is embedded in the insulation film 37PC. The wiring layer 38PB and the wiring layer 38PC are connected by the vias 39PB. Each via 39PB is embedded in the insulation film 37PB and extends in the z-direction.

The wiring layer 38PD is embedded in the insulation film 37PD. The wiring layer 38PC and the wiring layer 38PD are connected by the vias 39PC. Each via 39PC is embedded in the insulation film 37PC and extends in the z-direction.

The wiring layer 38PE is embedded in the insulation film 37PE. The wiring layer 38PD and the wiring layer 38PE are connected by the vias 39PD. Each via 39PD is embedded in the insulation film 37PD and extends in the z-direction.

In the present embodiment, the wiring layers 38PAto 38PE are respectively arranged for the insulation films 37PA to 37PE. However, there is no limit to this structure. The second insulation portion 36PB may include an insulation film that is free of a wiring layer.

Structure of Perimeter of Encapsulation Resin

The structures of the encapsulation resin 80 between the terminals 41A to 41D and between the terminals 51A to 51D will now be described with reference to FIGS. 13 and 14. FIG. 13 is a plan view of the insulation module 10 showing the terminals 41A to 41D and a portion of the encapsulation resin 80. FIG. 14 is a plan view of the insulation module 10 showing the terminals 51A to 51D and a portion of the encapsulation resin 80.

As shown in FIGS. 3 and 13, the first resin side surface 81 of the encapsulation resin 80 includes recess-projection portions 87 arranged between adjacent ones of the terminals 41A to 41D in the y-direction. More specifically, the recess-projection portions 87 are arranged on a portion of the first resin side surface 81 between the terminal 41A and the terminal 41B in the y-direction, a portion of the first resin side surface 81 between the terminal 41B and the terminal 41C in the y-direction, and a portion of the first resin side surface 81 between the terminal 41C and the terminal 41D in the y-direction. The recess-projection portions 87 are formed in the entirety of the first resin side surface 81 in the z-direction. Each recess-projection portion 87 is formed of the first resin side surface 81 and a recess 87a recessed from the first resin side surface 81.

The recess-projection portion 87 includes, for example, multiple (in the present embodiment, three) recesses 87a. Each recess 87a extends through the encapsulation resin 80 in the z-direction. In the present embodiment, the recess 87a includes a bottom surface that is parallel to the first side surface 85 and the second side surface 86 (refer to FIG. 5) of the first resin side surface 81. More specifically, the bottom surface of the recess 87a includes a portion corresponding to the first side surface 85 that extends from the resin main surface 80s toward the resin back surface 80r (refer to FIG. 5) inclining toward an outer side of the encapsulation resin 80 in the x-direction. The bottom surface of the recess 87a includes a portion corresponding to the second side surface 86 that extends from the resin back surface 80r toward the resin main surface 80s inclining toward an outer side of the encapsulation resin 80 in the x-direction.

As shown in FIGS. 4 and 14, the second resin side surface 82 of the encapsulation resin 80 includes recess-projection portions 88 arranged between adjacent ones of the terminals 51A to 51D in the y-direction. More specifically, the recess-projection portions 88 are arranged on a portion of the second resin side surface 82 between the terminal 51A and the terminal 51B in the y-direction, a portion of the second resin side surface 82 between the terminal 51B and the terminal 51C in the y-direction, and a portion of the second resin side surface 82 between the terminal 51C and the terminal 51D in the y-direction. More specifically, the recess-projection portions 88 are arranged on a portion of the second resin side surface 82 between the terminal 51A and the suspension lead 58D in the y-direction, a portion of the second resin side surface 82 between the suspension lead 58D and the terminal 51B in the y-direction, a portion of the second resin side surface 82 between the terminal 51B and the second suspension lead 53E in the y-direction, a portion of the second resin side surface 82 between the second suspension lead 53E and the terminal 51C in the y-direction, a portion of the second resin side surface 82 between the terminal 51C and the first suspension lead 52E in the y-direction, and a portion of the second resin side surface 82 between the first suspension lead 52E and the terminal 51D in the y-direction.

The recess-projection portions 88 are formed in the entirety of the second resin side surface 82 in the z-direction. Each recess-projection portion 88 is formed of the second resin side surface 82 and a recess 88a recessed from the second resin side surface 82. The recess-projection portion 88 includes, for example, multiple (in the present embodiment, three) recesses 88a. Each recess 88a extends through the encapsulation resin 80 in the z-direction. In the present embodiment, the recess 88a includes a bottom surface that is parallel to the first side surface 85 and the second side surface 86 (refer to FIG. 1) of the first resin side surface 81. More specifically, the bottom surface of the recess 88a includes a portion corresponding to the first side surface 85 that extends from the resin main surface 80s toward the resin back surface 80r (refer to FIG. 5) inclining toward an outer side of the encapsulation resin 80 in the x-direction. The bottom surface of the recess 88a includes a portion corresponding to the second side surface 86 that extends from the resin back surface 80r toward the resin main surface 80s inclining toward an outer side of the encapsulation resin 80 in the x-direction.

Alternatively, the bottom surface of each of the recesses 87a and 88a may extend in the z-direction. Each of the recess-projection portions 87 and 88 may include any number of the recesses 87a and 88a. Each of the recess-projection portions 87 and 88 may include at least one recess 87a and 88a, respectively. The recess-projection portion 87 may include a projection projecting from the first resin side surface 81 instead of the recess 87a. The recess-projection portion 88 may include a projection projecting from the second resin side surface 82 instead of the recess 88a.

The number of the recess-projection portions 87 may be changed in any manner. The recess-projection portions 87 may be arranged on at least one of a portion of the first resin side surface 81 between the terminal 41A and the terminal 41B in the y-direction, a portion of the first resin side surface 81 between the terminal 41B and the terminal 41C in the y-direction, and a portion of the first resin side surface 81 between the terminal 41C and the terminal 41D in the y-direction.

The number of the recess-projection portions 88 may also be changed in any manner. The recess-projection portions 88 may be arranged on at least one of a portion of the second resin side surface 82 between the terminal 51A and the terminal 51B in the y-direction, a portion of the second resin side surface 82 between the terminal 51B and the terminal 51C in the y-direction, and a portion of the second resin side surface 82 between the terminal 51C and the terminal 51D in the y-direction. More specifically, the recess-projection portions 88 may be arranged on at least one of a portion of the second resin side surface 82 between the terminal 51A and the suspension lead 58D in the y-direction, a portion of the second resin side surface 82 between the suspension lead 58D and the terminal 51B in the y-direction, a portion of the second resin side surface 82 between the terminal 51B and the second suspension lead 53E in the y-direction, a portion of the second resin side surface 82 between the second suspension lead 53E and the terminal 51C in the y-direction, a portion of the second resin side surface 82 between the terminal 51C and the first suspension lead 52E in the y-direction, and a portion of the second resin side surface 82 between the first suspension lead 52E and the terminal 51D in the y-direction.

Manufacturing Method

A method for manufacturing the insulation module 10 will now be briefly described.

The method for manufacturing the insulation module 10 includes, for example, a first lead frame preparing step, a light emitting element mounting step, a first wire forming step, a second lead frame preparing step, a light receiving element mounting step, a second wire forming step, a light-receiving-side transparent resin forming step, a plate-shaped member arranging step, a light-emitting-side transparent resin forming step, a joining step, and an encapsulation resin forming step.

In the first lead frame preparing step, a first frame that includes the first lead frames 40A to 40D is prepared. Subsequently, the first frame is bent so that portions corresponding to the inner leads 42A to 42D of the first lead frames 40A to 40D are bent.

In the light emitting element mounting step, the first light emitting element 20P is die-bonded to the die pad 42BB of the first lead frame 40B, and the second light emitting element 20Q is die-bonded to the die pad 42CB of the first lead frame 40C. More specifically, the conductive bonding material 90P is applied to the first surface 42Bs of the die pad 42BB. The conductive bonding material 90Q is applied to the first surface 42Cs of the die pad 42CB. The first light emitting element 20P is mounted on the conductive bonding material 90P. The second light emitting element 20Q is mounted on the conductive bonding material 90Q. The conductive bonding materials 90P and 90Q are solidified so that the first light emitting element 20P is bonded to the die pad 42BB and the second light emitting element 20Q is bonded to the die pad 42CB.

In the first wire forming step, the wires WA1 are formed to connect the first light emitting element 20P to the wire connector 42AB of the first lead frame 40A, and the wires WA2 are formed to connect the second light emitting element 20Q to the wire connector 42DB of the first lead frame 40D. The wires WA1 and WA2 are formed using a wire bonder.

In the second lead frame preparing step, a second frame that includes the second lead frames 50A to 50D and the intermediate frame 50E is prepared. The second frame is bent so that portions corresponding to the inner leads 52A to 52D of the second lead frames 50A to 50D and portions corresponding to the suspension leads 52E and 53E of the intermediate frame 50E are bent.

In the light receiving element mounting step, the first light receiving element 30P and the second light receiving element 30Q are die-bonded to the die pad 52DB of the second lead frame 50D. More specifically, the conductive bonding material 100P is applied to the first element mount 53D of the die pad 52DB, and the conductive bonding material 100Q is applied to the second element mount 54D of the die pad 52DB. The first light receiving element 30P is mounted on the conductive bonding material 100P. The second light receiving element 30Q is mounted on the conductive bonding material 100Q. The conductive bonding materials 100P and 100Q are solidified so that the first light receiving element 30P and the second light receiving element 30Q are bonded to the die pad 52DB.

In the second wire forming step, the wires WC1 to WC3 are formed to connect the first light receiving element 30P to the second lead frames 50A, 50B, and 50D, and the wires WB1 to WB4 are formed to connect the second light receiving element 30Q to the second lead frames 50A, 50C, and 50D and the intermediate frame 50E. The wires WB1 to WB4 and WC1 to WC3 are formed using a wire bonder.

The light-receiving-side transparent resin forming step is performed subsequent to the second wire forming step. In the light-receiving-side transparent resin forming step, the element main surface 30Ps of the first light receiving element 30P is potted with a first transparent resin, and the element main surface 30Qs of the second light receiving element 30Q is potted with a second transparent resin.

The plate-shaped member arranging step is performed subsequent to the light-receiving-side transparent resin forming step. In the plate-shaped member arranging step, the first plate-shaped member 70P is arranged on the first transparent resin, and the second plate-shaped member 70Q is arranged on the second transparent resin. In this case, due to the wires WC1 to WC3 connected to the first light receiving element 30P, the first plate-shaped member 70P is inclined to become closer to the element main surface 30Ps from the second semiconductor region toward the first semiconductor region of the first light receiving element 30P. Due to the wires WB1 to WB3 connected to the second light receiving element 30Q, the second plate-shaped member 70Q is inclined to become closer to the element main surface 30Qs from the second semiconductor region toward the first semiconductor region of the second light receiving element 30Q.

The light-emitting-side transparent resin forming step is performed subsequent to the plate-shaped member arranging step. In the light-emitting-side transparent resin forming step, the first plate-shaped member 70P is potted with a first transparent resin, and the second plate-shaped member 70Q is potted with a second transparent resin. The first transparent resin in the light-receiving-side transparent resin forming step and the first transparent resin in the light-emitting-side transparent resin forming step are formed from the same material. The second transparent resin in the light-receiving-side transparent resin forming step and the second transparent resin in the light-emitting-side transparent resin forming step are formed from the same material.

The joining step is performed subsequent to the first wire forming step and the light-emitting-side transparent resin forming step. In the joining step, the first lead frames 40A to 40D, on which the light emitting elements 20P and 20Q are mounted, are arranged so that the element main surface 20Ps of the first light emitting element 20P is in contact with the first transparent resin on the first plate-shaped member 70P and the element main surface 20Qs of the second light emitting element 20Q is in contact with the second transparent resin on the second plate-shaped member 70Q. In the joining step, the die pad 42BB and the die pad 52DB are arranged so that the recess 46B and the recess 59DC are opposed to each other.

The encapsulation resin forming step is performed subsequent to the joining step. In the encapsulation resin forming step, the encapsulation resin 80 is formed through, for example, transfer molding. Subsequent to the encapsulation resin forming step, the first lead frames 40A to 40D are cut from the first frame, and the second lead frames 50A to 50D are cut from the second frame. Portions of the first lead frames 40A to 40D and the second lead frames 50A to 50D projecting from the encapsulation resin 80 are bent to form the terminals 41A to 41D and 51A to 51D. The steps described above manufacture the insulation module 10.

Electrical Configuration

The electrical configuration of the insulation module 10 will now be described. FIG. 15 is a circuit diagram schematically showing the circuit structure of the insulation module 10 and the connection structure of the insulation module 10 and an inverter circuit 500.

The inverter circuit 500 of the present embodiment is of a full-bridge type and includes a first inverter circuit 510 and a second inverter circuit 520 connected in parallel to the first inverter circuit 510. The first inverter circuit 510 includes a first switching element 511 and a second switching element 512 that are connected in series to each other. The second inverter circuit 520 includes a first switching element 521 and a second switching element 522 that are connected in series to each other. Each of the switching elements 511, 512, 521, and 522 is, for example, a power transistor. The insulation module 10 of the present embodiment is an isolation gate driver for power transistors. Examples of the power transistor include insulated gate bipolar transistor (IGBT) and a metal-oxide-semiconductor field effect transistor (MOSFET). In the present embodiment, an MOSFET is used as the switching elements 501 and 502.

In the present embodiment, the insulation module 10 applies a drive voltage signal to the gate of the first switching element 511 and the gate of the first switching element 521. The insulation module 10 is a gate driver configured to drive the first switching elements 511 and 521.

The terminal 51A of the insulation module 10 is electrically connected to a positive electrode of a control power source 503. The terminal 51D of the insulation module 10 is electrically connected to the source of the first switching element 511 of the first inverter circuit 510 and the source of the first switching element 521 of the second inverter circuit 520.

As shown in FIG. 15, the insulation module 10 includes a first light emitting diode 20AP, a second light emitting diode 20AQ, a first light receiving diode 30AP, a second light receiving diode 30AQ, a first control circuit 130A, and a second control circuit 130B. A drive current of 10 mA or lower is supplied to the light emitting diodes 20AP and 20AQ. The first control circuit 130A and the second control circuit 130B are included in the control circuit 35PB (refer to FIG. 12).

The first light emitting diode 20AP includes the first electrode 21P (anode electrode) and the second electrode 22P (cathode electrode) of the first light emitting element 20P. The first electrode 21P of the first light emitting diode 20AP is electrically connected to the terminal 41A. The second electrode 22P of the first light emitting diode 20AP is electrically connected to the terminal 41B.

The first light receiving diode 30AP is configured to receive light from the first light emitting diode 20AP. The first light receiving diode 30AP is electrically connected to the first control circuit 130A and is insulated from the first light emitting diode 20AP. In other words, the first light emitting diode 20AP is insulated from the first control circuit 130A. The first light receiving diode 30AP includes a first electrode 31P and a second electrode 32P. In an example, the first electrode 31P is an anode electrode, and the second electrode 32P is a cathode electrode. The first electrode 31P and the second electrode 32P are electrically connected to the first control circuit 130A.

The first control circuit 130A includes a first Schmitt trigger 131A and a first output portion 132A. The first control circuit 130A generates a drive voltage signal based on a change in the voltage of the first light receiving diode 30AP when the first light receiving diode 30AP receives light from the first light emitting diode 20AP.

The first Schmitt trigger 131A is electrically connected to the first electrode 31P and the second electrode 32P of the first light receiving diode 30AP. The first Schmitt trigger 131A is also electrically connected to the terminals 51A and 51D. Thus, the first Schmitt trigger 131A is supplied with power from the control power source 503. The first Schmitt trigger 131A transfers voltage from the first light receiving diode 30AP to the first output portion 132A. The first Schmitt trigger 131A has a threshold voltage having a predetermined hysteresis. This configuration increases resistance to noise.

The first output portion 132A includes a first switching element 132Aa and a second switching element 132Ab that are connected in series to each other. In the example shown in FIG. 15, a p-type MOSFET is used in the first switching element 132Aa, and an n-type MOSFET is used in the second switching element 132Ab. Thus, in the present embodiment, the first output portion 132A is configured as a complementary MOS (CMOS). The switching elements 132Aa and 132Ab of the first output portion 132A are activated and deactivated when an input-output voltage is in a range of 3 V to 7 V.

The source of the first switching element 132Aa is electrically connected to the terminal 51A. The source of the second switching element 132Ab is electrically connected to the terminal 51D. A node N between the drain of the first switching element 132Aa and the drain of the second switching element 132Ab is electrically connected to the terminal 51B.

The gate of the first switching element 132Aa and the gate of the second switching element 132Ab are electrically connected to the first Schmitt trigger 131A. Thus, a signal is applied from the first Schmitt trigger 131A to each of the gate of the first switching element 132Aa and the gate of the second switching element 132Ab.

The first output portion 132A generates a drive voltage signal in accordance with complementary activation and deactivation of the first switching element 132Aa and the second switching element 132Ab based on the signal from the first Schmitt trigger 131A. The first output portion 132A applies the drive voltage signal to the gate of the first switching element 511.

In the present embodiment, the first control circuit 130A is configured to receive a signal including multiple pulses from the first light receiving element 30P. The first control circuit 130A outputs a drive voltage signal as an output signal to the gate of the first switching element 511 based on a portion of the multiple pulses excluding the initial pulse. The signal including multiple pulses is a pulse having a predetermined pulse period. In an example, a second signal including multiple pulses is transmitted after a first signal including multiple pulses, and the interval between the first signal and the second signal is longer than the pulse period.

The second light emitting diode 20AQ includes the first electrode 21Q (anode electrode) and the second electrode 22Q (cathode electrode) of the second light emitting element 20Q. The first electrode 21Q of the second light emitting diode 20AQ is electrically connected to the terminal 41D. The second electrode 22Q is electrically connected to the terminal 41C.

The second light receiving diode 30AQ is configured to receive light from the second light emitting diode 20AQ. The second light receiving diode 30AQ is electrically connected to the second control circuit 130B and is insulated from the second light emitting diode 20AQ. In other words, the second light emitting diode 20AQ is insulated from the second control circuit 130B. The second light receiving diode 30AQ includes a first electrode 31Q and a second electrode 32Q. In an example, the first electrode 31Q is an anode electrode, and the second electrode 32Q is a cathode electrode. The first electrode 31Q and the second electrode 32Q are electrically connected to the second control circuit 130B.

The second control circuit 130B includes a second Schmitt trigger 131B and a second output portion 132B. The second control circuit 130B generates a drive voltage signal based on a change in the voltage of the second light receiving diode 30AQ when the second light receiving diode 30AQ receives light from the second light emitting diode 20AQ.

The second Schmitt trigger 131B is electrically connected to the first electrode 31Q and the second electrode 32Q of the second light receiving diode 30AQ. The second Schmitt trigger 131B is also electrically connected to the terminals 51A and 51D. Thus, the second Schmitt trigger 131B is supplied with power from the control power source 503. The second Schmitt trigger 131B transfers voltage from the second light receiving diode 30AQ to the second output portion 132B. The second Schmitt trigger 131B has a threshold voltage having a predetermined hysteresis. This configuration increases resistance to noise.

The second output portion 132B includes a first switching element 132Ba and a second switching element 132Bb that are connected in series to each other. In the example shown in FIG. 15, a p-type MOSFET is used in the first switching element 132Ba, and an n-type MOSFET is used in the second switching element 132Bb. In the present embodiment, the second output portion 132B is configured as a complementary MOS. The electrical connection of the first switching element 132Ba and the second switching element 132Bb is the same as that of the first switching element 132Aa and the second switching element 132Ab and thus will not be described in detail.

In the present embodiment, the second control circuit 130B is configured to receive a signal including multiple pulses from the second light receiving element 30Q. The second control circuit 130B outputs a drive voltage signal as an output signal to the first switching element 521 based on a portion of the multiple pulses excluding the initial pulse.

The connection of the light emitting diodes 20AP and 20AQ to the terminals 41A to 41D may be changed in any manner. In an example, the first electrode 21P of the first light emitting diode 20AP may be electrically connected to the terminal 41B, and the second electrode 22P of the first light emitting diode 20AP may be electrically connected to the terminal 41A. The first electrode 21Q of the second light emitting diode 20AQ may be electrically connected to the terminal 41C, and the second electrode 22Q of the second light emitting diode 20AQ may be electrically connected to the terminal 41D.

The insulation module 10 may be used in the interface of a controller area network (CAN) bus or the interface of a serial peripheral interface (SPI) communication instead of an isolation gate driver.

Operation

The operation of the insulation module 10 of the present embodiment will now be described.

The element main surface 20Ps of the first light emitting element 20P is opposed to the light receiving surface 33P of the first light receiving element 30P in the z-direction. As shown in FIG. 6, the first light emitting element 20P and the first light receiving element 30P are arranged so that the center of the element main surface 20Ps of the first light emitting element 20P is aligned with the center of the light receiving surface 33P of the first light receiving element 30P in the x-direction.

The first electrode 21P of the first light emitting element 20P is arranged closer to the first resin side surface 81 (refer to FIG. 5) than the center of the element main surface 20Ps in the x-direction. Thus, as viewed in the z-direction, the first electrode 21P overlaps a portion of the first light receiving element 30P located closer to the first resin side surface 81 with respect to the center of the light receiving surface 33P in the x-direction. In other words, the first electrode 21P overlaps a portion of the first light receiving element 30P located on a side of the center of the light receiving surface 33P opposite the second semiconductor region in the x-direction.

Thus, the connecting part WAX of the wire WA1, which is connected to the first electrode 21P, overlaps the portion of the first light receiving element 30P located on a side of the center of the light receiving surface 33P opposite the second semiconductor region in the x-direction. Thus, as viewed in the z-direction, the area of the wire WA1 that overlaps both the element main surface 20Ps of the first light emitting element 20P and the light receiving surface 33P of the first light receiving element 30P is decreased as compared to a structure in which the connecting part WAX of the wire WA1 is connected to the center of the element main surface 20Ps of the first light emitting element 20P in the x-direction. This reduces interference of the wire WA1 with light from the first light emitting element 20P.

The first plate-shaped member 70P is inclined toward the element main surface 20Ps so that the distance in the z-direction between the element main surface 20Ps and the first plate-shaped member 70P increases from the end of the element main surface 20Ps of the first light emitting element 20P located closer to the second resin side surface 82 toward the end of the element main surface 20Ps located closer to the first resin side surface 81 in the x-direction. That is, the first electrode 21P is offset from the center of the element main surface 20Ps in the x-direction toward a portion at which that the distance to the first plate-shaped member 70P in the z-direction is greater than that at the center. Thus, the connecting part WAX of the wire WA1, which is connected to the first electrode 21P, is arranged in a space in which the distance between the element main surface 20Ps and the first plate-shaped member 70P is increased in the z-direction. Stress applied to the wire WA1 caused by interference of the first plate-shaped member 70P with the wire WA1 is reduced as compared to a structure in which the connecting part WAX of the wire WA1 is connected to the center of the element main surface 20Ps of the first light emitting element 20P in the x-direction.

Advantages of First Embodiment

The insulation module 10 of the present embodiment has the following advantages.

(1-1) The insulation module 10 includes the first light emitting element 20P, the first light receiving element 30P, the first plate-shaped member 70P, and the wire WA1. The first light emitting element 20P includes the element main surface 20Ps, corresponding to a light emitting surface, and the first electrode 21P, corresponding to a pad formed on the element main surface 20Ps. The first light receiving element 30P includes the light receiving surface 33P spaced apart and faced to the element main surface 20Ps and forms a photocoupler with the first light emitting element 20P. The first plate-shaped member 70P is arranged between the element main surface 20Ps and the light receiving surface 33P and is inclined from each of the element main surface 20Ps and the light receiving surface 33P. The first plate-shaped member 70P is light-transmissive and electrically insulative. The wire WA1 is connected to the first electrode 21P. The first electrode 21P is offset from the center of the element main surface 20Ps toward a portion at which the distance to the first plate-shaped member 70P is greater than that at the center.

When the first light receiving element 30P receives light from the first light emitting element 20P, if the amount of the received light is excessively small, the first light receiving element 30P may fail to generate a drive voltage signal despite the light received. In this regard, in the insulation module 10, the distance between the first light emitting element 20P and the first light receiving element 30P in the x-direction is decreased to avoid a situation in which the first light receiving element 30P receives an excessively small amount of light from the first light emitting element 20P. However, since the first plate-shaped member 70P is arranged between the first light emitting element 20P and the first light receiving element 30P and is inclined from each of the element main surface 20Ps and the light receiving surface 33P, limitations are imposed on the decrease in the distance between the first light emitting element 20P and the first light receiving element 30P.

In this regard, in the insulation module 10 of the present embodiment, as viewed in the z-direction, the area of the wire WA1 overlapping both the element main surface 20Ps and the light receiving surface 33P is decreased as compared to a structure in which the wire WA1 is connected to a first electrode arranged at the center of the element main surface 20Ps. This reduces the interference of the wire WA1 with the light from the first light emitting element 20P, thereby increasing the amount of light received by the light receiving surface 33P of the first light receiving element 30P. As a result, a situation in which the first light receiving element 30P receives light from the first light emitting element 20P but fails to generate the drive voltage signal is less likely to occur. The same applies to the second light emitting element 20Q and the second light receiving element 30Q as the first light emitting element 20P and the first light receiving element 30P. Thus, the advantage described above is obtained.

(1-2) The maximum distance between the element main surface 20Ps (light emitting surface) of the first light emitting element 20P and the first plate-shaped member 70P, opposed to the element main surface 20Ps in the z-direction, is less than the thickness of the first light emitting element 20P.

A decrease in the maximum distance between the element main surface 20Ps of the first light emitting element 20P and the first plate-shaped member 70P in the z-direction may decrease the height of the insulation module 10. However, the decrease in the maximum distance, for example, causes the first plate-shaped member 70P to bend the wire WA1 and produces a larger stress.

In this regard, in the present embodiment, as described in (1-1), the wire WA1 is arranged in the space in which the distance between the element main surface 20Ps and the first plate-shaped member 70P is increased. This reduces the stress produced by the bending of the wire WA1. The same applies to the second light emitting element 20Q and the second light receiving element 30Q as the first light emitting element 20P and the first light receiving element 30P. Thus, the advantage described above is obtained.

(1-3) The maximum distance between the element main surface 20Ps (light emitting surface) of the first light emitting element 20P and the first plate-shaped member 70P, opposed to the element main surface 20Ps in the z-direction, is less than the thickness of the first light receiving element 30P.

A decrease in the maximum distance between the element main surface 20Ps of the first light emitting element 20P and the first plate-shaped member 70P in the z-direction may decrease the height of the insulation module 10. However, the decrease in the maximum distance, for example, causes the first plate-shaped member 70P to bend the wire WA1 and produces a larger stress.

In this regard, in the present embodiment, as described in (1-1), the wire WA1 is arranged in the space in which the distance between the element main surface 20Ps and the first plate-shaped member 70P is increased. This reduces the stress produced by the bending of the wire WA1. The same applies to the second light emitting element 20Q and the second light receiving element 30Q as the first light emitting element 20P and the first light receiving element 30P. Thus, the advantage described above is obtained.

(1-4) The distance between the element main surface 20Ps of the first light emitting element 20P and the light receiving surface 33P of the first light receiving element 30P is less than the thickness of the first light receiving element 30P.

With this structure, the element main surface 20Ps of the first light emitting element 20P and the light receiving surface 33P of the first light receiving element 30P are arranged close to each other to increase the amount of light received from the first light emitting element 20P.

However, when the distance between the element main surface 20Ps of the first light emitting element 20P and the first plate-shaped member 70P in the z-direction is decreased, for example, the first plate-shaped member 70P may bend the wire WA1 and produce a larger stress.

In this regard, in the present embodiment, as described in (1-1), the wire WA1 is arranged in the space in which the distance between the element main surface 20Ps and the first plate-shaped member 70P is increased. This reduces the stress produced by the bending of the wire WA1. The same applies to the second light emitting element 20Q and the second light receiving element 30Q as the first light emitting element 20P and the first light receiving element 30P. Thus, the advantage described above is obtained.

(1-5) The thickness of the first light emitting element 20P is smaller than the thickness of the first light receiving element 30P. The thickness of the second light emitting element 20Q is smaller than the thickness of the second light receiving element 30Q.

This structure allows for reduction in the height of the insulation module 10.

(1-6) The minimum distance between the first electrode 21P of the first light emitting element 20P and the first plate-shaped member 70P, opposed to the first electrode 21P, is greater than ½ of the distance between the element main surface 20Ps of the first light emitting element 20P (light emitting surface) and the light receiving surface 33P of the first light receiving element 30P.

This structure increases the minimum distance between the element main surface 20Ps of the first light emitting element 20P and the first plate-shaped member 70P in the z-direction, thereby reducing the stress produced by the first plate-shaped member 70P bending the wire WA1. The same applies to the second light emitting element 20Q and the second light receiving element 30Q as the first light emitting element 20P and the first light receiving element 30P. Thus, the advantage described above is obtained.

(1-7) The encapsulation resin 80 includes the first resin side surface 81, on which the terminals 41A to 41D are arranged, and the second resin side surface 82, on which the terminals 51A to 51D are arranged. The recess-projection portions 87 are arranged on the first resin side surface 81 between adjacent ones of the terminals 41A to 41D in the y-direction. The recess-projection portions 88 are arranged on the second resin side surface 82 between adjacent ones of the terminals 51A to 51D in the y-direction.

This structure increases the creepage distance between ones of the terminals 41A to 41D located adjacent to each other in the y-direction. The structure also increases the creepage distance between ones of the terminals 51A to 51D located adjacent to each other in the y-direction. As a result, the insulation between adjacent ones of the terminals 41A to 41D in the y-direction is enhanced. The insulation between adjacent ones of the terminals 51A to 51D in the y-direction is enhanced.

(1-8) The die pad 52DB of the second lead frame 50D includes the suspension lead 58D. The suspension lead 58D is exposed from the second resin side surface 82 between the terminal 51A and the terminal 51B. The recess-projection portions 88 are provided on the second resin side surface 82 between the terminal 51A and the suspension lead 58D and between the terminal 51B and the suspension lead 58D.

This structure increases the creepage distance between the terminal 51A and the suspension lead 58D and the creepage distance between the terminal 51B and the suspension lead 58D. As a result, the insulation between the terminal 51A and the suspension lead 58D is enhanced. In addition, the insulation between the terminal 51B and the suspension lead 58D is enhanced.

(1-9) The intermediate frame 50E includes the first suspension lead 52E and the second suspension lead 53E. The first suspension lead 52E is exposed from the second resin side surface 82 between the terminal 51D and the terminal 51C. The second suspension lead 53E is exposed from the second resin side surface 82 between the terminal 51C and the terminal 51B. The recess-projection portions 88 are arranged on the second resin side surface 82 between the terminal 51D and the first suspension lead 52E, between the first suspension lead 52E and the terminal 51C, between the terminal 51C and the second suspension lead 53E, and between the second suspension lead 53E and the terminal 51B.

This structure increases the creepage distance between the terminal 51D and the first suspension lead 52E, the creepage distance between the first suspension lead 52E and the terminal 51C, the creepage distance between the terminal 51C and the second suspension lead 53E, and the creepage distance between the second suspension lead 53E and the terminal 51B. As a result, the insulation between each of the terminals 51D and 51C and the first suspension lead 52E is enhanced. The insulation between each of the terminals 51C and 51B and the second suspension lead 53E is enhanced.

(1-10) The recess 46B is formed in the die pad 42BB of the first lead frame 40B supporting the first light emitting element 20P. The recess 59DC is formed in the die pad 52DB of the second lead frame 50D supporting the first light receiving element 30P. The die pad 42BB and the die pad 52DB are arranged so that the recess 46B is opposed to the recess 59DC.

In this structure, the recess 46B and the recess 59DC are used as marks to adjust the position of the first light emitting element 20P and the first light receiving element 30P. Thus, as viewed in the z-direction, the first light emitting element 20P is accurately aligned with the first light receiving element 30P in a direction orthogonal to the z-direction. The same applies to the second light emitting element 20Q and the second light receiving element 30Q as the first light emitting element 20P and the first light receiving element 30P. Thus, the advantage described above is obtained.

(1-11) The first light receiving element 30P includes the optical-electrical conversion element 35PA, the control circuit 35PB configured to receive a signal from the optical-electrical conversion element 35PA, and the insulation layer 36P formed on the optical-electrical conversion element 35PA and the control circuit 35PB. The insulation layer 36P includes a first insulation portion 36PA formed on the optical-electrical conversion element 35PA and a second insulation portion 36PB formed on the control circuit 35PB. The second insulation portion 36PB includes the wiring layer 38PA to 38PB. The first insulation portion 36PA is free of a wiring layer.

In this structure, the first insulation portion 36PA, into which light is emitted from the first light emitting element 20P, does not include the wiring layers electrically connected to the control circuit 35PB. This reduces an erroneous operation of the control circuit 35PB caused by the light from the first light emitting element 20P.

(1-12) The insulation module 10 includes the first photocoupler formed of the first light emitting element 20P and the first light receiving element 30P and the second photocoupler formed of the second light emitting element 20Q and the second light receiving element 30Q. Each light emitting element 20P is mounted on the first lead frame 40. Each light receiving element 30P is mounted on the second lead frame 50.

In this structure, a signal communicated by the first photocoupler and a signal communicated by the second photocoupler are both transmitted from the first lead frame 40 toward the second lead frame 50. That is, the insulation module 10 outputs two types of signals in the same transmission direction.

(1-13) The insulation module 10 includes the first transparent resin 60P, which covers the first light emitting element 20P and the first light receiving element 30P, and the second transparent resin 60Q, which covers the second light emitting element 20Q and the second light receiving element 30Q. The encapsulation resin 80 is configured to encapsulate the first transparent resin 60P and the second transparent resin 60Q and includes the separation wall 89 separating the first transparent resin 60P from the second transparent resin 60Q.

In this structure, when light from the first light emitting element 20P transmits through the first transparent resin 60P, the light is blocked by the separation wall 89. This inhibits entrance of the light from the first light emitting element 20P into the second light receiving element 30Q. Also, when light from the second light emitting element 20Q transmits through the second transparent resin 60Q, the light is blocked by the separation wall 89. This inhibits entrance of the light from the second light emitting element 20Q into the first light receiving element 30P.

(1-14) The first light emitting element 20P is configured to emit light having the first wavelength. The second light emitting element 20Q is configured to emit light having the second wavelength that differs from the first wavelength. The first transparent resin 60P is formed from a resin material that transmits the light having the first wavelength and does not transmit the light having the second wavelength. The second transparent resin 60Q is formed from a resin material that transmits the light having the second wavelength and does not transmit the light having the first wavelength.

This structure limits passage of the first wavelength light into the second transparent resin 60Q and thus limits entrance of light from the first light emitting element 20P into the second light receiving element 30Q. Thus, the second light receiving element 30Q is less likely to receive the first wavelength light. The structure also limits passage of the second wavelength light into the first transparent resin 60P and thus limits entrance of light from the second light emitting element 20Q into the first light receiving element 30P. Thus, the first light receiving element 30P is less likely to receive the second wavelength light.

### Second Embodiment

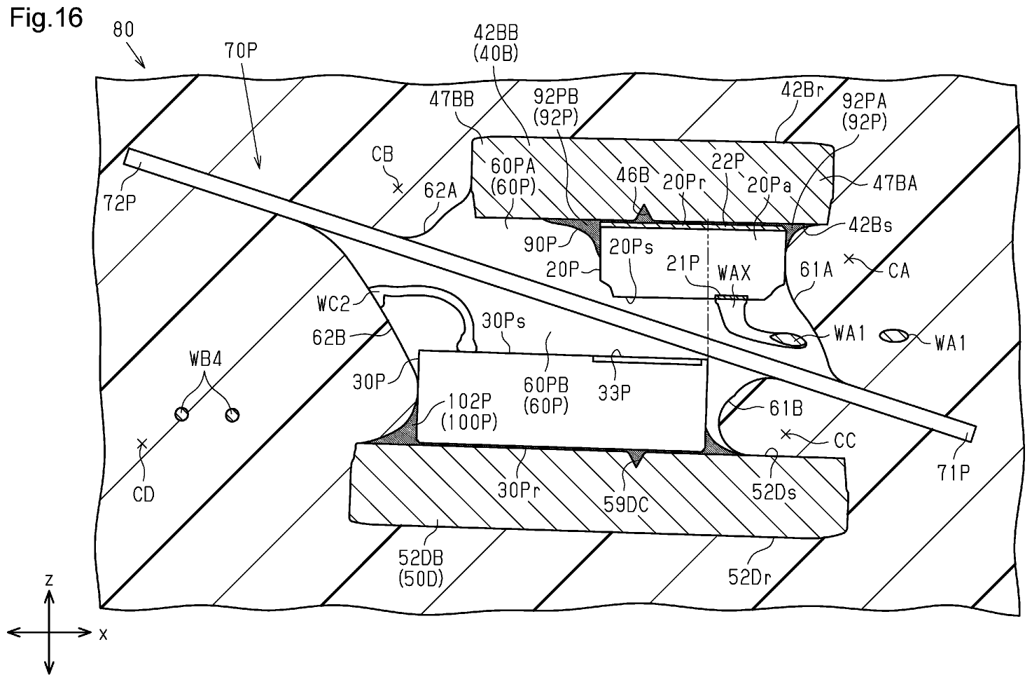

The structure of a second embodiment of the insulation module 10 will now be described with reference to FIG. 16. The insulation module 10 of the present embodiment differs from the first embodiment in the structures of the light emitting elements 20P and 20Q. In the description below, the same reference characters are given to those components that are the same as the corresponding components of the insulation module 10 of the first embodiment. Such components will not be described in detail.

FIG. 16 mainly shows a cross-sectional structure of the first light emitting element 20P, the first light receiving element 30P, the die pad 42BB of the first lead frame 40B, the die pad 52DB of the second lead frame 50D, the first transparent resin 60P, the first plate-shaped member 70P, and the encapsulation resin 80. The structure of the first light emitting element 20P, which differs from that of the first embodiment, will now be described in detail. The structure of the second light emitting element 20Q is the same as the structure of the first light emitting element 20P and thus will not be described in detail.

As shown in FIG. 16, the first light emitting element 20P is greater than that of the first embodiment in the dimension in the x-direction. In the present embodiment, as viewed in the z-direction, the first light emitting element 20P is rectangular, defined in a longitudinal direction and a lateral direction. The longitudinal direction of the first light emitting element 20P is the x-direction. The lateral direction of the first light emitting element 20P is the y-direction.

The element main surface 20Ps of the first light emitting element 20P includes an extension region 20Pa extending beyond the first light receiving element 30P toward the first resin side surface 81 (refer to FIG. 5) in the longitudinal direction (the x-direction). The element main surface 20Ps (light emitting surface) of the first light emitting element 20P is separated further away from the first plate-shaped member 70P from the second resin side surface 82 (refer to FIG. 5) toward the first resin side surface 81 in the longitudinal direction. In the present embodiment, the second resin side surface 82 corresponds to a “first side.” The first resin side surface 81 corresponds to a “second side.”

The first electrode 21P of the first light emitting element 20P is offset from the center of the element main surface 20Ps in the longitudinal direction (the x-direction). More specifically, the first electrode 21P is offset from the center of the element main surface 20Ps in the x-direction toward a portion at which the distance to the first plate-shaped member 70P is greater than that at the center. In the present embodiment, the first electrode 21P is arranged in the extension region 20Pa. In other words, the first electrode 21P is arranged closer to the first resin side surface 81 than the first light receiving element 30P is. Thus, the first electrode 21P does not overlap the light receiving surface 33P of the first light receiving element 30P as viewed in the z-direction.

The wire WA1 is connected to the first electrode 21P. The wire WA1 is connected to a portion of the element main surface 20Ps of the first light emitting element 20P offset from the center in the x-direction so as not to contact the first plate-shaped member 70P. The connecting part WAX, which is a portion of the wire WA1 connected to the first electrode 21P, is offset from the center of the element main surface 20Ps in the x-direction toward a portion at which the distance to the first plate-shaped member 70P is greater than that at the center. In the present embodiment, the connecting part WAX is arranged in the extension region 20Pa. In other words, the connecting part WAX is arranged closer to the first resin side surface 81 than the first light receiving element 30P is. Thus, the connecting part WAX does not overlap the light receiving surface 33P of the first light receiving element 30P as viewed in the z-direction. Since the wire WA1 extends from the connecting part WAX toward the first resin side surface 81, the wire WA1 is arranged to avoid overlapping with the first light receiving element 30P as viewed in the z-direction.

Advantages of Second Embodiment

The insulation module 10 of the present embodiment has the following advantages.

(2-1) As viewed in the z-direction, the first light emitting element 20P is rectangular, defined in a longitudinal direction and a lateral direction. The element main surface 20Ps (light emitting surface) of the first light emitting element 20P is separated further away from the first plate-shaped member 70P from the second resin side surface 82 (first side) toward the first resin side surface (second side) in the longitudinal direction. The first electrode 21P of the first light emitting element 20P is offset in the longitudinal direction from the center of the element main surface 20Ps in the x-direction toward a portion at which the distance to the first plate-shaped member 70P is greater than that at the center. The wire WA1 is connected to the first electrode 21P so as not to contact the first plate-shaped member 70P.

With this structure, as viewed in the z-direction, the area of the wire WA1 overlapping both the element main surface 20Ps and the light receiving surface 33P is decreased as compared to a structure in which the wire WA1 is connected to a first electrode arranged at the center of the element main surface 20Ps. This reduces the interference of the wire WA1 with the light from the first light emitting element 20P, thereby increasing the amount of light received by the light receiving surface 33P of the first light receiving element 30P. As a result, a situation in which the first light receiving element 30P receives light from the first light emitting element 20P but fails to generate the drive voltage signal is less likely to occur. The same applies to the second light emitting element 20Q and the second light receiving element 30Q as the first light emitting element 20P and the first light receiving element 30P. Thus, the advantage described above is obtained.

(2-2) The insulation module 10 includes the first light emitting element 20P, the first light receiving element 30P, the first plate-shaped member 70P, and the wire WA1. The first light emitting element 20P includes the element main surface 20Ps, corresponding to a light emitting surface, and the first electrode 21P, corresponding to a pad formed on the element main surface 20Ps. The first light receiving element 30P includes the light receiving surface 33P spaced apart and faced to the element main surface 20Ps and forms a photocoupler with the first light emitting element 20P. The first plate-shaped member 70P is arranged between the element main surface 20Ps and the light receiving surface 33P and is inclined from each of the element main surface 20Ps and the light receiving surface 33P. The first plate-shaped member 70P is light-transmissive and electrically insulative. The wire WA1 is connected to the first electrode 21P. As viewed in the z-direction, the first light emitting element 20P is rectangular and defines a longitudinal direction and a lateral direction. The element main surface 20Ps (light emitting surface) of the first light emitting element 20P is separated further away from the first plate-shaped member 70P from the second resin side surface 82 (first side) toward the first resin side surface 81 (second side) in the longitudinal direction. The element main surface 20Ps is separated further away from the first plate-shaped member 70P from the first side toward the second side in the longitudinal direction. The element main surface 20Ps includes the extension region 20Pa extending beyond the first light receiving element 30P toward the second side in the longitudinal direction. The first electrode 21P is arranged in the extension region 20Pa.

With this structure, as viewed in the z-direction, the first electrode 21P is located toward the second side (the first resin side surface 81) in the longitudinal direction with respect to the region overlapping both the element main surface 20Ps and the light receiving surface 33P. Thus, the wire WA1 is not located in the region overlapping the element main surface 20Ps and the light receiving surface 33P. This increases the amount of light received by the light receiving surface 33P of the first light receiving element 30P. As a result, a situation in which the first light receiving element 30P receives light from the first light emitting element 20P but fails to generate the drive voltage signal is less likely to occur. The same applies to the second light emitting element 20Q and the second light receiving element 30Q as the first light emitting element 20P and the first light receiving element 30P. Thus, the advantage described above is obtained.

### Third Embodiment

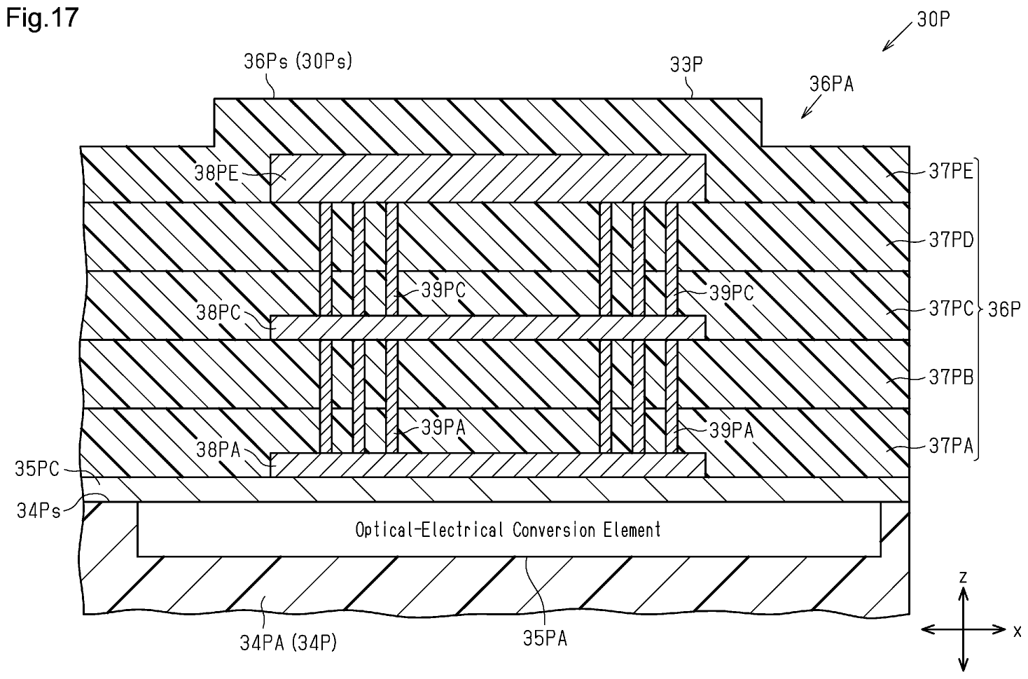

The structure of a third embodiment of the insulation module 10 will now be described with reference to FIG. 17. The insulation module 10 of the present embodiment differs from the first embodiment in the structures of the light receiving elements 30P and 30Q. In the description below, the same reference characters are given to those components that are the same as the corresponding components of the insulation module 10 of the first embodiment. Such components will not be described in detail.

FIG. 17 shows a cross-sectional structure of the first light receiving element 30P including the element main surface 30Ps. FIG. 17 shows an enlarged cross-sectional structure of the element main surface 30Ps of the first light receiving element 30P including the optical-electrical conversion element 35PA and its surroundings. In the element main surface 30Ps of the first light receiving element 30P, the cross-sectional structure of the control circuit 35PB and its surroundings is the same as that of the first embodiment shown in FIG. 12. The structure of the first light receiving element 30P, which differs from that of the first embodiment, will now be described in detail. The second light receiving element 30Q has the same structure as the first light receiving element 30P and thus will not be described in detail.

As shown in FIG. 17, in the first light receiving element 30P of the present embodiment, a wiring layer is also arranged in the first insulation portion 36PA, which corresponds to the first semiconductor region 34PA of the insulation layer 36P. However, the number of wiring layers arranged in the first insulation portion 36PA differs from the number of the wiring layers 38PA to 38PE in the second insulation portion 36PB. More specifically, the first insulation portion 36PA and the second insulation portion 36PB include the same number of stacked insulation films (the insulation films 37PA to 37PE). However, the number of wiring layers in the first insulation portion 36PA is less than the number of wiring layers (the wiring layers 38PA to 38PE) of the second insulation portion 36PB. Therefore, the first insulation portion 36PA includes at least one insulation film that is free of a wiring layer. In the present embodiment, the first insulation portion 36PA does not include the wiring layers 38PB and 38PD. Thus, in the first insulation portion 36PA, the insulation films 37PB and 37PD correspond to an insulation film that is free of a wiring layer. In the present embodiment, the wiring layers 38PA, 38PC, and 38PE of the first insulation portion 36PA correspond to “second wiring layer.” The wiring layers 38PAto 38PE of the second insulation portion 36PB correspond to “first wiring layer.”

As described above, in the first light receiving element 30P of the present embodiment, at least one first wiring layer is formed on the second insulation portion 36PB. At least one layer that is free of a wiring layer is arranged on the first insulation portion 36PA. In the first light receiving element 30P of the present embodiment, multiple first wiring layers are formed on the second insulation portion 36PB. One or more second wiring layers are formed on the first insulation portion 36PA. The second wiring layers of the first insulation portion 36PA are less in number than the first wiring layers of the second insulation portion 36PB.

As viewed in the z-direction, the wiring layers 38PA, 38PC, and 38PE of the first insulation portion 36PA overlap the optical-electrical conversion element 35PA. In the present embodiment, as viewed in the z-direction, the optical-electrical conversion element 35PA includes a region extending beyond the wiring layers 38PA, 38PC, and 38PE. The insulation films 37PA to 37PE are arranged on the region of the optical-electrical conversion element 35PA, extending from the wiring layers 38PA, 38PC, and 38PE.

As viewed in the z-direction, the amount of light received by the optical-electrical conversion element 35PA may be adjusted by adjusting the area of each layer of each of the wiring layers 38PA, 38PC, and 38PE (hereafter, simply referred to as the area of each of the wiring layers 38PA, 38PC, and 38PE) arranged on the optical-electrical conversion element 35PA. More specifically, at the time of designing the insulation module 10, the area of each of the wiring layers 38PA, 38PC, and 38PE is set so that the optical-electrical conversion element 35PA receives an amount of light that is within a predetermined range. In an example, in the z-direction, the area of each of the wiring layers 38PA, 38PC, and 38PE is set so that the percentage of the light that perpendicularly enters the optical-electrical conversion element 35PA without reflecting is in a range of 60% to 70%. The percentage of the light that perpendicularly enters the optical-electrical conversion element 35PA without reflecting is not limited to the range of 60% to 70% and may be, for example, a range of 30% to 40%, a range of 40% to 50%, a range of 50% to 60%, a range of 70% to 80%, or a range of 80% to 90%. As described above, the percentage of light that perpendicularly enters the optical-electrical conversion element 35PA without reflecting is appropriately adjusted by adjusting the wiring pattern of the wiring layers 38PA, 38PC, and 38PE in accordance with the properties of the optical-electrical conversion element 35PA and the like.

Advantages of Third Embodiment

The insulation module 10 of the present embodiment has the following advantages.

(3-1) The insulation layer 36P includes the first insulation portion 36PA formed on the optical-electrical conversion element 35PA and the second insulation portion 36PB formed on the control circuit 35PB. The wiring layers 38PA to 38PE are formed on the second insulation portion 36PB. The wiring layers 38PA, 38PC, 38PE, which are less in number than those of the second insulation portion 36PB, are formed on the first insulation portion 36PA. That is, the first insulation portion 36PA includes at least one layer that is free of a wiring layer.

With this structure, the first insulation portion 36PA, which receives light from the first light emitting element 20P, includes a fewer number of wiring layers electrically connected to the control circuit 35PB than the second insulation portion 36PB. Thus, the control circuit 35PB will not be erroneously operated by incident light or the like when a larger amount of light is received from the first light emitting element 20P. In addition, the area of each of the wiring layers 38PA, 38PC, and 38PE may be adjusted to adjust the percentage of light that perpendicularly enters the optical-electrical conversion element 35PA without reflecting in accordance with the properties of the optical-electrical conversion element 35PA.

### Fourth Embodiment

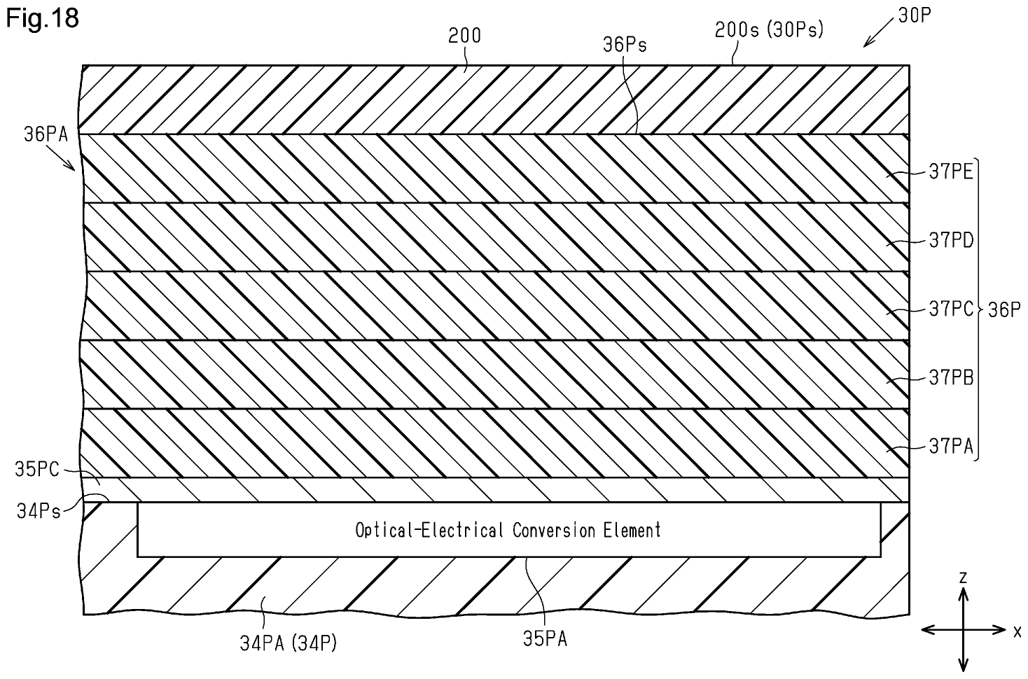

The structure of a fourth embodiment of the insulation module 10 will now be described with reference to FIG. 18. The insulation module 10 of the present embodiment differs from the first embodiment in the structures of the light receiving elements 30P and 30Q. In the description below, the same reference characters are given to those components that are the same as the corresponding components of the insulation module 10 of the first embodiment. Such components will not be described in detail.

FIG. 18 shows a cross-sectional structure of the first light receiving element 30P including the element main surface 30Ps. FIG. 18 shows an enlarged cross-sectional structure of the element main surface 30Ps of the first light receiving element 30P including the optical-electrical conversion element 35PA and its surroundings. In the element main surface 30Ps of the first light receiving element 30P, the cross-sectional structure of the control circuit 35PB and its surroundings is the same as that of the first embodiment shown in FIG. 12. The structure of the first light receiving element 30P, which differs from that of the first embodiment, will now be described in detail. The second light receiving element 30Q has the same structure as the first light receiving element 30P and thus will not be described in detail.

As shown in FIG. 18, in the first light receiving element 30P of the present embodiment, an insulation layer 200 is arranged on the insulation layer 36P. That is, the insulation layer 200 is formed on the surface 36Ps of the insulation layer 36P. In the present embodiment, the insulation layer 200 is formed on the entirety of the surface 36Ps of the insulation layer 36P. The insulation layer 200 includes a surface 200s defining the element main surface 30Ps of the first light receiving element 30P.

The insulation layer 200 is formed from an insulative resin material that selectively absorbs or blocks infrared. In the present embodiment, the insulation layer 200 corresponds to an “infrared cut layer.” Thus, the infrared cut layer is formed from a resin material. The insulation layer 200 is formed by, for example, being applied to the surface 36Ps of the insulation layer 36P. The insulation layer 200 is, for example, formed from a resin material having a lower transmittance than that of the first transparent resin 60P. The insulation layer 200 is, for example, formed from a material having a lower transmittance than that of the first plate-shaped member 70P. The insulation layer 36P is formed from a material that allows passage of infrared. However, the material of the insulation layer 36P is not limited to that described above and may be any material.

The region of the surface 36Ps of the insulation layer 36P on which the insulation layer 200 is formed may be changed in any manner. In an example, the insulation layer 200 may be formed in only the region of the surface 36Ps of the insulation layer 36P corresponding to the first insulation portion 36PA.

The thickness of the insulation layer 200 may be changed in any manner. In an example, the thickness of the insulation layer 200 may be greater than the thickness of the insulation layer 36P. In another example, the thickness of the insulation layer 200 may be smaller than the thickness of the insulation layer 36P.

Advantages of Fourth Embodiment

The insulation module 10 of the present embodiment has the following advantages.

(4-1) The first light receiving element 30P includes the insulation layer 200 arranged on the insulation layer 36P. The insulation layer 200 covers the first insulation portion 36PA formed on at least the optical-electrical conversion element 35PA.

With this structure, the insulation layer 200 absorbs or blocks infrared. Thus, the light from the first light emitting element 20P is reduced by the insulation layer 200 and is transmitted to the first light receiving element 30P. This reduces the amount of light received by the first light receiving element 30P from the first light emitting element 20P. The second light receiving element 30Q has the same structure as the first light receiving element 30P and thus obtains the advantage described above.

### Fifth Embodiment

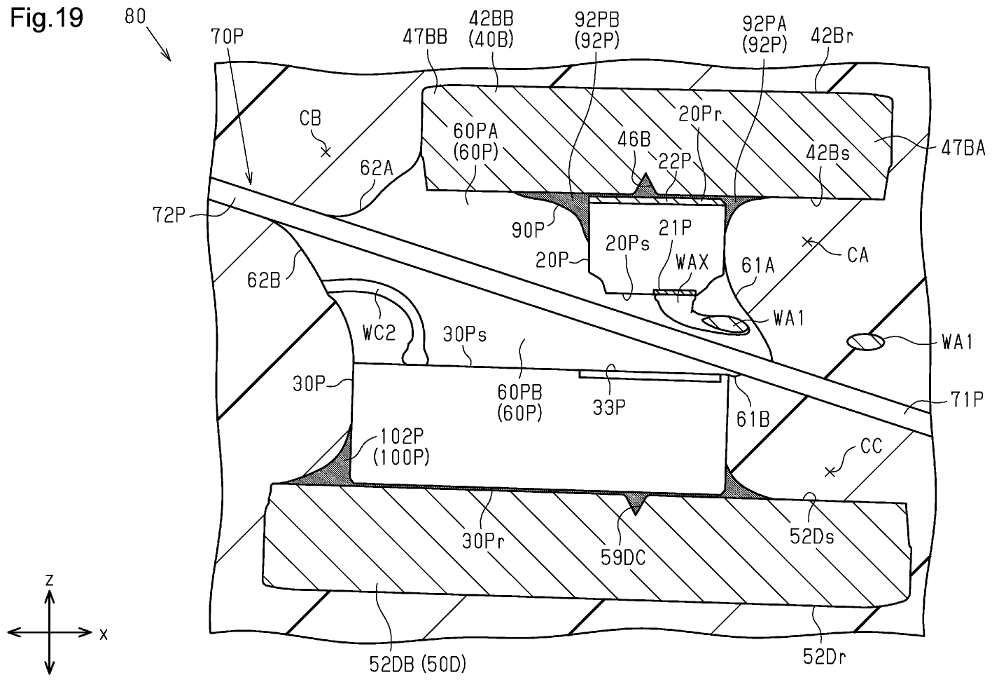

The structure of a fifth embodiment of the insulation module 10 will now be described with reference to FIG. 19. The insulation module 10 of the present embodiment differs from the first embodiment in the structures of the transparent resins 60P and 60Q. In the description below, the same reference characters are given to those components that are the same as the corresponding components of the insulation module 10 of the first embodiment. Such components will not be described in detail.

FIG. 19 mainly shows a cross-sectional structure of the first light emitting element 20P, the first light receiving element 30P, the die pad 42BB of the first lead frame 40B, the die pad 52DB of the second lead frame 50D, the first transparent resin 60P, the first plate-shaped member 70P, and the encapsulation resin 80. The structure of the first transparent resin 60P, which differs from that of the first embodiment, will now be described in detail. The second transparent resin 60Q has the same structure as the first transparent resin 60P and thus will not be described in detail.

As shown in FIG. 19, in the present embodiment, the light-receiving-side transparent resin 60PB of the first transparent resin 60P is not in contact with the two side surfaces of the first light receiving element 30P in the x-direction. Hence, the encapsulation resin 80 is in contact with the two side surfaces of the first light receiving element 30P in the x-direction. Although not shown, the light-receiving-side transparent resin 60PB is also not in contact with the two side surfaces of the first light receiving element 30P in the y-direction. Hence, the encapsulation resin 80 is in contact with the two side surfaces of the first light receiving element 30P in the y-direction. In the example shown, the encapsulation resin 80 is in contact with the entire portion of the side surfaces of the first light receiving element 30P exposed from the conductive bonding material 100P.

The light-receiving-side transparent resin 60PB covers the element main surface 30Ps of the first light receiving element 30P. Therefore, the light-receiving-side transparent resin 60PB is arranged between the element main surface 30Ps of the first light receiving element 30P and the first plate-shaped member 70P in the z-direction and not below the element main surface 30Ps. In a cross-sectional structure of the light-receiving-side transparent resin 60PB cut along the xz-plane, the curved surfaces 61B and 62B of the light-receiving-side transparent resin 60PB are shorter than the curved surfaces 61B and 62B of the first embodiment. Each of the curved surfaces 61B and 62B includes an interface between the light-receiving-side transparent resin 60PB and the encapsulation resin 80. Thus, in the present embodiment, the interface between the light-receiving-side transparent resin 60PB and the encapsulation resin 80 is smaller than that in the first embodiment.

The curved surface 61B of the present embodiment differs in shape from the curved surface 61B of the first embodiment. The curved surface 61B is curved so that the center of curvature is located on a side of the curved surface 61B opposite the die pad 52DB.

In the same manner as the curved surface 62B of the first embodiment, the curved surface 62B of the present embodiment is curved so that the center of curvature is located on a side of the curved surface 62B opposite the first plate-shaped member 70P. However, the curved surface 62B of the present embodiment differs from the curved surface 62B of the first embodiment in the position of the center of curvature and the radius of curvature. In the curved surface 62B of the present embodiment, for example, the center of curvature is located closer to the first plate-shaped member 70P than that of the curved surface 62B of the first embodiment, and the radius of curvature is smaller than that of the curved surface 62B of the first embodiment.

Advantages of Fifth Embodiment

The insulation module 10 of the present embodiment has the following advantages.

(5-1) The encapsulation resin 80 covers the side surfaces of the first light receiving element 30P. This structure decreases the interface between the light-receiving-side transparent resin 60PB of the first transparent resin 60P and the encapsulation resin 80. This limits separation of the encapsulation resin 80 from the light-receiving-side transparent resin 60PB caused by the temperature.

### Sixth Embodiment

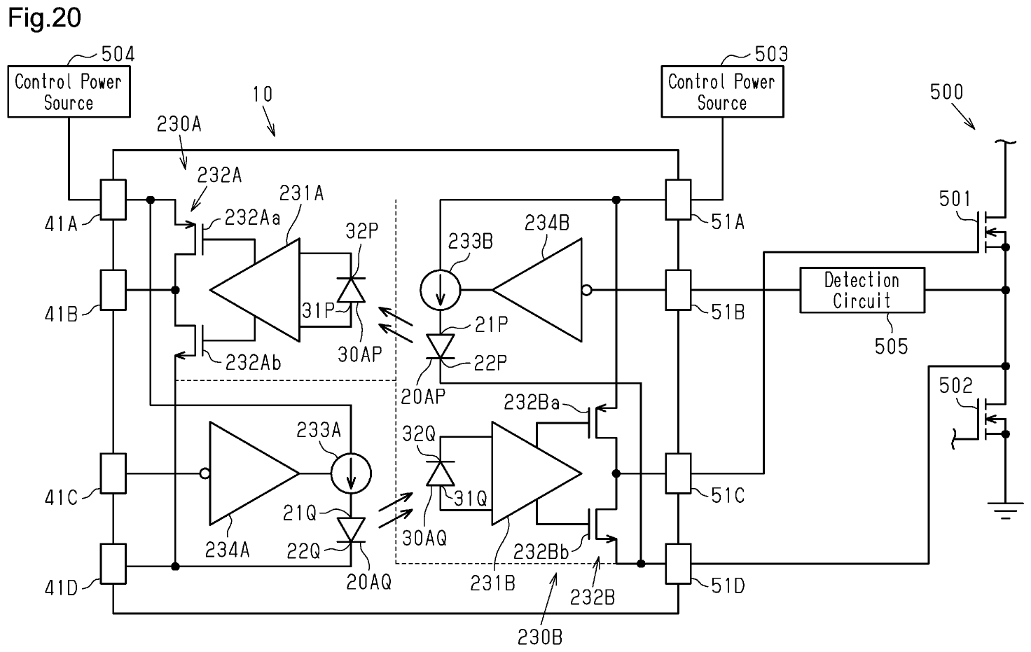

The structure of a sixth embodiment of the insulation module 10 will now be described with reference to FIG. 20. The insulation module 10 of the present embodiment differs from the first embodiment in the electrical connections of the first light emitting element 20P and the first light receiving element 30P with terminals. In the description below, the same reference characters are given to those components that are the same as the corresponding components of the insulation module 10 of the first embodiment. Such components will not be described in detail.

FIG. 20 is a circuit diagram schematically showing the circuit structure of the insulation module 10 and the connection structure of the insulation module 10 and an inverter circuit 500.

The inverter circuit 500 of the present embodiment is a half-bridge inverter circuit and includes a first switching element 501 and a second switching element 502 that are connected in series to each other.

The terminal 51A of the insulation module 10 is electrically connected to a positive electrode of a control power source 503. The terminal 51D of the insulation module 10 is electrically connected between the source of the first switching element 501 and the drain of the second switching element 502.

As shown in FIG. 20, the insulation module 10 includes a first light emitting diode 20AP, a second light emitting diode 20AQ, a first light receiving diode 30AP, a second light receiving diode 30AQ, a first control circuit 230A, and a second control circuit 230B. The structures of the light emitting diodes 20AP and 20AQ and the light receiving diodes 30AP and 30AQ are the same as those of the first embodiment.

The first light emitting diode 20AP is connected to the terminals 51A and 51D. More specifically, the first electrode 21P (anode electrode) of the first light emitting diode 20AP is electrically connected to the terminal 51A, and the second electrode 22P (cathode electrode) is electrically connected to the terminal 51D. The control power source 503 is electrically connected to the terminal 51A. The control power source 503 supplies drive voltage to the first light emitting diode 20AP and the second control circuit 230B.

The first light receiving diode 30AP is electrically connected to the first control circuit 230A and is insulated from the first light emitting diode 20AP. In other words, the first light emitting diode 20AP is insulated from the first control circuit 230A. The first light emitting diode 20AP is electrically connected to the second control circuit 230B. The first electrode 31P (anode electrode) and the second electrode 32P (cathode electrode) of the first light receiving diode 30AP are electrically connected to the first control circuit 230A. The first control circuit 230A is electrically connected to the terminals 41A to 41D.

The second light emitting diode 20AQ is connected to the terminals 41A and 41D. More specifically, the first electrode 21Q (anode electrode) of the second light emitting diode 20AQ is electrically connected to the terminal 41A, and the second electrode 22Q (cathode electrode) is electrically connected to the terminal 41D. A control power source 504 is electrically connected to the terminal 41A. The control power source 504 supplies drive voltage to the second light emitting diode 20AQ and the first control circuit 230A.

The second light receiving diode 30AQ is electrically connected to the second control circuit 230B and is insulated from the second light emitting diode 20AQ. In other words, the second light emitting diode 20AQ is insulated from the second control circuit 230B. The second light emitting diode 20AQ is electrically connected to the first control circuit 230A. The first electrode 31Q (anode electrode) and the second electrode 32Q (cathode electrode) of the second light receiving diode 30AQ are electrically connected to the second control circuit 230B. The second control circuit 230B is electrically connected to the terminals 51A to 51D.

As described above, the first light emitting diode 20AP and the first light receiving diode 30AP form a photocoupler that transmits a signal from the terminals 51A to 51D, that is, the inverter circuit 500, to the terminals 41A to 41D. The second light emitting diode 20AQ and the second light receiving diode 30AQ form a photocoupler that transmits a signal from the terminals 41A to 41D to the terminals 51A to 51D. Thus, the insulation module 10 of the present embodiment is configured to bidirectionally transmit signals.

The structures of the control circuits 230A and 230B will now be described.

The first control circuit 230A includes a first Schmitt trigger 231A, a first output portion 232A, a first current source 233A, and a first driver 234A. The first current source 233A and the first driver 234A form a drive unit that drives the second light emitting diode 20AQ.

The structures of the first Schmitt trigger 231A and the first output portion 232A are the same as those in the first embodiment. The connection of the first Schmitt trigger 231A with the first light receiving diode 30AP and the connection of the first Schmitt trigger 231A with the first output portion 232A are the same as those of the first embodiment. The first output portion 232A is connected to the terminals 41A, 41B, and 41D, which differs from that of the first embodiment. More specifically, the first control circuit 230A is connected to the terminals 41A, 41B, and 41D instead of the terminals 51B to 51D electrically connected to the inverter circuit 500. The first output portion 232A includes a first switching element 232Aa and a second switching element 232Ab that form a complementary MOS in the same manner as the first embodiment.

The first current source 233A is electrically connected to the terminal 41A and the first electrode 21Q of the second light emitting diode 20AQ. This allows a constant current to be supplied to the second light emitting diode 20AQ from the terminal 41A.

The first driver 234A is electrically connected to both the first current source 233A and the terminal 41C. The first driver 234A is a circuit that controls the supply of current to the second light emitting diode 20AQ. More specifically, the first driver 234A controls the supply of current to the second light emitting diode 20AQ based on a control signal provided to the terminal 41C from the outside of the insulation module 10. In an example, when the control signal is input to the first driver 234A, the first driver 234A supplies current to the second light emitting diode 20AQ. When the control signal is not input to the first driver 234A, the first driver 234A does not supply current to the second light emitting diode 20AQ.

The second control circuit 230B includes a second Schmitt trigger 231B, a second output portion 232B, a second current source 233B, and a second driver 234B. The second current source 233B and the second driver 234B form a drive unit that drives the first light emitting diode 20AP.

The structures of the second Schmitt trigger 231B and the second output portion 232B are the same as those in the first embodiment. The connection of the second Schmitt trigger 231B with the second light receiving diode 30AQ, the connection of the second Schmitt trigger 231B with the second output portion 232B, and the connection of the second output portion 232B with the terminals 51A, 51B, 51D are the same as those of the first embodiment. The second output portion 232B includes a first switching element 232Ba and a second switching element 232Bb that form a complementary MOS in the same manner as the first embodiment.

The second current source 233B is electrically connected to the terminal 51A and the first electrode 21P of the first light emitting diode 20AP. This allows a constant current to be supplied to the first light emitting diode 20AP from the terminal 51A.

The second driver 234B is electrically connected to both the second current source 233B and the terminal 51B. The second driver 234B is a circuit that controls the supply of current to the first light emitting diode 20AP. More specifically, the second driver 234B controls the supply of current to the first light emitting diode 20AP based on a control signal provided to the terminal 51B from the outside of the insulation module 10. In an example, when the control signal is input to the second driver 234B, the second driver 234B supplies current to the first light emitting diode 20AP. When the control signal is not input to the second driver 234B, the second driver 234B does not supply current to the first light emitting diode 20AP.

In the present embodiment, the terminal 51B is electrically connected to a detection circuit 505 that detects voltage between the source of the first switching element 501 of the inverter circuit 500 and the drain of the second switching element 502. When the detection circuit 505 detects an excessively high voltage between the source of the first switching element 501 and the drain of the second switching element 502, the detection circuit 505 provides an anomaly signal to the terminal 51B as the control signal. In an example, the detection circuit 505 is configured to provide the anomaly signal to the terminal 51B when the voltage between the source of the first switching element 501 and the drain of the second switching element 502 is greater than a predetermined threshold value.

In the insulation module 10 of the present embodiment, the first control circuit 230A may include a current limiting resistor instead of the first current source 233A. The second control circuit 230B may include a current limiting resistor instead of the second current source 233B.

The first driver 234A and the first current source 233A can be omitted from the first control circuit 230A. In this case, the first electrode 21Q of the second light emitting diode 20AQ is electrically connected to the terminal 41A. The second electrode 22Q is electrically connected to the terminal 41D. The second driver 234B and the second current source 233B may be omitted from the second control circuit 230B. In this case, the first electrode 21P of the first light emitting diode 20AP is electrically connected to the terminal 51A, and the second electrode 22P is electrically connected to the terminal 51D.

Advantages of Sixth Embodiment

The insulation module 10 of the present embodiment has the following advantages.

(6-1) The insulation module 10 includes the first photocoupler formed of the first light emitting element 20P and the first light receiving element 30P and the second photocoupler formed of the second light emitting element 20Q and the second light receiving element 30Q. The first light emitting element 20P is electrically connected to the first lead frame 40. The second light emitting element 20Q is electrically connected to the second lead frame 50. The first light receiving element 30P is electrically connected to the second lead frame 50. The second light receiving element 30Q is electrically connected to the first lead frame 40.

In this structure, the first photocoupler transmits a signal from the first lead frame 40 toward the second lead frame 50. The second photocoupler transmits a signal from the second lead frame 50 toward the first lead frame 40. Thus, the insulation module 10 bidirectionally transmits signals.

### Modified Examples

The above embodiments exemplify, without any intention to limit, applicable forms of an insulation module according to the present disclosure. The insulation module according to the present disclosure can be applicable to forms differing from the above embodiments. In an example of such a form, the structure of the embodiments is partially replaced, changed, or omitted, or a further structure is added to the embodiments. The modified examples described below may be combined with one another as long as there is no technical inconsistency. In the modified examples, the same reference characters are given to those components that are the same as the corresponding components of the above embodiments. Such components will not be described in detail.

The first to sixth embodiments may be combined.

In the third to sixth embodiments, the position of the first electrode 21P in the element main surface 20Ps of the first light emitting element 20P in the x-direction may be changed in any manner. In an example, the first electrode 21P may be arranged in the center of the element main surface 20Ps of the first light emitting element 20P in the x-direction. In this structure, the connecting part WAX, which is part of the wire WA1 connected to the first electrode 21P, is located at the center of the element main surface 20Ps in the x-direction. In the same manner, the connecting part WAY, which is part of the wire WA2 connected to the first electrode 21Q of the second light emitting element 20Q, may be located at the center of the element main surface 20Qs of the second light emitting element 20Q in the x-direction.

In each embodiment, the number of the wires WA1 and WA2 may be changed in any manner. The number of the wires WA1 and WA2 may be one or three or more.

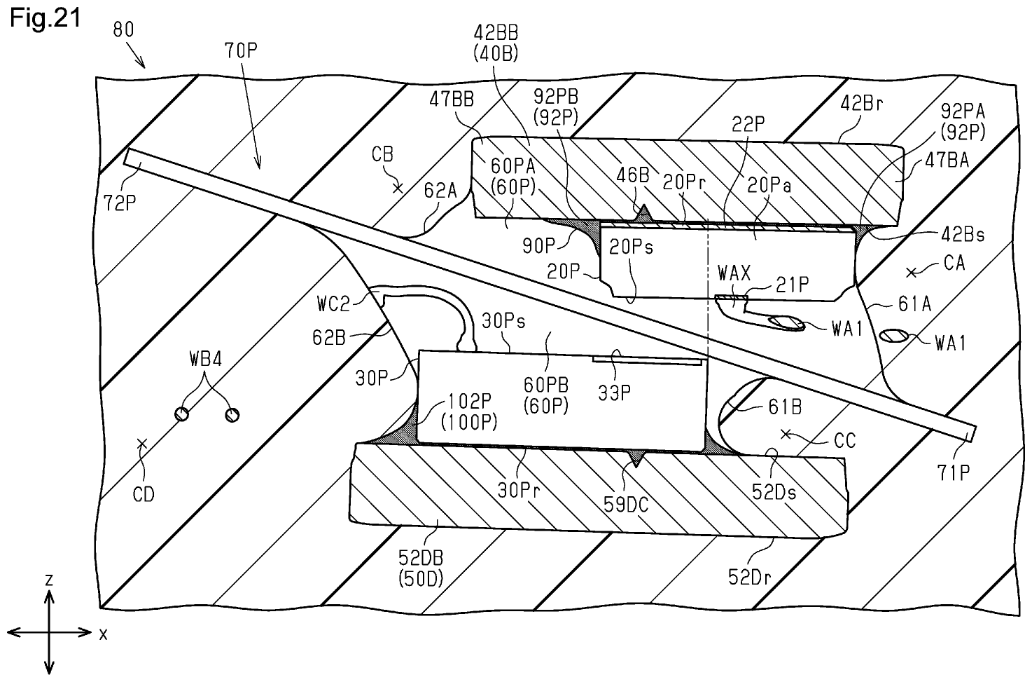

In the second embodiment, the position of the first electrode 21P of the first light emitting element 20P in the x-direction may be changed to any position within the extension region 20Pa. In an example, as shown in FIG. 21, when the extension region 20Pa of the first light emitting element 20P includes the center of the element main surface 20Ps in the x-direction, the first electrode 21P may be arranged in the center of the element main surface 20Ps in the x-direction. In this structure, the connecting part WAX, which is part of the wire WA1 connected to the first electrode 21P, is arranged at the center of the element main surface 20Ps in the x-direction. Thus, as viewed in the z-direction, the wire WA1 does not overlap the light receiving surface 33P of the first light receiving element 30P, that is, is located closer to the first resin side surface 81 than the light receiving surface 33P is. This structure obtains the same advantages as the second embodiment.

In the second embodiment, the connecting part WAX of the wire WA1 is located in the first transparent resin 60P. Alternatively, the connecting part WAX may be located outside the first transparent resin 60P. In this case, the entire wire WA1 is encapsulated by the encapsulation resin 80. Thus, the portion of the element main surface 20Ps of the first light emitting element 20P including the first electrode 21P may be covered by the encapsulation resin 80. The extension region 20Pa of the first light emitting element 20P may be covered by the encapsulation resin 80.

In each embodiment, the position of the first light emitting element 20P relative to the first light receiving element 30P in the x-direction may be changed in any manner. The first light emitting element 20P may be opposed in the z-direction to a position closer to the center of the first light receiving element 30P in the x-direction than one of the two ends of the first light receiving element 30P in the x-direction that is located closer to the first resin side surface 81. The position of the second light emitting element 20Q relative to the second light receiving element 30Q in the x-direction may be changed in the same manner.

In each embodiment, the distance between the first light emitting element 20P and the first light receiving element 30P in the z-direction may be changed in any manner. In an example, the distance between the first light emitting element 20P and the first light receiving element 30P in the z-direction may be greater than the thickness of the first light emitting element 20P (the dimension of the first light emitting element 20P in the z-direction). In an example, the distance between the first light emitting element 20P and the first light receiving element 30P in the z-direction may be greater than the thickness of the first light receiving element 30P (the dimension of the first light receiving element 30P in the z-direction).

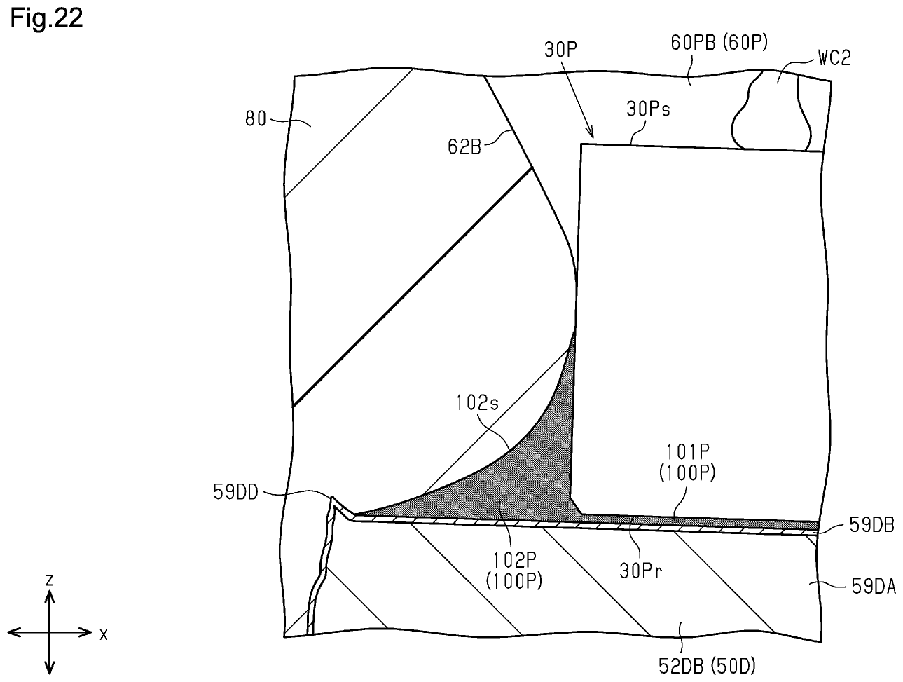

In each embodiment, as shown in FIG. 22, a ridge 59DD may be arranged on one of the two ends of the die pad 52DB of the second lead frame 50D in the x-direction that is located closer to the second resin side surface 82 (refer to FIG. 5). The ridge 59DD extends upward. More specifically, the ridge 59DD includes the main metal layer 59DA and the plated layer 59DB. In the ridge 59DD, the height-wise dimension of the portion formed of the main metal layer 59DA is greater than the thickness of the plated layer 59DB. The height-wise dimension of the ridge 59DD may be changed in any range that is effective in limiting leakage of the conductive bonding material 100P to a side surface of the die pad 52DB in the x-direction.

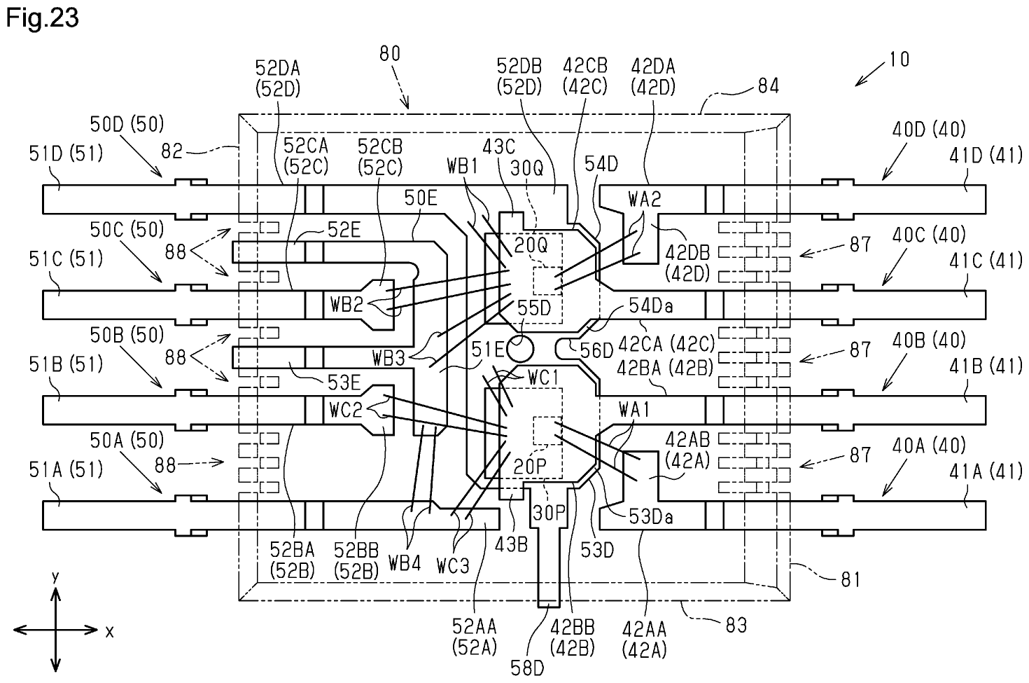

In each embodiment, the position of the suspension lead 58D arranged on the die pad 52DB of the second lead frame 50D may be changed in any manner. In an example, as shown in FIG. 23, the suspension lead 58D may extend from the distal end of the protrusion 57D of the die pad 52DB toward the third resin side surface 83 in the y-direction. In this case, the suspension lead 58D is exposed from the third resin side surface 83. In the modified example shown in FIG. 23, the first resin side surface 81 and the second resin side surface 82 correspond to “terminal surface.” The third resin side surface 83 corresponds to a “suspension lead surface.”

In this structure, the suspension lead 58D is not exposed from the second resin side surface 82 between the terminal 51A and the terminal 51B in the y-direction. Thus, the insulation property is affected by the creepage distance of the second resin side surface 82 between the terminal 51A and the terminal 51B. In addition, the recess-projection portions 88 may be increased in the number of recesses and protrusions between the terminal 51A and the terminal 51B. This enhances the insulation between the terminal 51A and the terminal 51B.

In each embodiment, at least one of the recess-projection portion 87 and the recess-projection portion 88 may be omitted from the encapsulation resin 80.

In the first and second embodiments, when the encapsulation resin 80 has at least one of a structure in which the recess-projection portions 87 are arranged on the first resin side surface 81 and a structure in which the recess-projection portions 88 are arranged on the second resin side surface 82, the position of the first electrode 21P in the element main surface 20Ps of the first light emitting element 20P in the x-direction may be changed in any manner. In an example, the first electrode 21P may be arranged in the center of the element main surface 20Ps of the first light emitting element 20P in the x-direction. In this structure, the connecting part WAX, which is part of the wire WA1 connected to the first electrode 21P, is located at the center of the element main surface 20Ps in the x-direction. In the same manner, the connecting part WAY, which is part of the wire WA2 connected to the first electrode 21Q of the second light emitting element 20Q, may be located at the center of the element main surface 20Qs of the second light emitting element 20Q in the x-direction.

In this modified example, the suspension lead 58D may be exposed from the third resin side surface 83 as in the modified example shown in FIG. 23. In this case, the first resin side surface 81 and the second resin side surface 82 correspond to “terminal surface,” and the third resin side surface 83 corresponds to a “suspension lead surface.”

In each embodiment, each of the first transparent resin 60P and the second transparent resin 60Q may be configured to allow passage of light (first wavelength light) from the first light emitting element 20P and light (second wavelength light) from the second light emitting element 20Q.

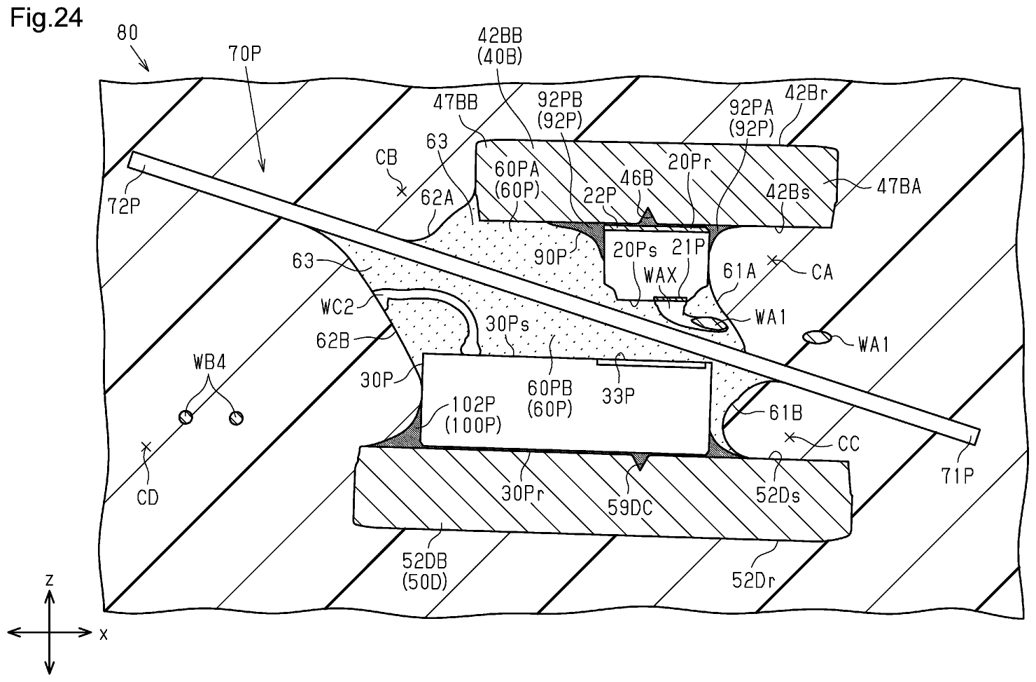

In each embodiment, the first transparent resin 60P may include an inorganic particle 63 that absorbs or reflects light from the first light emitting element 20P. In an example, as shown in FIG. 24, the light-emitting-side transparent resin 60PA and the light-receiving-side transparent resin 60PB of the first transparent resin 60P include the inorganic particle 63. An example of the inorganic particle 63 is a filler. The inorganic particle 63 is present in the entire first transparent resin 60P.

The amount of the inorganic particle 63 contained in the first transparent resin 60P may be changed in any manner. The amount of the inorganic particle 63 contained in the first transparent resin 60P is, for example, set so that the first light receiving element 30P receives an amount of light from the first light emitting element 20P that is in a predetermined range.

The cross-sectional shape of the inorganic particle 63 may be elliptical or circular. The inorganic particle 63 may include different types of inorganic particle having different cross-sectional shapes. In an example, the inorganic particle 63 may include a first inorganic particle having a first cross-sectional shape and a second inorganic particle having a second cross-sectional shape.

The inorganic particle 63 may include inorganic particles having the same size. The inorganic particle 63 may include different types of inorganic particle having different sizes. In an example, the inorganic particle 63 may include a first inorganic particle having a first size and a second inorganic particle having a second size.

The inorganic particle 63 may include different types of inorganic particle that differ from each other in material. In an example, the inorganic particle 63 may include a first inorganic particle formed from a first material and a second inorganic particle formed from a second material that differs from the first material.

The inorganic particle 63 include inorganic particles having the same size, the same cross-sectional shape, and the same material.

The inorganic particle 63 may include different types of inorganic particle formed of a combination of different cross-sectional shapes, different sizes, and different materials. The color of the inorganic particle 63 may be black to mainly absorb light or white to mainly reflect light.

In the first transparent resin 60P, at least one of the light-emitting-side transparent resin 60PA and the light-receiving-side transparent resin 60PB may include the inorganic particle 63. More specifically, in the first transparent resin 60P, while the light-emitting-side transparent resin 60PA includes an inorganic particle, the light-receiving-side transparent resin 60PB may include no inorganic particle. In the first transparent resin 60P, while the light-receiving-side transparent resin 60PB includes inorganic particle, the light-emitting-side transparent resin 60PA may include no inorganic particle. In the same manner, the second transparent resin 60Q may include an inorganic particle that absorbs or reflects light from the second light emitting element 20Q.

When the first transparent resin 60P includes the inorganic particle 63, the position of the first electrode 21P in the element main surface 20Ps of the first light emitting element 20P in the x-direction may be changed in any manner. In an example, the first electrode 21P may be arranged in the center of the element main surface 20Ps of the first light emitting element 20P in the x-direction. In this structure, the connecting part WAX, which is part of the wire WA1 connected to the first electrode 21P, is located at the center of the element main surface 20Ps in the x-direction. When the second transparent resin 60Q includes the inorganic particle 63, the connecting part WAY, which is part of the wire WA2 connected to the first electrode 21Q of the second light emitting element 20Q, may be located at the center of the element main surface 20Qs of the second light emitting element 20Q in the x-direction.

In each embodiment, the first plate-shaped member 70P may include an inorganic particle that absorbs or reflects light from the first light emitting element 20P. The second plate-shaped member 70Q may include an inorganic particle that absorbs or reflects light from the second light emitting element 20Q. The inorganic particle of the first plate-shaped member 70P and the inorganic particle of the second plate-shaped member 70Q may be, for example, the same as the inorganic particle 63 shown in FIG. 24.

When the first plate-shaped member 70P includes the inorganic particle, the position of the first electrode 21P in the element main surface 20Ps of the first light emitting element 20P in the x-direction may be changed in any manner. In an example, the first electrode 21P may be arranged in the center of the element main surface 20Ps of the first light emitting element 20P in the x-direction. In this structure, the connecting part WAX, which is part of the wire WA1 connected to the first electrode 21P, is located at the center of the element main surface 20Ps in the x-direction. When the second plate-shaped member 70Q includes the inorganic particle, the connecting part WAY, which is part of the wire WA2 connected to the first electrode 21Q of the second light emitting element 20Q, may be located at the center of the element main surface 20Qs of the second light emitting element 20Q in the x-direction.

In each embodiment, each of the first transparent resin 60P and the first plate-shaped member 70P may include an inorganic particle that absorbs or reflects light from the first light emitting element 20P. Also, each of the second transparent resin 60Q and the second plate-shaped member 70Q may include an inorganic particle that absorbs or reflects light from the second light emitting element 20Q.

When at least one of the transparent resins 60P and 60Q and the plate-shaped members 70P and 70Q includes an inorganic particle, the die pad 52DB, on which the light receiving elements 30P and 30Q are mounted, may be configured to be inclined toward the resin back surface 80r from the second resin side surface 82 toward the first resin side surface 81. The inclination direction of the die pad 52DB with respect to a direction (horizontal direction) orthogonal to the z-direction is the same as the inclination direction of the plate-shaped members 70P and 70Q with respect to the horizontal direction. The inclination angle of the die pad 52DB with respect to the horizontal direction is less than the inclination angle of the plate-shaped members 70P and 70Q with respect to the horizontal direction.

The inclination angle of the die pad 52DB with respect to the horizontal direction is, for example, in a range of 10 to 2°. The inclination angle of the die pad 52DB with respect to the horizontal direction is not limited to this and may be, for example, any value in a range of greater than 0° and less than or equal to 10°. Alternatively, the inclination angle of the die pad 52DB with respect to the horizontal direction may be in a range of 2° to 3°, in a range of 3° to 4°, in a range of 4° to 5°, in a range of 5° to 6°, in a range of 6° to 7°, or in a range of 7° to 8°.

As described above, when the die pad 52DB is inclined with respect to the horizontal direction, the height-wise position of the terminals 51A to 51D, projecting from the second resin side surface 82 of the encapsulation resin 80, is adjusted to a standard height-wise position specified in advance, and a thick inorganic particle may be included in at least one of the transparent resins 60P and 60Q and the plate-shaped members 70P and 70Q. More specifically, when at least one of the transparent resins 60P and 60Q and the plate-shaped members 70P and 70Q includes an inorganic particle and the volume of the member including the inorganic particle is increased, the inclination of the die pad 52DB with respect to the horizontal direction ensures the space for the increased volume.

In the same manner, the die pad 42BB, on which the first light emitting element 20P is mounted, and the die pad 42CB, on which the second light emitting element 20Q is mounted, may be configured to be inclined toward the resin back surface 80r from the second resin side surface 82 toward the first resin side surface 81. In other words, the die pads 42BB and 42CB may be configured to be inclined toward the resin main surface 80s from the first resin side surface 81 toward the second resin side surface 82. As described above, the die pads 42BB and 42CB are configured to be inclined in the same direction as the die pad 52DB. The inclination direction of die pads 42BB and 42CB with respect to a direction (horizontal direction) orthogonal to the z-direction is the same as the inclination direction of the plate-shaped members 70P and 70Q with respect to the horizontal direction. The inclination angle of the die pads 42BB and 42CB with respect to the horizontal direction is less than the inclination angle of the plate-shaped members 70P and 70Q with respect to the horizontal direction.

The inclination angle of the die pads 42BB and 42CB with respect to the direction (horizontal direction) orthogonal to the z-direction is, for example, in a range of 10 to 2°. The inclination angle of the die pads 42BB and 42CB with respect to the horizontal direction is not limited to this and may be, for example, any value in a range of greater than 0° and less than or equal to 10°. Alternatively, the inclination angle of the die pads 42BB and 42CB with respect to the horizontal direction may be in a range of 2° to 3°, in a range of 3° to 4°, in a range of 4° to 5°, in a range of 5° to 6°, in a range of 6° to 7°, or in a range of 7° to 8°.

As described above, when the die pads 42BB and 42CB are inclined with respect to the horizontal direction, the height-wise position of the terminals 41A to 41D, projecting from the first resin side surface 81 of the encapsulation resin 80, is adjusted to a standard height-wise position specified in advance, and a thick inorganic particle may be included in at least one of the transparent resins 60P and 60Q and the plate-shaped members 70P and 70Q. More specifically, when at least one of the transparent resins 60P and 60Q and the plate-shaped members 70P and 70Q includes an inorganic particle and the volume of the member including the inorganic particle is increased, the inclination of the die pads 42BB and 42CB with respect to the horizontal direction ensures the space for the increased volume.

In the first, second, fifth, and sixth embodiments, the first insulation portion 36PA may include the wiring layers 38PA to 38PE. In this case, As viewed in the z-direction, the optical-electrical conversion element 35PA includes a region extending beyond the wiring layers 38PA to 38PE.

As viewed in the z-direction, the amount of light received by the optical-electrical conversion element 35PA may be adjusted by adjusting the area of each layer of each of the wiring layers 38PA to 38PE (hereafter, simply referred to as the area of each of the wiring layers 38PA to 38PE) arranged on the optical-electrical conversion element 35PA. More specifically, at the time of designing the insulation module 10, the area of each of the wiring layers 38PA to 38PE is set so that the optical-electrical conversion element 35PA receives an amount of light that is within a predetermined range. In an example, in the z-direction, the area of each of the wiring layers 38PA to 38PE is set so that the percentage of the light that perpendicularly enters the optical-electrical conversion element 35PA without reflecting is in a range of 60% to 70%. The percentage of the light that perpendicularly enters the optical-electrical conversion element 35PA without reflecting is not limited to the range of 60% to 70% and may be, for example, a range of 30% to 40%, a range of 40% to 50%, a range of 50% to 60%, a range of 70% to 80%, or a range of 80% to 90%. As described above, the percentage of light that perpendicularly enters the optical-electrical conversion element 35PA without reflecting is appropriately adjusted by adjusting the wiring pattern of the wiring layers 38PA to 38PE in accordance with the properties of the optical-electrical conversion element 35PA and the like.

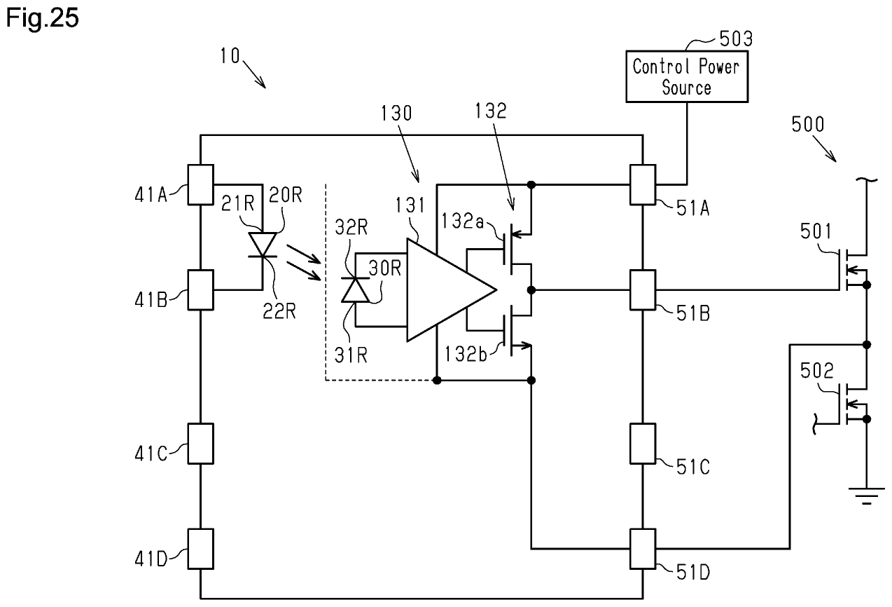

In each embodiment, the number of photocouplers formed of a light emitting element and a light receiving element may be changed in any manner. In an example, the insulation module 10 may include one photocoupler. FIG. 25 is a circuit diagram schematically showing an example of the circuit structure of an insulation module 10 including one photocoupler and the connection structure of the insulation module 10 and the inverter circuit 500.

Although not shown, the insulation module 10 includes a light emitting element and a light receiving element configured to receive light from the light emitting element. The light emitting element is configured in the same manner as the first light emitting element 20P of the first embodiment. The light receiving element is configured in the same manner as the first light receiving element 30P of the first embodiment. The light emitting element and the light receiving element are encapsulated, for example, in the same manner as the first transparent resin 60P, the first plate-shaped member 70P, the first light emitting element 20P, and the first light receiving element 30P are encapsulated by the encapsulation resin 80 in the first embodiment.

As shown in FIG. 25, the inverter circuit 500 includes the first switching element 501 and the second switching element 502 that are connected in series to each other. The switching elements 501 and 502 are each, for example, a transistor. Examples of the transistor include a MOSFET and an IGBT. In this modified example, a MOSFET is used as each of the switching elements 501 and 502.

In the example shown, the insulation module 10 applies a drive voltage signal to the gate of the first switching element 501. The insulation module 10 is a gate driver configured to drive the first switching element 501.

The terminal 51A of the insulation module 10 is electrically connected to a positive electrode of a control power source 503. The terminal 51D of the insulation module 10 is connected between the source of the first switching element 501 and the drain of the second switching element 502.

The electrical configuration of the insulation module 10 is, for example, the same as that of the insulation module 10 of the first embodiment, with omission of the second light emitting diode 20AQ, the second light receiving diode 30AQ, and the second control circuit 130B.

The insulation module 10 includes a light emitting diode 20R, a light receiving diode 30R, and a control circuit 130. The light emitting diode 20R has the same structure as the first light emitting diode 20AP of the first embodiment. The light receiving diode 30R has the same structure as the first light receiving diode 30AP of the first embodiment.

The light emitting diode 20R includes a first electrode 21R electrically connected to the terminal 41A and a second electrode 22R electrically connected to the terminal 41B.

The light receiving diode 30R is electrically connected to the control circuit 130 and is insulated from the light emitting diode 20R. In an example, the light receiving diode 30R includes a first electrode 31R as the anode electrode and a second electrode 32R as the cathode electrode. The first electrode 31R and the second electrode 32R are electrically connected to the control circuit 130.

The control circuit 130 includes a Schmitt trigger 131 and an output portion 132 in the same manner as the first control circuit 130A of the first embodiment. The control circuit 130 generates a drive voltage signal based on a change in the voltage of the light receiving diode 30R when the light receiving diode 30R receives light from the light emitting diode 20R.

The Schmitt trigger 131 is electrically connected to the first electrode 31R and the second electrode 32R of the light receiving diode 30R. The Schmitt trigger 131 is electrically connected to the terminals 51A and 51D. Thus, the Schmitt trigger 131 is supplied with power from the control power source 503. The Schmitt trigger 131 transfers voltage from the light receiving diode 30R to the output portion 132. The Schmitt trigger 131 has a threshold voltage having a predetermined hysteresis. This configuration increases resistance to noise.

The output portion 132 includes a first switching element 132a and a second switching element 132b that are connected in series to each other. In the example shown, a p-type MOSFET is used in the first switching element 132a, and an n-type MOSFET is used in the second switching element 132b. The switching elements 132a and 132b are connected in the same manner as the first embodiment.

The gate of the first switching element 132a and the gate of the second switching element 132b are electrically connected to the Schmitt trigger 131. Thus, a signal is applied from the Schmitt trigger 131 to each of the gate of the first switching element 132a and the gate of the second switching element 132b.

The output portion 132 generates a drive voltage signal in accordance with complementary activation and deactivation of the first switching element 132a and the second switching element 132b based on the signal from the Schmitt trigger 131. The output portion 132 applies the drive voltage signal to the gate of the first switching element 501.

The insulation module 10 shown in FIG. 25 may include a driver and a current source as in the sixth embodiment. The current source is arranged between the terminal 41A and the first electrode 21R of the light emitting diode 20R. The driver is arranged, for example, to connect the terminal 41C and the current source. Thus, the current supplied to the light emitting diode 20R is controlled in accordance with a signal input to the terminal 41C.

The insulation module 10 of the first to fifth embodiments may include the second driver 234B and the second current source 233B, which drive the first light emitting diode 20AP, and the first driver 234A and the first current source 233A, which drive the second light emitting diode 20AQ, as in the sixth embodiment.

In the present disclosure, the term “on” includes the meaning of “above” in addition to the meaning of “on” unless otherwise clearly indicated in the context. Thus, the phrase “A is formed on B” is intended to mean that A may be disposed directly on B in contact with B in the embodiments and also that A may be disposed above B without contacting B in a modified example. In other words, the term “on” does not exclude a structure in which another member is formed between A and B.

In this specification, “at least one of A and B” should be understood to mean “only A, only B, or both A and B.”

Clauses

The technical aspects that are understood from the present disclosure will hereafter be described. It should be noted that, for the purpose of facilitating understanding with no intention to limit, elements described in clauses are given the reference characters of the corresponding elements of the embodiments. The reference characters used as examples to facilitate understanding, and the elements in each clause are not limited to those elements given with the reference characters.

A1. An insulation module (10), including:
a light emitting element (20P) including a light emitting surface (20Ps) and a pad (21P) formed on the light emitting surface (20Ps);
a light receiving element (30P) including a light receiving surface (33P) spaced apart and faced to the light emitting surface (20Ps), the light receiving element (30P) and the light emitting element (20P) forming a photocoupler;
a plate-shaped member (70P) arranged between the light emitting surface (20Ps) and the light receiving surface (33P) and inclined from each of the light emitting surface (20Ps) and the light receiving surface (33P), the plate-shaped member (70P) being light-transmissive and electrically insulating; and
a wire (WA1) connected to the pad (21P),
where the pad (21P) is offset from a center of the light emitting surface (20Pa) toward a portion at which a distance to the plate-shaped member (70P) is greater than that at the center.

A2. The insulation module according to clause A1, where
as viewed in a direction orthogonal to the light emitting surface (20Ps), the light emitting element (20Ps) is rectangular, defined in a longitudinal direction and a lateral direction,
the light emitting surface (20Ps) is separated further away from the plate-shaped member (70P) from a first side toward a second side in the longitudinal direction,
the pad (21P) is offset in the longitudinal direction from the center of the light emitting surface (20Pa) toward a portion at which a distance to the plate-shaped member (70P) is greater than that at the center, and
the wire (WA1) is connected to the pad (21P) so as not to contact the plate-shaped member (70P).

A3. An insulation module, including:
a light emitting element (20P) including a light emitting surface (20Ps) and a pad (21P) formed on the light emitting surface (20Ps);
a light receiving element (30P) including a light receiving surface (33P) spaced apart and faced to the light emitting surface (20Ps), the light receiving element (30P) and the light emitting element (20P) forming a photocoupler;
a plate-shaped member (70P) arranged between the light emitting surface (20Ps) and the light receiving surface (33P) and inclined from each of the light emitting surface (20Ps) and the light receiving surface (33P), the plate-shaped member (70P) being light-transmissive and electrically insulating; and
a wire (WA1) connected to the pad (21P), where
as viewed in a direction orthogonal to the light emitting surface (20Ps), the light emitting element (20P) is rectangular, defined in a longitudinal direction and a lateral direction,
the light emitting surface (20Ps) is separated further away from the plate-shaped member (70P) from a first side toward a second side in the longitudinal direction,
the light emitting surface (20Ps) includes an extension region (20Pa) that extends beyond the light receiving element (30P) toward the second side in the longitudinal direction, and the pad (21P) is arranged in the extension region (20Pa).

A4. The insulation module according to any one of clauses A1 to A3, where
a maximum distance between the light emitting surface (20Ps) and the plate-shaped member (70P), opposed to the light emitting surface (20Ps), is less than a thickness of the light emitting element (20P).

A5. The insulation module according to any one of clauses A1 to A4, where a maximum distance (D1) between the light emitting surface (20Ps) and the plate-shaped member (70P), opposed to the light emitting surface (20Ps), is less than a thickness of the light receiving element (30P).

A6. The insulation module according to any one of clauses A1 to A5, where a thickness of the light emitting element (20P) is less than a thickness of the light receiving element (30P).

A7. The insulation module according to any one of clauses A1 to A6, where a minimum distance between the pad (21P) and the plate-shaped member (70P), opposed to the pad (21P), is greater than or equal to one-half of a distance (DG) between the light emitting surface (20Ps) and the light receiving surface (33P).

A8. The insulation module according to any one of clauses A1 to A7, including:
a transparent resin (60P) at least partially arranged between the light emitting surface (20Ps) and the light receiving surface (33P); and
a light-blocking encapsulation resin (80) covering the transparent resin (60P), the light emitting element (20P), the light receiving element (30P), and the plate-shaped member (70P).

A9. The insulation module according to clause A8, where
the transparent resin (60P) includes a light-emitting-side transparent resin (60PA) arranged between the plate-shaped member (70P) and the light emitting element (20P) and a light-receiving-side transparent resin (60PB) arranged between the plate-shaped member (70P) and the light receiving element (30P), and
the light-receiving-side transparent resin (60PB) includes a side surface (62B) that is curved to have a center of curvature (CD) located on a side of the side surface (62B) of the light-receiving-side transparent resin (60PB) opposite the plate-shaped member (70P).

A10. The insulation module according to clause A9, where the light-emitting-side transparent resin (60PA) includes a side surface (62A) that is curved to have a center of curvature (CB) located on a side of the side surface (62A) of the light-emitting-side transparent resin (60PA) opposite the plate-shaped member (70P).

A11. The insulation module according to any one of clauses A8 to A10, where the encapsulation resin (80) covers a side surface of the light receiving element (30P).

A12. The insulation module according to any one of clauses A8 to A11, where
the encapsulation resin (80) includes a resin side surface (81/82) on which multiple terminals (41A to 41D/51A to 51D) are arranged, and
the resin side surface (81/82) includes a recess-projection portion (87/88) arranged between a first terminal and a second terminal of the multiple terminals (41A to 41D/51A to 51D).

A13. The insulation module according to clause A12, including:
a lead frame (50D) including a die pad (52DB) that supports the light receiving element (30P), where
the lead frame (50D) includes a suspension lead (58D) extending from the die pad (52DB),
the suspension lead (58D) is exposed from the resin side surface (82), and the resin side surface (83) includes the recess-projection portion (88) arranged between the suspension lead (58D), corresponding to the first terminal, and a terminal (51A, 51B) corresponding to the second terminal and located next to the suspension lead (58D).

A14. The insulation module according to any one of clauses A1 to A13, including:
a first die pad (42BB) supporting the light emitting element (20P); and
a second die pad (52DB) supporting the light receiving element (30P), where
a first recess (46B) is formed in the first die pad (42BB),
a second recess (59DC) is formed in the second die pad (52DB),
the light emitting element (20P) is bonded to the first die pad (42BB) including the first recess (46B) by a first bonding material (90P) arranged on the first die pad (42BB),
the light receiving element (30P) is bonded to the second die pad (52DB) including the second recess (59DC) by a second bonding material (100P) arranged on the second die pad (52DB),
the first die pad (42BB) and the second die pad (52DB) are arranged so that the first recess (46B) and the second recess (59DC) are opposed to each other.

A15. The insulation module according to any one of clauses A1 to A14, where
the light receiving element (30P) includes
   an optical-electrical conversion element (35PA),
   a control circuit (35PB) configured to receive a signal from the optical-electrical conversion element (35PA), and
   an insulation layer (36P) formed on the optical-electrical conversion element (35PA) and the control circuit (35PB),
the insulation layer (36P) includes
   a first insulation portion (36PA) formed on the optical-electrical conversion element (35PA), and
   a second insulation portion (36PB) formed on the control circuit (35PB), the second insulation portion (36PB) includes at least one first wiring layer, and the first insulation portion (36PA) includes at least one layer that is free of a wiring layer.

A16. The insulation module according to any one of clauses A1 to A14, where
the light receiving element (30P) includes
   an optical-electrical conversion element (35PA),
   a control circuit (35PB) configured to receive a signal from the optical-electrical conversion element (35PA), and
   an insulation layer (36P) formed on the optical-electrical conversion element (35PA) and the control circuit (35PB),
the insulation layer (36P) includes
   a first insulation portion (36PA) formed on the optical-electrical conversion element (35PA),
   a second insulation portion (36PB) formed on the control circuit (35PB), multiple first wiring layers are formed on the second insulation portion (36PB), and
one or more second wiring layers are formed on the first insulation portion (36PA) and are less in number than the first wiring layers of the second insulation portion (36PB).

A17. The insulation module according to any one of clauses A1 to A14, where
the light receiving element (30P) includes
   an optical-electrical conversion element (35PA), and
   a control circuit (35PB) configured to receive a signal from the optical-electrical conversion element (35PA), and
when the light receiving element (30P) receives a signal that includes multiple pulses from the light emitting element (20P), the control circuit (35PB) is configured to output an output signal based on a portion of the multiple pulses excluding an initial pulse.

A18. The insulation module according to any one of clauses A1 to A17, where
the light receiving element includes a first light receiving element (30P) and a second light receiving element (30Q),
the light emitting element includes a first light emitting element (20P) and a second light emitting element (20Q),
the first light emitting element (20P) and the first light receiving element (30P) form a first photocoupler,
the second light emitting element (20Q) and the second light receiving element (30Q) form a second photocoupler,
the insulation module (10), further including:
   a first transparent resin (60P) covering the first light emitting element (20P) and the first light receiving element (30P);
   a second transparent resin (60Q) covering the second light emitting element (20Q) and the second light receiving element (30Q); and
   an encapsulation resin (80) encapsulating the first transparent resin (60P) and the second transparent resin (60Q),
the encapsulation resin (80) includes a separation wall (89) that separates the first transparent resin (60P) from the second transparent resin (60Q).

A19. The insulation module according to any one of clauses A1 to A17, where
the light receiving element includes a first light receiving element (30P) and a second light receiving element (30Q),
the light emitting element includes a first light emitting element (20P) and a second light emitting element (20Q),
the first light emitting element (20P) and the first light receiving element (30P) form a first photocoupler,
the second light emitting element (20Q) and the second light receiving element (30Q) form a second photocoupler,
the insulation module (10), further including:
   a first transparent resin (60P) covering the first light emitting element (20P) and the first light receiving element (30P); and
   a second transparent resin (60Q) covering the second light emitting element (20Q) and the second light receiving element (30Q),
the first light emitting element (20P) is configured to emit light having a first wavelength,
the second light emitting element (20Q) is configured to emit light having a second wavelength that differs from the first wavelength,
the first transparent resin (60P) is formed from a resin material that transmits light having the first wavelength and does not transmit light having the second wavelength, and
the second transparent resin (60Q) is formed from a resin material that transmits light having the second wavelength and does not transmit light having the first wavelength.

A20. The insulation module according to clause A18 or A19, where the plate-shaped member includes
a first plate-shaped member (70P) arranged between the first light emitting element (20P) and the first light receiving element (30P), and
a second plate-shaped member (70Q) arranged between the second light emitting element (20Q) and the second light receiving element (30Q).

B1. An insulation module, including:
a light emitting element (20P) including a light emitting surface (20Ps); and
a light receiving element (30P) including a light receiving surface (33P) spaced apart and faced to the light emitting surface (20Ps), the light receiving element (30P) and the light emitting element (20P) forming a photocoupler,
where an infrared cut layer (200) that selectively cuts infrared is arranged on the light receiving surface (33P).

B2. The insulation module according to clause B1, where
the light receiving element (30P) includes an element main surface (30Ps) including the light receiving surface (33P),
the infrared cut layer (200) includes the element main surface (30Ps).

B3. The insulation module according to clause B1 or B2, where
the light receiving element (30P) includes
   an optical-electrical conversion element (35PA),
   a control circuit (35PB) configured to receive a signal from the optical-electrical conversion element (35PA), and
   an insulation layer (36P) formed on the optical-electrical conversion element (35PA) and the control circuit (35PB),
where the infrared cut layer (200) is formed on the insulation layer (36P).

B4. The insulation module according to clause B3, where the insulation layer (36P) is formed from a material that allows passage of infrared.

B5. The insulation module according to any one of clauses B1 to B4, where the infrared cut layer (200) is formed from a resin material.

B6. An insulation module, including:
a light emitting element (20P) including a light emitting surface (20Ps);
a light receiving element (30P) including a light receiving surface (33P) spaced apart and faced to the light emitting surface (20Ps), the light receiving element (30P) and the light emitting element (20P) forming a photocoupler;
a transparent resin (60P) at least partially arranged between the light emitting surface (20Ps) and the light receiving surface (33P); and
a plate-shaped member (70P) arranged between the light emitting surface (20Ps) and the light receiving surface (33P) and inclined from each of the light emitting surface (20Ps) and the light receiving surface (33P), the plate-shaped member (70P) being light-transmissive and electrically insulating,
where at least one of the transparent resin (60P) and the plate-shaped member (70P) includes an inorganic particle (63) that absorbs or reflects light from the light emitting element.

B7. The insulation module according to clause B6, where
the transparent resin (60P) includes a light-emitting-side transparent resin (60PA) arranged between the plate-shaped member (70P) and the light emitting element (20P) and a light-receiving-side transparent resin (60PB) arranged between the plate-shaped member (70P) and the light receiving element (30P), and
one of the light-emitting-side transparent resin (60PA) and the light-receiving-side transparent resin (60PB) includes the inorganic particle (63).

B8. The insulation module according to clause B6, where
the transparent resin (60P) includes a light-emitting-side transparent resin (60PA) arranged between the plate-shaped member (70P) and the light emitting element (20P) and a light-receiving-side transparent resin (60PB) arranged between the plate-shaped member (70P) and the light receiving element (30P), and
each of the light-emitting-side transparent resin (60PA) and the light-receiving-side transparent resin (60PB) includes the inorganic particle (63).

B9. The insulation module according to any one of clauses B6 to B8, including:
a first die pad (42BB) on which the light emitting element (20P) is mounted;
a second die pad (52DB) on which the light receiving element (30P) is mounted; and
an encapsulation resin (80) encapsulating the transparent resin (60P), the plate-shaped member (70P), the first die pad (42BB), the second die pad (52DB), the light emitting element (20P), and the light receiving element (30P),
where the second die pad (52DB) is configured to be inclined in a direction that is same as an inclination direction of the plate-shaped member (70P) with respect to a horizontal direction that is orthogonal to a thickness-wise direction (z-direction) of the encapsulation resin (80).

B10. The insulation module according to clause B9, where an inclination angle of the second die pad (52DB) with respect to the horizontal direction is less than an inclination angle of the plate-shaped member (70P) with respect to the horizontal direction.

B11. The insulation module according to any one of clauses B6 to B10, including:
a first die pad (42BB) on which the light emitting element (20P) is mounted;
a second die pad (52DB) on which the light receiving element (30P) is mounted; and
an encapsulation resin (80) encapsulating the transparent resin (60P), the plate-shaped member (70P), the first die pad (42BB), the second die pad (52DB), the light emitting element (20P), and the light receiving element (30P),
where the first die pad (42BB) is configured to be inclined in a direction that is same as an inclination direction of the plate-shaped member (70P) with respect to a horizontal direction that is orthogonal to a thickness-wise direction (z-direction) of the encapsulation resin (80).

B12. The insulation module according to clause B11, where
an inclination angle of the first die pad (42BB) with respect to the horizontal direction is less than an inclination angle of the plate-shaped member (70P) with respect to the horizontal direction.

B13. An insulation module, including:
a light emitting element (20P) including a light emitting surface (20Ps);
a light receiving element (30P) including a light receiving surface (33P) spaced apart and faced to the light emitting surface (20Ps), the light receiving element (30P) and the light emitting element (20P) forming a photocoupler;
a transparent resin (60P) at least partially arranged between the light emitting surface (20Ps) and the light receiving surface (33P); and
a plate-shaped member (70P) arranged between the light emitting surface (20Ps) and the light receiving surface (33P) and inclined from each of the light emitting surface (20Ps) and the light receiving surface (33P), the plate-shaped member (70P) being light-transmissive and electrically insulating,
where a transmittance of the plate-shaped member (70P) is lower than a transmittance of the transparent resin (60P).

B14. An insulation module, including:
a light emitting element (20P) including a light emitting surface (20Ps);
a light receiving element (30P) including a light receiving surface (33P) spaced apart and faced to the light emitting surface (20Ps), the light receiving element (30P) and the light emitting element (20P) forming a photocoupler;
a transparent resin (60P) at least partially arranged between the light emitting surface (20Ps) and the light receiving surface (33P); and
a plate-shaped member (70P) arranged between the light emitting surface (20Ps) and the light receiving surface (33P) and inclined from each of the light emitting surface (20Ps) and the light receiving surface (33P), the plate-shaped member (70P) being light-transmissive and electrically insulating,
where a transmittance of the transparent resin (60P) is lower than a transmittance of the plate-shaped member (70P).

C1. An insulation module, including:
a light emitting element (20P) including a light emitting surface (20Ps); and
a light receiving element (30P) including a light receiving surface (33P) spaced apart and faced to the light emitting surface (20Ps), the light receiving element (30P) and the light emitting element (20P) forming a photocoupler, where
the light receiving element (30P) includes
   an optical-electrical conversion element (35PA),
   a control circuit (35PB) configured to receive a signal from the optical-electrical conversion element (35PA), and
   an insulation layer (36P) formed on the optical-electrical conversion element (35PA) and the control circuit (35PB),
the insulation layer (36P) includes
   a first insulation portion (36PA) formed on the optical-electrical conversion element (35PA), and
   a second insulation portion (36PB) formed on the control circuit (35PB), the second insulation portion (36PB) includes at least one first wiring layer, and
the first insulation portion (36PA) includes at least one layer that is free of a wiring layer.

C2. An insulation module, including:
a light emitting element (20P) including a light emitting surface (20Ps); and
a light receiving element (30P) including a light receiving surface (33P) spaced apart and faced to the light emitting surface (20Ps), the light receiving element (30P) and the light emitting element (20P) forming a photocoupler, where
the light receiving element (30P) includes
   an optical-electrical conversion element (35PA),
   a control circuit (35PB) configured to receive a signal from the optical-electrical conversion element (35PA), and
   an insulation layer (36P) formed on the optical-electrical conversion element (35PA) and the control circuit (35PB),
the insulation layer (36P) includes
   a first insulation portion (36PA) formed on the optical-electrical conversion element (35PA), and
   a second insulation portion (36PB) formed on the control circuit (35PB), multiple first wiring layers are formed on the second insulation portion (36PB), and
one or more second wiring layers are formed on the first insulation portion (36PA) and are less in number than the first wiring layers of the second insulation portion (36PB).

C3. An insulation module, including:
a light emitting element (20P) including a light emitting surface (20Ps); and
a light receiving element (30P) including a light receiving surface (33P) spaced apart and faced to the light emitting surface (20Ps), the light receiving element (30P) and the light emitting element (20P) forming a photocoupler, where
the light receiving element (30P) includes
   an optical-electrical conversion element (35PA), and
   a control circuit (35PB) configured to receive a signal from the optical-electrical conversion element (35PA), and
when the light receiving element (30P) receives a signal that includes multiple pulses from the light emitting element (20P), the control circuit (35PB) is configured to output an output signal based on a portion of the multiple pulses excluding an initial pulse.

C4. The insulation module according to any one of clauses C1 to C3, where an infrared cut layer (200) that selectively cuts infrared is arranged on the light receiving surface (33P).

C5. The insulation module according to clause C4, where
the light receiving element (30P) includes an element main surface (30Ps) including the light receiving surface (33P), and the infrared cut layer (200) includes the element main surface (30Ps).

C6. The insulation module according to clause C4 or C5, where the insulation layer (36P) is formed from a material that allows passage of infrared.

C7. The insulation module according to any one of clauses C4 to C6, where the infrared cut layer (200) is formed from a resin material.

D1. An insulation module, including:
a light emitting element (20P) including a light emitting surface (20Ps);
a light receiving element (30P) including a light receiving surface (33P) spaced apart and faced to the light emitting surface (20Ps), the light receiving element (30P) and the light emitting element (20P) forming a photocoupler;
a transparent resin (60P) at least partially arranged between the light emitting surface (20Ps) and the light receiving surface (33P); and
a light-blocking encapsulation resin (80) covering the transparent resin (60P), the light emitting element (20P), and the light receiving element (30P),
where the encapsulation resin (80) covers a side surface of the light receiving element (20P).

D2. The insulation module according to clause D1, where
the transparent resin (60P) includes a light-emitting-side transparent resin (60PA) arranged between the plate-shaped member (70P) and the light emitting element (20P) and a light-receiving-side transparent resin (60PB) arranged between the plate-shaped member (70P) and the light receiving element (30P), and
the light-receiving-side transparent resin (60PB) includes a side surface (62B) that is curved to have a center of curvature (CD) located on a side of the side surface (62B) of the light-receiving-side transparent resin (60PB) opposite the plate-shaped member (70P).

E1. An insulation module, including:
a light emitting element (20P) including a light emitting surface (20Ps) and a pad (21P) formed on the light emitting surface (20Ps);
a light receiving element (30P) including a light receiving surface (33P) spaced apart and faced to the light emitting surface (20Ps), the light receiving element (30P) and the light emitting element (20P) forming a photocoupler;
a light-blocking encapsulation resin (80) covering a transparent resin (60P), the light emitting element (20P), and the light receiving element (30P);
multiple terminals (41A to 41D/51A to 51D) arranged next to one another on a resin side surface (81/82) of the encapsulation resin (80),
where the resin side surface (81/82) includes a recess-projection portion (87/88) arranged between a first terminal and a second terminal of the multiple terminals (41A to 41D/51A to 51D).

E2. The insulation module according to clause E1, including:
a lead frame (50D) including a die pad (52DB) that supports the light receiving element (30P), where
the lead frame (50D) includes a suspension lead (58D) extending from the die pad,
the suspension lead (58D) is exposed from the resin side surface (82), and
the resin side surface (82) includes the recess-projection portion (88) arranged between the suspension lead (58D), corresponding to the first terminal, and a terminal (51A, 51B) corresponding to the second terminal and located next to the suspension lead (58D).

E3. The insulation module according to clause E1, including:
a lead frame (50D) including a die pad (52DB) that supports the light receiving element (30P), where
the lead frame (50D) includes a suspension lead (58D) extending from the die pad (52DB),
the resin side surface includes a terminal surface (81/82) on which the multiple terminals (41A to 41D/51A to 51D) are arranged and a suspension lead surface (83) differing from the terminal surface (81/82), and the suspension lead (58D) extends out from the suspension lead surface (83).

F1. An insulation module, including:
a light emitting element (20P) including a light emitting surface (20Ps) and a pad (21P) formed on the light emitting surface (20Ps); and
a light receiving element (30P) including a light receiving surface (33P) spaced apart and faced to the light emitting surface (20Ps), the light receiving element (30P) and the light emitting element (20P) forming a photocoupler, where
a distance (DG) between the light emitting surface (20Ps) and the light receiving surface (33P) is less than a thickness of the light receiving element (30P).

F2. The insulation module according to clause F1, where the distance (DG) between the light emitting surface (20Ps) and the light receiving surface (33P) is less than a thickness of the light emitting element (20P).

F3. The insulation module according to clause F1 or F2, where a thickness of the light emitting element (20P) is less than a thickness of the light receiving element (30P).

G1. An insulation module, including:
a first light emitting element (20P) including a first light emitting surface (20Ps);
a second light emitting element (20Q) including a second light emitting surface (20Qs);
a first light receiving element (30P) including a first light receiving surface (33P) spaced apart and faced to the first light emitting surface (20Ps), the first light receiving element (30P) and the first light emitting element (20P) forming a first photocoupler;
a second light receiving element (30Q) including a second light receiving surface (33Q) spaced apart and faced to the second light emitting surface (20Qs), the second light receiving element (30Q) and the second light emitting element (20Q) forming a second photocoupler;
a first transparent resin (60P) covering at least the first light emitting element (20P) and the first light receiving element (30P),
a second transparent resin (60Q) covering at least the second light emitting element (20Q) and the second light receiving element (30Q),
an encapsulation resin (80) encapsulating the first transparent resin (60P) and the second transparent resin (60Q) and being formed from a light-blocking material,
the encapsulation resin (80) includes a separation wall (89) that separates the first transparent resin (60P) from the second transparent resin (60Q).

G2. The insulation module according to clause G1, including:
a first plate-shaped member (70P) arranged between the first light emitting element (20P) and the first light receiving element (30P); and
a second plate-shaped member (70Q) arranged between the second light emitting element (20Q) and the second light receiving element (30Q),
where the separation wall (89) separates the first plate-shaped member (70P) from the second plate-shaped member (70Q).

G3. An insulation module, including:
a first light emitting element (20P) including a first light emitting surface (20Ps);
a second light emitting element (20Q) including a second light emitting surface (20Qs);
a first light receiving element (30P) including a first light receiving surface (33P) spaced apart and faced to the first light emitting surface (20Ps), the first light receiving element (30P) and the first light emitting element (20P) forming a first photocoupler;
a second light receiving element (30Q) including a second light receiving surface (33Q) spaced apart and faced to the second light emitting surface (20Qs), the second light receiving element (30Q) and the second light emitting element (20Q) forming a second photocoupler;
a first transparent resin (60P) covering at least the first light emitting element (20P) and the first light receiving element (30P);
a second transparent resin (60Q) covering at least the second light emitting element (20Q) and the second light receiving element (30Q), where
the first light emitting element (20P) is configured to emit light having a first wavelength,
the second light emitting element (20Q) is configured to emit light having a second wavelength that differs from the first wavelength,
the first transparent resin (60P) is formed from a resin material that transmits light having the first wavelength and does not transmit light having the second wavelength, and
the second transparent resin (60Q) is formed from a resin material that transmits light having the second wavelength and does not transmit light having the first wavelength.

G4. The insulation module according to clause G3, including:
an encapsulation resin (80) encapsulating the first transparent resin (60P) and the second transparent resin (60Q) and being formed from a light-blocking material.

G5. The insulation module according to clause G4, where the encapsulation resin (80) includes a separation wall (89) that separates the first transparent resin (60P) from the second transparent resin (60Q).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

1. An insulation module, comprising:
a light emitting element including a light emitting surface and a pad formed on the light emitting surface;
a light receiving element including a light receiving surface spaced apart and faced to the light emitting surface, the light receiving element and the light emitting element forming a photocoupler;
a plate-shaped member arranged between the light emitting surface and the light receiving surface and inclined from each of the light emitting surface and the light receiving surface, the plate-shaped member being light-transmissive and electrically insulating; and
a wire connected to the pad,
wherein the pad is offset from a center of the light emitting surface toward a portion of the light emitting surface at which a distance to the plate-shaped member is greater than that at the center of the light emitting surface.

2. The insulation module according to claim 1, wherein
as viewed in a direction orthogonal to the light emitting surface, the light emitting element is rectangular, defined in a longitudinal direction and a lateral direction,
the light emitting surface is separated further away from the plate-shaped member from a first side toward a second side in the longitudinal direction,
the pad is offset in the longitudinal direction from the center of the light emitting surface toward a portion of the light emitting surface at which a distance to the plate-shaped member is greater than that at the center of the light emitting surface, and
the wire is connected to the pad so as not to contact the plate-shaped member.

3. An insulation module, comprising:
a light emitting element including a light emitting surface and a pad formed on the light emitting surface;
a light receiving element including a light receiving surface spaced apart and faced to the light emitting surface, the light receiving element and the light emitting element forming a photocoupler;
a plate-shaped member arranged between the light emitting surface and the light receiving surface and inclined from each of the light emitting surface and the light receiving surface, the plate-shaped member being light-transmissive and electrically insulating; and
a wire connected to the pad, wherein
as viewed in a direction orthogonal to the light emitting surface, the light emitting element is rectangular, defined in a longitudinal direction and a lateral direction,
the light emitting surface is separated further away from the plate-shaped member from a first side toward a second side in the longitudinal direction,
the light emitting surface includes an extension region that extends beyond the light receiving element toward the second side in the longitudinal direction, and
the pad is arranged in the extension region.

4. The insulation module according to claim 1, wherein
a maximum distance between the light emitting surface and the plate-shaped member, opposed to the light emitting surface, is less than a thickness of the light emitting element.

5. The insulation module according to claim 1, wherein a maximum distance between the light emitting surface and the plate-shaped member, opposed to the light emitting surface, is less than a thickness of the light receiving element.

6. The insulation module according to claim 1, wherein a thickness of the light emitting element is less than a thickness of the light receiving element.

7. The insulation module according to claim 1, wherein a minimum distance between the pad and the plate-shaped member, opposed to the pad, is greater than or equal to one-half of a distance between the light emitting surface and the light receiving surface.

8. The insulation module according to claim 1, comprising:
a transparent resin at least partially arranged between the light emitting surface and the light receiving surface; and
a light-blocking encapsulation resin covering the transparent resin, the light emitting element, the light receiving element, and the plate-shaped member.

9. The insulation module according to claim 8, wherein
the transparent resin includes a light-emitting-side transparent resin arranged between the plate-shaped member and the light emitting element and a light-receiving-side transparent resin arranged between the plate-shaped member and the light receiving element, and
the light-receiving-side transparent resin includes a side surface that is curved to have a center of curvature located on a side of the side surface of the light-receiving-side transparent resin opposite the plate-shaped member.

10. The insulation module according to claim 9, wherein the light-emitting-side transparent resin includes a side surface that is curved to have a center of curvature located on a side of the side surface of the light-emitting-side transparent resin opposite the plate-shaped member.

11. The insulation module according to claim 8, wherein the encapsulation resin covers a side surface of the light receiving element.

12. The insulation module according to claim 8, wherein
the encapsulation resin includes a resin side surface on which multiple terminals are arranged, and
the resin side surface includes a recess-projection portion arranged between a first terminal and a second terminal of the multiple terminals.

13. The insulation module according to claim 12, comprising:
a lead frame including a die pad that supports the light receiving element, wherein
the lead frame includes a suspension lead extending from the die pad,
the suspension lead is exposed from the resin side surface, and
the resin side surface includes the recess-projection portion arranged between the suspension lead, corresponding to the first terminal, and a terminal corresponding to the second terminal and located next to the suspension lead.

14. The insulation module according to claim 1, comprising:
a first die pad supporting the light emitting element; and
a second die pad supporting the light receiving element, wherein
a first recess is formed in the first die pad,
a second recess is formed in the second die pad,
the light emitting element is bonded to the first die pad including the first recess by a first bonding material arranged on the first die pad,
the light receiving element is bonded to the second die pad including the second recess by a second bonding material arranged on the second die pad,
the first die pad and the second die pad are arranged so that the first recess and the second recess are opposed to each other.

15. The insulation module according to claim 1, wherein
the light receiving element includes
an optical-electrical conversion element,
a control circuit configured to receive a signal from the optical-electrical conversion element, and
an insulation layer formed on the optical-electrical conversion element and the control circuit,
the insulation layer includes
a first insulation portion formed on the optical-electrical conversion element, and
a second insulation portion formed on the control circuit,
the second insulation portion includes at least one first wiring layer, and
the first insulation portion includes at least one layer that is free of a wiring layer.

16. The insulation module according to claim 1, wherein
the light receiving element includes
an optical-electrical conversion element,
a control circuit configured to receive a signal from the optical-electrical conversion element, and
an insulation layer formed on the optical-electrical conversion element and the control circuit,
the insulation layer includes
a first insulation portion formed on the optical-electrical conversion element,
a second insulation portion formed on the control circuit,
multiple first wiring layers are formed on the second insulation portion, and
one or more second wiring layers are formed on the first insulation portion and are less in number than the first wiring layers of the second insulation portion.

17. The insulation module according to claim 1, wherein
the light receiving element includes
an optical-electrical conversion element, and
a control circuit configured to receive a signal from the optical-electrical conversion element, and
when the light receiving element receives a signal that includes multiple pulses from the light emitting element, the control circuit is configured to output an output signal based on a portion of the multiple pulses excluding an initial pulse.

18. The insulation module according to claim 1, wherein
the light receiving element includes a first light receiving element and a second light receiving element,
the light emitting element includes a first light emitting element and a second light emitting element,
the first light emitting element and the first light receiving element form a first photocoupler,
the second light emitting element and the second light receiving element form a second photocoupler,
the insulation module, further comprising:
a first transparent resin covering the first light emitting element and the first light receiving element;
a second transparent resin covering the second light emitting element and the second light receiving element; and
an encapsulation resin encapsulating the first transparent resin and the second transparent resin,
the encapsulation resin includes a separation wall that separates the first transparent resin from the second transparent resin.

19. The insulation module according to claim 1, wherein
the light receiving element includes a first light receiving element and a second light receiving element,
the light emitting element includes a first light emitting element and a second light emitting element,
the first light emitting element and the first light receiving element form a first photocoupler,
the second light emitting element and the second light receiving element form a second photocoupler,
the insulation module, further comprising:
a first transparent resin covering the first light emitting element and the first light receiving element; and
a second transparent resin covering the second light emitting element and the second light receiving element,
the first light emitting element is configured to emit light having a first wavelength,
the second light emitting element is configured to emit light having a second wavelength that differs from the first wavelength,
the first transparent resin is formed from a resin material that transmits light having the first wavelength and does not transmit light having the second wavelength, and
the second transparent resin is formed from a resin material that transmits light having the second wavelength and does not transmit light having the first wavelength.

20. The insulation module according to claim 18, wherein the plate-shaped member includes
a first plate-shaped member arranged between the first light emitting element and the first light receiving element, and
a second plate-shaped member arranged between the second light emitting element and the second light receiving element.
